(19) United States
(12) Patent Application Publication
(10) Pub. No.: US 2018/0351069 A1
(43) Pub. Date: Dec. 6, 2018

(54) THERMOELECTRIC DEVICES AND SYSTEMS

(71) Applicant: MATRIX INDUSTRIES, INC., Menlo Park, CA (US)

(72) Inventors: Akram I. Boukai, Menlo Park, CA (US); Douglas W. Tham, Menlo Park, CA (US); Haifan Liang, Menlo Park, CA (US); Anne M. Ruminski, Menlo Park, CA (US); Arjun Mendiratta, Menlo Park, CA (US)

(21) Appl. No.: 15/992,635

(22) Filed: May 30, 2018

Related U.S. Application Data
(63) Continuation of application No. PCT/US2016/064501, filed on Dec. 1, 2016.
(60) Provisional application No. 62/320,990, filed on Apr. 11, 2016.
(60) Provisional application No. 62/261,647, filed on Dec. 1, 2015.

(51) Int. Cl. H01L 35/32; H01L 35/10; H01L 35/34

(52) U.S. Cl. CPC H01L 35/32; G04C 10/00; H01L 35/34; H01L 35/10

(57) ABSTRACT

The present disclosure provides a thermoelectric power management system that includes an electronic device comprising a user interface and a thermoelectric device. The thermoelectric device comprises a thermoelectric unit, a coupler, at least one fastener coupled to the thermoelectric unit and a separate heat expelling unit in thermal communication with the thermoelectric unit. The thermoelectric unit comprises a heat transfer surface that rests adjacent to a body surface of a user and the coupler removably secures the electronic device against the thermoelectric unit. Moreover, the at least one fastener secures the thermoelectric device to the body surface of the user and the thermoelectric device, during use, generates power upon flow of thermal energy from the heat transfer surface to the separate heat expelling unit.

### CROSS-REFERENCE

This application is a bypass continuation of International Application No. PCT/US2016/064501, filed Dec. 1, 2016, which claims priority to U.S. Provisional Patent Application Ser. No. 62/320,990, filed on Apr. 11, 2016 and U.S. Provisional Patent Application 62/261,647, filed on Dec. 1, 2015, each of which is incorporated herein by reference in its entirety for all purposes.

### BACKGROUND

Over 15 Terawatts of heat is lost to the environment annually around the world by heat engines that require petroleum as their primary fuel source. This is because these engines only convert about 30 to 40% of petroleum's chemical energy into useful work. Waste heat generation is an unavoidable consequence of the second law of thermodynamics.

The term “thermoelectric effect” encompasses the Seebeck effect, Peltier effect and Thomson effect. Solid-state cooling and power generation based on thermoelectric effects typically employ the Seebeck effect or Peltier effect for power generation and heat pumping. The utility of such conventional thermoelectric devices is, however, typically limited by their low coefficient-of-performance (COP) (for refrigeration applications) or low efficiency (for power generation applications).

Thermoelectric device performance may be captured by a so-called thermoelectric figure-of-merit, Z=S²σ/k, where ‘S’ is the Seebeck coefficient, ‘σ’ is the electrical conductivity, and ‘k’ is thermal conductivity. Z is typically employed as the indicator of the COP and the efficiency of thermoelectric devices—that is, COP scales with Z. A dimensionless figure-of-merit, ZT, may be employed to quantify thermoelectric device performance, where ‘T’ can be an average temperature of the hot and the cold sides of the device.

Applications of conventional semiconductor thermoelectric coolers are rather limited, as a result of a low figure-of-merit, despite many advantages that they provide over other refrigeration technologies. In cooling, low efficiency of thermoelectric devices made from conventional thermoelectric materials with a small figure-of-merit limits their applications in providing efficient thermoelectric cooling.

### SUMMARY

The present disclosure provides thermoelectric elements, devices and systems, and methods for forming such elements, devices and systems.

Although there are thermoelectric devices currently available, recognized herein are various limitations associated with such thermoelectric devices. For example, some thermoelectric devices currently available may not be flexible and able to conform to objects of various shapes, making it difficult to maximize a surface area for heat transfer. As another example, some thermoelectric devices currently available are substantially thick and not suitable for use in electronic devices that require more compact thermoelectric devices.

The present disclosure provides thermoelectric elements, devices and systems, and methods for forming such thermoelectric elements, devices and systems. Thermoelectric elements and devices of the present disclosure can be flexible and able to conform to objects of various shapes, sizes and configurations, making such elements and devices suitable for use in various settings, such as consumer and industrial settings. Thermoelectric elements and devices of the present disclosure can conform to surfaces to collect waste heat and transform at least a fraction of the waste heat to usable energy. In some cases waste heat can be generated during a chemical, electrical, and/or mechanical energy transformation process.

In an aspect of the present disclosure, a method for forming a thermoelectric element having a figure of merit (ZT) that is at least about 0.25 comprises (a) providing a reaction space comprising a semiconductor substrate, a working electrode in electrical communication with a first surface of the semiconductor substrate, an etching solution (e.g., electrolyte) in contact with a second surface of the semiconductor substrate, and a counter electrode in the etching solution, wherein the first and second surfaces of the semiconductor substrate is substantially free of a metallic coating; and (b) using the electrode and counter electrode to (i) direct electrical current to the semiconductor substrate at a current density of at least about 0.1 mA/cm², and (ii) etch the second surface of the semiconductor substrate with the etching solution to form a pattern of holes in the semiconductor substrate, thereby forming the thermoelectric element having the ZT that is at least about 0.25, wherein the etch is performed at an electrical potential of at least about 1 volt (V) across the semiconductor substrate and etching solution, and wherein the etch has an etch rate that is at least about 1 nanometer (nm) per second at 25° C. In some embodiments, the electrical potential is at least about 1 volt (V) across the working electrode, etching solution and counter electrode.

In some embodiments, the electrical potential is an alternating current (AC) voltage. In some embodiments, the electrical potential is a direct current (DC) voltage.

In some embodiments, the working electrode is in contact with the first surface. In some embodiments, the working electrode is in ohmic contact with the first surface. In some embodiments, the semiconductor substrate is part of the working electrode.

In some embodiments, the etch rate is at least about 10 nm per second. In some embodiments, the etch rate is at least about 100 nm per second. In some embodiments, the etch rate is at least about 1000 nm per second.

In some embodiments, the current density is at least about 1 mA/cm². In some embodiments, the current density is at least about 10 mA/cm². In some embodiments, the current density is from about 10 mA/cm² to 50 mA/cm², 10 mA/cm² to 30 mA/cm², or 10 mA/cm² to 20 mA/cm². In some embodiments, the current density is less than or equal to about 100 mA/cm² or 50 mA/cm². In some embodiments, the semiconductor substrate is etched under an alternating current at the current density.

In some embodiments, the working electrode is an anode during the etching. In some embodiments, the method further comprises annealing the semiconductor substrate subsequent to (b). In some embodiments, the method further comprises, prior to (b), heating the etching solution to a temperature that is greater than 25° C. In some embodiments, the semiconductor substrate is etched in the absence of (or without the aid of) a metal catalyst.

In some embodiments, the pattern of holes includes a disordered pattern of holes. In some embodiments, the working electrode does not contact the etching solution.

In some embodiments, the etching solution includes an acid. In some embodiments, the acid is selected from the group consisting of HF, HCl, HBr and HI. In some embodiments, the etching solution includes an alcohol additive. In some embodiments, the etch is performed in the absence of illuminating the semiconductor substrate.

In some embodiments, the ZT is at least 0.5, 0.6, 0.7, 0.8, 0.9, or 1 at 25° C. In some embodiments, the semiconductor substrate comprises silicon.

In another aspect, a method for forming a thermoelectric element having a figure of merit (ZT) that is at least about 0.25, comprises (a) providing a semiconductor substrate in a reaction space comprising an etching solution (e.g., electrolyte); (b) inducing flow of electrical current to the semiconductor substrate at a current density of at least about 0.1 mA/cm²; and (c) using the etching solution to etch the semiconductor substrate under the current density of at least about 0.1 mA/cm² to form a disordered pattern of holes in the semiconductor substrate, thereby forming the thermoelectric element having the ZT that is at least about 0.25, wherein the etching is performed (i) in the absence of a metal catalyst and (ii) at an electrical potential of at least about 1 volt (V) across the semiconductor substrate and etching solution, and wherein the etching has an etch rate of at least about 1 nanometer (nm) per second at 25° C.

In some embodiments, the electrical potential is an alternating current (AC) voltage. In some embodiments, the electrical potential is a direct current (DC) voltage.

In some embodiments, the etch rate is at least about 10 nm per second. In some embodiments, the etch rate is at least about 100 nm per second. In some embodiments, the etch rate is at least about 1000 nm per second.

In some embodiments, the current density is at least about 1 mA/cm². In some embodiments, the current density is at least about 10 mA/cm². In some embodiments, the current density is from about 10 mA/cm² to 50 mA/cm², 10 mA/cm² to 30 mA/cm², or 10 mA/cm² to 20 mA/cm². In some embodiments, the current density is less than or equal to about 100 mA/cm² or 50 mA/cm². In some embodiments, the semiconductor substrate is etched under an alternating current at the current density.

In some embodiments, the etching solution includes an acid. In some embodiments, the acid is selected from the group consisting of HF, HCl, HBr and HI. In some embodiments, the etching solution includes an alcohol additive. In some embodiments, the etch is performed in the absence of illuminating the semiconductor substrate.

In some embodiments, the method further comprises annealing the semiconductor substrate subsequent to (c). In some embodiments, the method further comprises, prior to (c), heating the etching solution to a temperature that is greater than 25° C. In some embodiments, the semiconductor substrate comprises silicon.

Another aspect of the present disclosure provides a computer readable medium comprising machine executable code that, upon execution by one or more computer processors, implements any of the methods above or elsewhere herein.

Another aspect of the present disclosure provides a computer control system comprising one or more computer processor and memory coupled thereto. The memory comprises machine executable code that, upon execution by the one or more computer processors, implements any of the methods above or elsewhere herein

In another aspect of the present disclosure, a thermoelectric device comprising at least one flexible thermoelectric element including a semiconductor substrate, wherein surfaces of the semiconductor substrate have a metal content less than about 1% as measured by x-ray photoelectron spectroscopy (XPS), wherein the flexible thermoelectric element has a figure of merit (ZT) that is at least about 0.25 at 25° C., and wherein the flexible thermoelectric element has a Young's Modulus that is less than or equal to about 1×10⁶ pounds per square inch (psi) at 25° C. as measured by static deflection of the thermoelectric element.

In some embodiments, the semiconductor substrate has a surface roughness between about 0.1 nanometers (nm) and 50 nm as measured by transmission electron microscopy (TEM). In some embodiments, the surface roughness is between about 1 nm and 20 nm as measured by TEM. In some embodiments, the surface roughness is between about 1 nm and 10 nm as measured by TEM.

In some embodiments, the metal content is less than or equal to about 0.001% as measured by XPS. In some embodiments, the Young's Modulus is less than or equal to about 800,000 psi at 25° C. In some embodiments, the figure of merit is at least about 0.5, 0.6, 0.7, 0.8, 0.9, or 1.

In some embodiments, the semiconductor substrate is chemically doped n-type or p-type. In some embodiments, the semiconductor substrate comprises silicon.

In some embodiments, the thermoelectric element includes a pattern of holes. In some embodiments, the pattern of holes is polydisperse. In some embodiments, the pattern of holes includes a disordered pattern of holes. In some embodiments, the disordered pattern of holes is polydisperse.

In some embodiments, the thermoelectric element includes a pattern of wires. In some embodiments, the pattern of wires is polydisperse. In some embodiments, the pattern of wires includes a disordered pattern of wires. In some embodiments, the disordered pattern of wires is polydisperse.

Another aspect of the present disclosure provides an electronic device comprising a flexible thermoelectric element including a semiconductor substrate, wherein surfaces of the semiconductor substrate have a metal content less than about 1% as measured by x-ray photoelectron spectroscopy (XPS), wherein the flexible thermoelectric element has a figure of merit (ZT) that is at least about 0.25 at 25° C., and wherein the flexible thermoelectric element bends at an angle of at least about 10⁰ relative to a measurement plane at a plastic deformation that is less than 20% as measured by three-point testing.

In some embodiments, the semiconductor substrate has a surface roughness between about 0.1 nanometers (nm) and 50 nm as measured by transmission electron microscopy (TEM). In some embodiments, the surface roughness is between about 1 nm and 20 nm as measured by TEM. In some embodiments, the surface roughness is between about 1 nm and 10 nm as measured by TEM.

In some embodiments, the metal content is less than or equal to about 0.001% as measured by XPS. In some embodiments, the flexible thermoelectric element bends at an angle of at least about 20° relative to the measurement plane. In some embodiments, the figure of merit is at least about 0.5, 0.6, 0.7, 0.8, 0.9, or 1.

In some embodiments, the electronic device is a watch, a health or fitness tracking device, or a waste heat recovery unit. The electronic device can be part of a larger system including other electronic devices and a control module, for example. Other electronic devices may be used, such as, for example, a refrigerator, an oven, a microwave, a computer processor, a vehicle engine, a pipe or other conduit (e.g., exhaust pipe), motor, or other source of heat, such as waste heat.

In some embodiments, the semiconductor substrate is chemically doped n-type or p-type. In some embodiments, the semiconductor substrate comprises silicon.

In some embodiments, the electronic device comprises a plurality of thermoelectric elements. Each of the plurality of thermoelectric elements can be as described above or elsewhere herein. In some embodiments, the plurality of thermoelectric elements is oppositely chemically doped n-type and p-type.

In some embodiments, the thermoelectric element includes a pattern of holes. In some embodiments, the pattern of holes is polydisperse. In some embodiments, the pattern of holes includes a disordered pattern of holes. In some embodiments, the disordered pattern of holes is polydisperse.

In some embodiments, the thermoelectric element includes a pattern of wires. In some embodiments, the pattern of wires is polydisperse. In some embodiments, the pattern of wires includes a disordered pattern of wires. In some embodiments, the disordered pattern of wires is polydisperse.

Another aspect of the present disclosure provides a system for generating power, comprising a fluid flow channel for directing a fluid; and a thermoelectric device comprising at least one flexible thermoelectric element adjacent to at least a portion of the fluid flow channel, wherein the flexible thermoelectric element has a Young's Modulus that is less than or equal to about 1×10⁶ pounds per square inch (psi) at 25° C., wherein the flexible thermoelectric element has a first surface that is in thermal communication with the fluid flow channel and a second surface that is in thermal communication with a heat sink, and wherein the thermoelectric device generates power upon the flow of heat from the fluid flow channel through the thermoelectric device to the heat sink.

In some embodiments, the thermoelectric device comprises at least two thermoelectric elements that are oppositely chemically doped n-type and p-type. In some embodiments, the Young's Modulus is less than or equal to about 800,000 psi at 25° C.

In some embodiments, the thermoelectric element comprises a semiconductor material. In some embodiments, the semiconductor material includes silicon.

In some embodiments, the flexible thermoelectric element substantially conforms to a shape of the fluid flow channel. In some embodiments, the fluid flow channel is a pipe. In some embodiments, the fluid flow channel is cylindrical.

An additional aspect of the present disclosure provides a thermoelectric power management system. The thermoelectric power management system comprises an electronic device comprising a user interface; and a thermoelectric device integrated with the electronic device in a housing. The thermoelectric device includes a thermoelectric unit having a heat transfer surface that rests adjacent to a body surface of a user, and at least one fastening member or fastener coupled to the thermoelectric unit. The at least one fastening member or fastener secures the thermoelectric device to the body surface of the user and comprises a heat expelling unit comprising at least one heat pipe that is in thermal communication with the thermoelectric unit. During use, the thermoelectric unit can generate power upon flow of thermal energy from the heat transfer surface to the heat expelling unit.

In some embodiments, the electronic device is a watch. In some embodiments, the user interface is a graphical user interface. In some embodiments, the thermoelectric device comprises a plurality of fastening members or fasteners coupled to the thermoelectric unit, where the plurality of fastening members or fasteners secure the thermoelectric device to the body surface of the user. In some embodiments, the electronic device comprises an energy storage unit. In some embodiments, the thermoelectric power management system further comprises an inductive unit in electrical communication with the thermoelectric unit. The inductive unit couples the power generated by the thermoelectric unit to the electronic device. In some embodiments, the fastening member or fastener comprises the heat transfer surface.

An additional aspect of the present disclosure provides a thermoelectric power management system. The thermoelectric power management system includes an electronic device comprising a user interface; and a thermoelectric device. The thermoelectric device comprises a thermoelectric unit having a heat transfer surface that rests adjacent to a body surface of a user; a securing member or coupler that removably secures the thermoelectric unit against the electronic device; at least one fastening member or fastener coupled to the thermoelectric unit, where the at least one fastening member or fastener secures the thermoelectric device to the body surface of the user; and a separate heat expelling unit in thermal communication with the thermoelectric unit. During use, the thermoelectric unit can generate power upon flow of thermal energy from the heat transfer surface to the separate heat expelling unit.

In some embodiments, the separate heat expelling unit comprises at least one heat pipe that is in thermal communication with the thermoelectric unit. In some embodiments, the fastening member or fastener comprises the heat expelling unit. In some embodiments, the fastening member or fastener comprises the heat transfer surface. In some embodiments, the electronic device is a watch. In some embodiments, the user interface is a graphical user interface. In some embodiments, the thermoelectric device comprises a plurality of fastening members or fasteners coupled to the thermoelectric unit, wherein the plurality of fastening members or fasteners secure the thermoelectric device to the body surface of the user. In some embodiments, the electronic device comprises an energy storage unit. In some embodiments, the securing member or coupler is magnetic. In some embodiments, the thermoelectric power management system further comprises an inductive unit in electrical communication with the thermoelectric unit. The inductive unit couples the power generated by the thermoelectric unit to the electronic device.

An additional aspect of the present disclosure provides a thermoelectric power management system. The thermoelectric power management system includes an electronic device comprising a user interface; and a thermoelectric device. The thermoelectric device comprises a thermoelectric unit having a heat transfer surface that rests adjacent to a body surface of a user; a securing member or coupler that secures the thermoelectric unit against the electronic device; (iii) at least one fastening member or fastener coupled to the thermoelectric unit, where the at least one fastening member or fastener secures the thermoelectric device to the body surface of the user; and a separate heat expelling unit in thermal communication with the thermoelectric unit, where the thermoelectric unit is impedance matched with the body surface. During use, the thermoelectric unit can generate power upon flow of thermal energy from the heat transfer surface to the separate heat expelling unit.

In some embodiments, the separate heat expelling unit comprises at least one heat pipe that is in thermal communication with the thermoelectric unit. In some embodiments, the fastening member or fastener comprises the heat expelling unit. In some embodiments, the fastening member or fastener comprises the heat transfer surface. In some embodiments, the electronic device is a watch. In some embodiments, the user interface is a graphical user interface. In some embodiments, the thermoelectric device comprises a plurality of fastening members or fasteners coupled to the thermoelectric unit, where the plurality of fastening members or fasteners secure the thermoelectric device to the body surface of the user. In some embodiments, the electronic device comprises an energy storage unit. In some embodiments, the securing member or coupler is magnetic. In some embodiments, the thermoelectric power management system further comprises an inductive unit in electrical communication with the thermoelectric unit. The inductive unit can couple the power generated by the thermoelectric unit to the electronic device.

An additional aspect of the disclosure provides a thermoelectric power management system. The thermoelectric power management system comprises a conduit through which a fluid can flow and a thermoelectric device. The thermoelectric device comprises (i) a first heat transfer surface that is in thermal communication with the conduit; (ii) a thermoelectric material in thermal communication with the first heat transfer surface; and (iii) a second heat transfer surface that is in thermal communication with the thermoelectric material. During use, the thermoelectric device generates power upon flow of thermal energy from the conduit, through the first heat transfer surface, to the second heat transfer surface. The thermoelectric power management system can also include an electronic device electrically coupled to the thermoelectric device that, during use, is at least partially (e.g., at least 1%, 5%, 10%, 20%, 30%, 40%, 50%, 60%, 70%, 80%, 90%, 95%, 99% of a power demand or requirement) or fully powered by power generated by the thermoelectric device.

In some embodiments, the electronic device comprises a user interface. In some embodiments, the fluid is a gas. In some embodiments, the fluid is a liquid. In some embodiments, the conduit is a pipe. In some embodiments, the conduit is a vent. In some embodiments, the first heat transfer surface and/or the second heat transfer surface comprise a heat sink. In some embodiments, the heat sink comprises one or more fins (or heat fins).

In some embodiments, during use, the thermoelectric device generates power upon flow of thermal energy from the second heat transfer surface, through the first heat transfer surface, to the conduit. In some embodiments, the second heat transfer surface transfers thermal energy from a surrounding environment to the thermoelectric material. In some embodiments, the first heat transfer surface and/or the second heat transfer surface are physically separated from the thermoelectric material by one or more thermal interface layers which one or more thermal interface layers at least partially regulate the flow of thermal energy through the thermoelectric device. In some embodiments, the thermoelectric device is impedance matched with the conduit.

An additional aspect of the disclosure provides a thermoelectric power management system, comprising: an electronic device comprising a user interface; and a thermoelectric device integrated with the electronic device in a housing, wherein the thermoelectric device comprises (i) a thermoelectric unit having a heat transfer surface that rests adjacent to a body surface of a user, and (ii) at least one fastener coupled to the thermoelectric unit, wherein the at least one fastener secures the thermoelectric device to the body surface of the user, wherein the at least one fastener comprises a heat expelling unit comprising at least one heat pipe that is in thermal communication with the thermoelectric unit, wherein during use, the thermoelectric unit generates power upon flow of thermal energy from the heat transfer surface to the heat expelling unit.

In some embodiments, the electronic device is a watch. In some embodiments, the user interface is a graphical user interface. In some embodiments, the thermoelectric device comprises a plurality of fasteners coupled to the thermoelectric unit, wherein the plurality of fasteners secure the thermoelectric device to the body surface of the user. In some embodiments, the electronic device comprises an energy storage unit. In some embodiments, the thermoelectric power management system further comprises an inductive unit in electrical communication with the thermoelectric unit, wherein the inductive unit couples the power generated by the thermoelectric unit to the electronic device. In some embodiments, the fastener comprises the heat transfer surface.

An additional aspect of the disclosure provides a thermoelectric power management system, comprising: an electronic device comprising a user interface; and a thermoelectric device comprising (i) a thermoelectric unit having a heat transfer surface that rests adjacent to a body surface of a user, (ii) a coupler that removably secures the thermoelectric unit against the electronic device, (iii) at least one fastener coupled to the thermoelectric unit, wherein the at least one fastener secures the thermoelectric device to the body surface of the user, and (iv) a separate heat expelling unit in thermal communication with the thermoelectric unit, wherein during use, the thermoelectric unit generates power upon flow of thermal energy from the heat transfer surface to the separate heat expelling unit.

In some embodiments, the separate heat expelling unit comprises at least one heat pipe that is in thermal communication with the thermoelectric unit. In some embodiments, the fastener comprises the heat expelling unit. In some embodiments, the fastener comprises the heat transfer surface. In some embodiments, the electronic device is a watch. In some embodiments, the user interface is a graphical user interface. In some embodiments, the thermoelectric device comprises a plurality of fasteners coupled to the thermoelectric unit, wherein the plurality of fasteners secure the thermoelectric device to the body surface of the user. In some embodiments, the electronic device comprises an energy storage unit. In some embodiments, the coupler is magnetic. In some embodiments, the thermoelectric power management system further comprises an inductive unit in electrical communication with the thermoelectric unit, wherein the inductive unit couples the power generated by the thermoelectric unit to the electronic device.

An additional aspect of the disclosure provides a thermoelectric power management system, comprising: an electronic device comprising a user interface; and a thermoelectric device comprising (i) a thermoelectric unit having a heat transfer surface that rests adjacent to a body surface of a user, (ii) a coupler that secures the thermoelectric unit against the electronic device, (iii) at least one fastener coupled to the thermoelectric unit, wherein the at least one fastener secures the thermoelectric device to the body surface of the user, and (iv) a separate heat expelling unit in thermal communication with the thermoelectric unit, wherein the thermoelectric unit is impedance matched with the body surface, wherein during use, the thermoelectric unit generates power upon flow of thermal energy from the heat transfer surface to the separate heat expelling unit.

In some embodiments, the separate heat expelling unit comprises at least one heat pipe that is in thermal communication with the thermoelectric unit. In some embodiments, the fastener comprises the heat expelling unit. In some embodiments, the fastener comprises the heat transfer surface. In some embodiments, the electronic device is a watch. In some embodiments, the user interface is a graphical user interface. In some embodiments, the thermoelectric device comprises a plurality of fasteners coupled to the thermoelectric unit, wherein the plurality of fasteners secure the thermoelectric device to the body surface of the user. In some embodiments, the electronic device comprises an energy storage unit. In some embodiments, the coupler is magnetic. In some embodiments, the thermoelectric power management system further comprises an inductive unit in electrical communication with the thermoelectric unit, wherein the inductive unit couples the power generated by the thermoelectric unit to the electronic device.

An additional aspect of the disclosure provides a thermoelectric power management system, comprising: a conduit that permits flow of a fluid; a thermoelectric device comprising (i) a first heat transfer surface that is in thermal communication with the conduit; (ii) a thermoelectric material in thermal communication with the first heat transfer surface; and (iii) a second heat transfer surface that is in thermal communication with the thermoelectric material, wherein during use, the thermoelectric device generates power upon flow of thermal energy from the conduit, through the first heat transfer surface, to the second heat transfer surface; and an electronic device electrically coupled to the thermoelectric device, wherein during use, the thermoelectric device generates power that is sufficient to meet at least a portion of a power demand of the electronic device.

In some embodiments, the electronic device comprises a user interface. In some embodiments, the fluid is a gas. In some embodiments, the fluid is a liquid. In some embodiments, the conduit is a pipe. In some embodiments, the conduit is a vent. In some embodiments, the first heat transfer surface and/or the second heat transfer surface comprise a heat sink. In some embodiments, the heat sink comprises one or more fins. In some embodiments, wherein during use, the thermoelectric device generates power upon flow of thermal energy from the second heat transfer surface, through the first heat transfer surface, to the conduit. In some embodiments, the second heat transfer surface transfers thermal energy from a surrounding environment to the thermoelectric material. In some embodiments, the first heat transfer surface and/or the second heat transfer surface are physically separated from the thermoelectric material by one or more thermal interface layers which one or more thermal interface layers at least partially regulate the flow of thermal energy through the thermoelectric device. In some embodiments, the thermoelectric device is impedance matched with the conduit. In some embodiments, wherein during use, the thermoelectric device generates power that is sufficient to meet all of the power demand of the electronic device.

An additional aspect of the disclosure provides a method for generating power, comprising: (a) activating a thermoelectric power management device comprising: (i) an electronic unit comprising a user interface; and (ii) a thermoelectric unit integrated with the electronic device in a housing, wherein the thermoelectric device comprises (1) a thermoelectric unit having a heat transfer surface that rests adjacent to a body surface of a user, and (2) at least one fastener coupled to the thermoelectric unit, wherein the at least one fastener secures the thermoelectric device to the body surface of the user, wherein the at least one fastener comprises a heat expelling unit comprising at least one heat pipe that is in thermal communication with the thermoelectric unit; and (b) using the thermoelectric unit to generate power upon flow of thermal energy from the heat transfer surface to the heat expelling unit.

An additional aspect of the disclosure provides a method for generating power, comprising: (a) activating a thermoelectric power management device comprising: (i) an electronic unit comprising a user interface; and (ii) a thermoelectric unit comprising (1) a thermoelectric unit having a heat transfer surface that rests adjacent to a body surface of a user, (2) a coupler that removably secures the thermoelectric unit against the electronic device, (3) at least one fastener coupled to the thermoelectric unit, wherein the at least one fastener secures the thermoelectric device to the body surface of the user, and (4) a separate heat expelling unit in thermal communication with the thermoelectric unit; and (b) using the thermoelectric unit to generate power upon flow of thermal energy from the heat transfer surface to the separate heat expelling unit.

An additional aspect of the disclosure provides a method for generating power, comprising: (a) activating a thermoelectric power management device comprising: (i) an electronic unit comprising a user interface; and (ii) a thermoelectric unit comprising (1) a thermoelectric unit having a heat transfer surface that rests adjacent to a body surface of a user, (2) a coupler that secures the thermoelectric unit against the electronic device, (3) at least one fastener coupled to the thermoelectric unit, wherein the at least one fastener secures the thermoelectric device to the body surface of the user, and (4) a separate heat expelling unit in thermal communication with the thermoelectric unit, wherein the thermoelectric unit is impedance matched with the body surface; and (b) using the thermoelectric unit to generate power upon flow of thermal energy from the heat transfer surface to the separate heat expelling unit.

An additional aspect of the disclosure provides a method for generating power, comprising: (a) activating a thermoelectric power management device comprising: (i) a conduit that permits flow of a fluid; (ii) a thermoelectric unit comprising (1) a first heat transfer surface that is in thermal communication with the conduit; (2) a thermoelectric material in thermal communication with the first heat transfer surface; and (3) a second heat transfer surface that is in thermal communication with the thermoelectric material, wherein during use, the thermoelectric device generates power upon flow of thermal energy from the conduit, through the first heat transfer surface, to the second heat transfer surface; and (iii) an electronic unit electrically coupled to the thermoelectric unit; and (b) using the thermoelectric unit to generate power; and (c) providing the power to the electronic unit, which power is sufficient to meet at least a portion of a power demand of the electronic unit.

In some embodiments, the power is sufficient to meet all of the power demand of the electronic unit.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “figure” and “FIG.” herein), of which:

FIG. 1 shows a thermoelectric device having a plurality of elements;

FIG. 2 is a schematic perspective view of a thermoelectric element, in accordance with an embodiment of the present disclosure;

FIG. 3 is a schematic top view of the thermoelectric element of FIG. 2, in accordance with an embodiment of the present disclosure;

FIG. 4 is a schematic side view of the thermoelectric element of FIGS. 2 and 3, in accordance with an embodiment of the present disclosure;

FIG. 5 is a schematic perspective top view of a thermoelectric element, in accordance with an embodiment of the present disclosure;

FIG. 6 is a schematic perspective top view of the thermoelectric element of FIG. 5, in accordance with an embodiment of the present disclosure;

FIG. 7 is a schematic perspective view of a thermoelectric device comprising elements having an array of wires, in accordance with an embodiment of the present disclosure;

FIG. 8 is a schematic perspective view of a thermoelectric device comprising elements having an array of holes, in accordance with an embodiment of the present disclosure;

FIG. 9 is a schematic perspective view of a thermoelectric device comprising elements having an array of holes that are oriented perpendicularly with respect to the vector V, in accordance with an embodiment of the present disclosure;

FIG. 10 schematically illustrates a method for manufacturing a flexible thermoelectric device comprising a plurality of thermoelectric elements;

FIG. 11 schematically illustrates a flexible thermoelectric device having a flexible thermoelectric material;

FIG. 12 schematically illustrates a heat recovery system comprising a heat sink and a thermoelectric device;

FIG. 13 schematically illustrates a weldable tube with an integrated thermoelectric device and heat sinks;

FIG. 14A schematically illustrates a flexible heat sink wrapped around an object; FIG. 14B is a cross-sectional side view of FIG. 14A;

FIG. 15 schematically illustrates a flexible thermoelectric tape with an integrated heat sink;

FIG. 16 schematically illustrates an electronic device having thermoelectric elements in electrical communication with top and bottom interconnects;

FIG. 17A is a schematic perspective side view of a baby monitor; FIG. 17B is a schematic angled side view of the baby monitor of FIG. 17A; FIG. 17C is a schematic side view of the baby monitor of FIG. 17A; FIG. 17D is a schematic top view of the baby monitor of FIG. 17A;

FIG. 18A is a schematic perspective side view of a pacemaker; FIG. 18B is a schematic side view of the pacemaker of FIG. 18A; FIG. 18C is a schematic top view of the pacemaker of FIG. 18A;

FIG. 19A is a schematic perspective view of a wearable electronic device; FIG. 19B schematically illustrates the wearable electronic device of FIG. 19A adjacent to a hand of a user;

FIG. 20 is a schematic perspective view of eyewear;

FIG. 21A is a schematic perspective view of a medical device; FIG. 21B schematically illustrates the medical device of FIG. 21A mounted on a body of a user;

FIG. 22 schematically illustrates heat recover systems as part of a vehicle exhaust system;

FIG. 23A is a schematic perspective side view of a heat recovery and power generation system installed on a radiator; FIG. 23B is a schematic side view of the heat recovery and power generation system of FIG. 23A;

FIG. 24A is a schematic perspective side view of a heat recovery and power generation system installed in a heat exchanger; FIG. 24B is a schematic side view of the heat recovery and power generation system of FIG. 24A;

FIG. 25 shows a computer control system that is programmed or otherwise configured to implement various methods provided herein, such as manufacturing thermoelectric elements;

FIG. 26A shows a scanning electron microscopy (SEM) micrograph of a thermoelectric element; and FIG. 26B shows an x-ray diffraction (XRD) plot showing bulk and porous silicon in a thermoelectric element;

FIG. 27A and FIG. 27B schematically depict views of an example wearable device described herein;

FIGS. 28A-28C schematically depict views of example wearable devices described herein;

FIGS. 29A-29C schematically depict views of example wearable devices described herein;

FIGS. 30A-30C schematically depict views of an example wearable device described herein;

FIG. 31A schematically depicts an example thermoelectric device;

FIG. 31B schematically depicts a cross sectional view of an example thermoelectric device;

FIG. 32A schematically depicts an example thermoelectric device described herein;

FIG. 32B graphically depicts temperature profiles of various components of an example thermoelectric device;

FIG. 33A and FIG. 33B schematically depict views of an example wearable device described herein;

FIGS. 34A and 34B schematically depict views of an example wearable device described herein;

FIG. 35 schematically depicts a view of an example wearable device described herein;

FIGS. 36A and 36B schematically depict an example thermoelectric device described herein; and

FIG. 37 schematically depicts an example thermoelectric device described herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “nanostructure,” as used herein, generally refers to structures having a first dimension (e.g., width) along a first axis that is less than about 1 micrometer (“micron”) in size. Along a second axis orthogonal to the first axis, such nanostructures can have a second dimension from nanometers or smaller to microns, millimeters or larger. In some cases, the dimension (e.g., width) is less than about 1000 nanometers (“nm”), or 500 nm, or 100 nm, or 50 nm, or smaller. Nanostructures can include holes formed in a substrate material. The holes can form a mesh having an array of holes. In other cases, nanostructure can include rod-like structures, such as wires, cylinders or box-like structure. The rod-like structures can have circular, elliptical, triangular, square, rectangular, pentagonal, hexagonal, heptagonal, octagonal or nonagonal, or other cross-sections.

The term “nanohole,” as used herein, generally refers to a hole, filled or unfilled, having a width or diameter less than or equal to about 1000 nanometers (“nm”), or 500 nm, or 100 nm, or 50 nm, or smaller. A nanohole filled with a metallic, semiconductor, or insulating material can be referred to as a “nanoinclusion.”

The term “nanowire,” as used herein, generally refers to a wire or other elongate structure having a width or diameter that is less than or equal to about 1000 nm, or 500 nm, or 100 nm, or 50 nm, or smaller.

The term “n-type,” as used herein, generally refers to a material that is chemically doped (“doped”) with an n-type dopant. For instance, silicon can be doped n-type using phosphorous or arsenic.

The term “p-type,” as used herein, generally refers to a material that is doped with an p-type dopant. For instance, silicon can be doped p-type using boron or aluminum.

The term “metallic,” as used herein, generally refers to a substance exhibiting metallic properties. A metallic material can include one or more elemental metals.

The term “monodisperse,” as used herein, generally refers to features having shapes, sizes (e.g., widths, cross-sections, volumes) or distributions (e.g., nearest neighbor spacing, center-to-center spacing) that are similar to one another. In some examples, monodisperse features (e.g., holes, wires) have shapes or sizes that deviate from one another by at most about 20%, 15%, 10%, 5%, 4%, 3%, 2%, 1%, 0.5%, or 0.1%. In some cases, monodisperse features are substantially monodisperse.

The term “etching material,” as used herein, generally refers to a material that facilitates the etching of substrate (e.g., semiconductor substrate) adjacent to the etching material. In some examples, an etching material catalyzes the etching of a substrate upon exposure of the etching material to an oxidizing agent and a chemical etchant.

The term “etching layer,” as used herein, generally refers to a layer that comprises an etching material. Examples of etching materials include silver, platinum, chromium, molybdenum, tungsten, osmium, iridium, rhodium, ruthenium, palladium, copper, nickel and other metals (e.g., noble metals), or any combination thereof, or any non-noble metal that can catalyze the decomposition of a chemical oxidant, such as, for example, copper, nickel, or combinations thereof.

The term “etch block material,” as used herein, generally refers to a material that blocks or otherwise impedes the etching of a substrate adjacent to the etch block material. An etch block material may provide a substrate etch rate that is reduced, or in some cases substantially reduced, in relation to a substrate etch rate associated with an etching material. The term “etch block layer,” as used herein, generally refers to a layer that comprises an etch block material. An etch block material can have an etch rate that is lower than that of an etching material.

The term “reaction space,” as used herein, generally refers to any environment suitable for the formation of a thermoelectric device or a component of the thermoelectric device. A reaction space can be suitable for the deposition of a material film or thin film adjacent to a substrate, or the measurement of the physical characteristics of the material film or thin film. A reaction space may include a chamber, which may be a chamber in a system having a plurality chambers. The system may include a plurality of fluidically separated (or isolated) chambers. The system may include multiple reactions spaces, with each reaction space being fluidically separated from another reaction space. A reaction space may be suitable for conducting measurements on a substrate or a thin film formed adjacent to the substrate.

The term “current density,” as used herein, generally refers to electric (or electrical) current per unit area of cross section, such as the cross section of a substrate. In some examples, current density is electric current per unit area of a surface of a semiconductor substrate.

The term “adjacent” or “adjacent to,” as used herein, includes ‘next to’, ‘adjoining’, ‘in contact with’, and ‘in proximity to’. In some instances, adjacent components are separated from one another by one or more intervening layers. The one or more intervening layers may have a thickness less than about 10 micrometers (“microns”), 1 micron, 500 nanometers (“nm”), 100 nm, 50 nm, 10 nm, 1 nm, 0.5 nm or less. For example, a first layer adjacent to a second layer can be in direct contact with the second layer. As another example, a first layer adjacent to a second layer can be separated from the second layer by at least a third layer.

The term “heat pipe,” as used herein, generally refers to a heat-transfer device or unit that combines the principles of thermal conductivity and phase transition to manage the transfer of heat between two interfaces (e.g., between two solid interfaces). In an example, at a hot interface of a heat pipe, a liquid in contact with a thermally conductive solid surface turns into a vapor by absorbing heat from a surface. The vapor then travels along the heat pipe to a cold interface and condenses back into a liquid, releasing latent heat. The liquid then returns to the hot interface through, e.g., capillary action, centrifugal force, or gravity, and the cycle may be repeated. Such heat pipe may provide an effective thermal conductivity of up to about 0.01 kW/(m·K), 0.1 kW/(m·K), 0.5 kW/(m·K), 1 kW/(m·K), 10 kW/(m·K), 20 kW/(m·K), 30 kW/(m·K), 40 kW/(m·K), 50 kW/(m·K), or 100 kW/(m·K).

### Thermoelectric Elements, Devices and Systems

The present disclosure provides thermoelectric elements, devices and systems that can be employed for use in various applications, such as heating and/or cooling applications, power generation, consumer applications and industrial applications. In some examples, thermoelectric materials are used in consumer electronic devices (e.g., smart watches, portable electronic devices, and health/fitness tracking devices). As another example, a thermoelectric material of the present disclosure can be used in an industrial setting, such as at a location where there is heat loss. In such a case, heat can be captured by a thermoelectric device and used to generate power.

Thermoelectric devices of the present disclosure can be used to generate power upon the application of a temperature gradient across such devices. Such power can be used to provide electrical energy to various types of devices, such as consumer electronic devices.

Thermoelectric devices of the present disclosure can have various non-limiting advantages and benefits. In some cases, thermoelectric devices can have substantially high aspect ratios, uniformity of holes or wires, and figure-of-merit, ZT, which can be suitable for optimum thermoelectric device performance. With respect to the figure-of-merit, Z can be an indicator of coefficient-of-performance (COP) and the efficiency of a thermoelectric device, and T can be an average temperature of the hot and the cold sides of the thermoelectric device. In some embodiments, the figure-of-merit (ZT) of a thermoelectric element or thermoelectric device is at least about 0.01, 0.02, 0.03, 0.04, 0.05, 0.06, 0.07, 0.08, 0.09, 0.1, 0.15, 0.2, 0.25, 0.3, 0.35, 0.4, 0.45 0.5, 0.55, 0.6, 0.65, 0.7, 0.75, 0.8, 0.85, 0.9, 0.95, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, or 3.0 at 25° C. In some case, the figure-of-merit is from about 0.01 to 3, 0.1 to 2.5, 0.5 to 2.0 or 0.5 to 1.5 at 25° C.

The figure of merit (ZT) can be a function of temperature. In some cases, ZT increases with temperature. For example, a thermoelectric having a ZT of 0.5 at 25° C. can have a greater ZT at 100° C.

Thermoelectric devices of the present disclosure can have electrodes each comprising an array of nanostructures (e.g., holes or wires). The array of nanostructures can include a plurality of holes or elongate structures, such as wires (e.g., nanowires). The holes or wires can be ordered and have uniform sizes and distributions. As an alternative, the holes or wires may not be ordered and may not have a uniform distribution. In some examples, there is no long range order with respect to the holes or wires. In some cases, the holes or wires may intersect each other in random directions. Methods for forming patterned or disordered patterns of nanostructures (e.g., holes or wires) are provided elsewhere herein.

The present disclosure provides thermoelectric elements that can be flexible or substantially flexible. A flexible material can be a material that can be conformed to a shape, twisted, or bent without experiencing plastic deformation. This can enable thermoelectric elements to be used in various settings, such as settings in which contact area with a heat source or heat sink is important. For example, a flexible thermoelectric element can be brought in efficient contact with a heat source or heat sink, such as by wrapping the thermoelectric element around the heat source or heat sink.

A thermoelectric device can include one or more thermoelectric elements. The thermoelectric elements can be flexible. An individual thermoelectric element can include at least one semiconductor substrate which can be flexible. In some cases, individual semiconductor substrates of a thermoelectric element can be rigid but substantially thin (e.g., 500 nm to 1 mm or 1 micrometer to 0.5 mm) such that they provide a flexible thermoelectric element when disposed adjacent one another. Similarly, individual thermoelectric elements of a thermoelectric device can be rigid but substantially thin such that they provide a flexible thermoelectric device when disposed adjacent one another. In some cases, a semiconductor substrate of a thermoelectric element comprises silicon (e.g., single-crystal silicon).

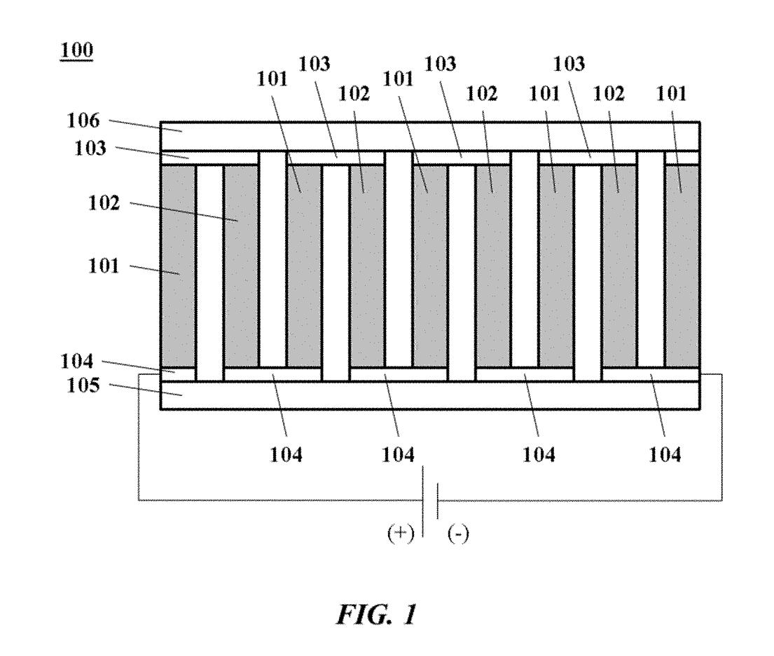

FIG. 1 shows a thermoelectric device 100, in accordance with some embodiments of the present disclosure. The thermoelectric device 100 includes n-type 101 and p-type 102 elements disposed between a first set of electrodes 103 and a second set of electrodes 104 of the thermoelectric device 100. The first set of electrodes 103 connects adjacent n-type 101 and p-type 102 elements, as illustrated.

The electrodes 103 and 104 are in contact with a hot side material 105 and a cold side material 106 respectively. In some embodiments, the hot side material 105 and cold side material 106 are electrically insulating but thermally conductive. The application of an electrical potential to the electrodes 103 and 104 leads to the flow of current, which generates a temperature gradient (ΔT) across the thermoelectric device 100. The temperature gradient (ΔT) extends from a first temperature (average), T1, at the hot side material 105 to a second temperature (average), T2, at the cold side material 106, where T1>T2. The temperature gradient can be used for heating and cooling purposes.

The n-type 101 and p-type 102 elements of the thermoelectric device 100 can be formed of structures having dimensions from nanometers to micrometers, such as, e.g., nanostructures. In some situations, the nanostructures are holes or inclusions, which can be provided in an array of holes (i.e., mesh). In other situations, the nanostructures are rod-like structures, such as nanowires. In some cases, the rod-like structures are laterally separated from one another.

In some cases, the n-type 101 and/or p-type 102 elements are formed of an array of wires or holes oriented along the direction of the temperature gradient. That is, the holes or wires extend from the first set of electrodes 103 to the second set of electrodes 104. In other cases, the n-type 101 and/or p-type 102 elements are formed of an array of holes or wires oriented along a direction that is angled between about 0° and 90° in relation to the temperature gradient. In an example, the array of holes is orthogonal to the temperature gradient. The holes or wires, in some cases, have dimensions on the order of nanometers to micrometers. In some cases, holes can define a nanomesh.

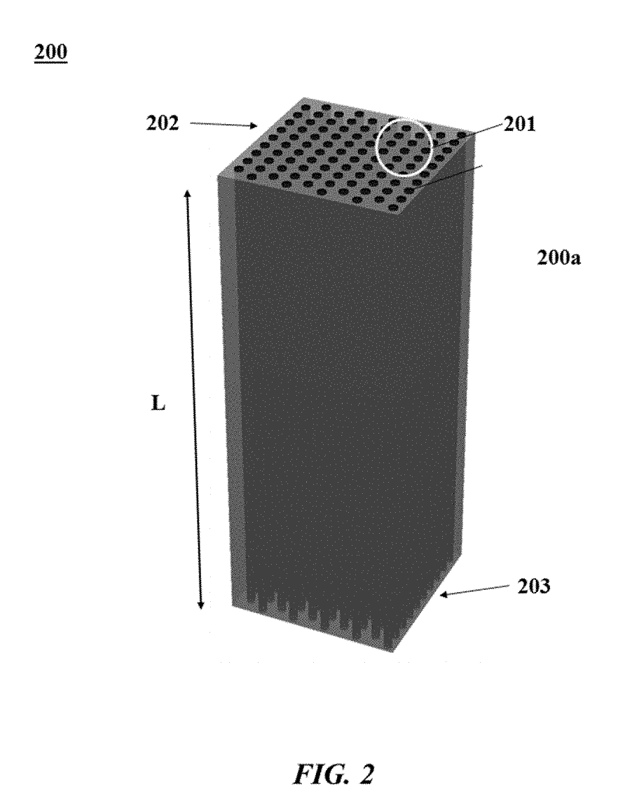

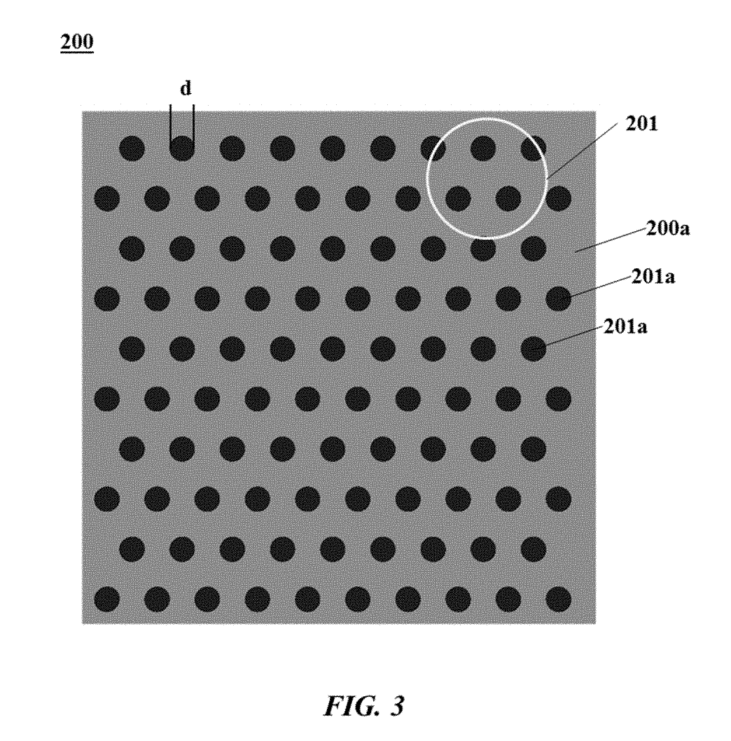

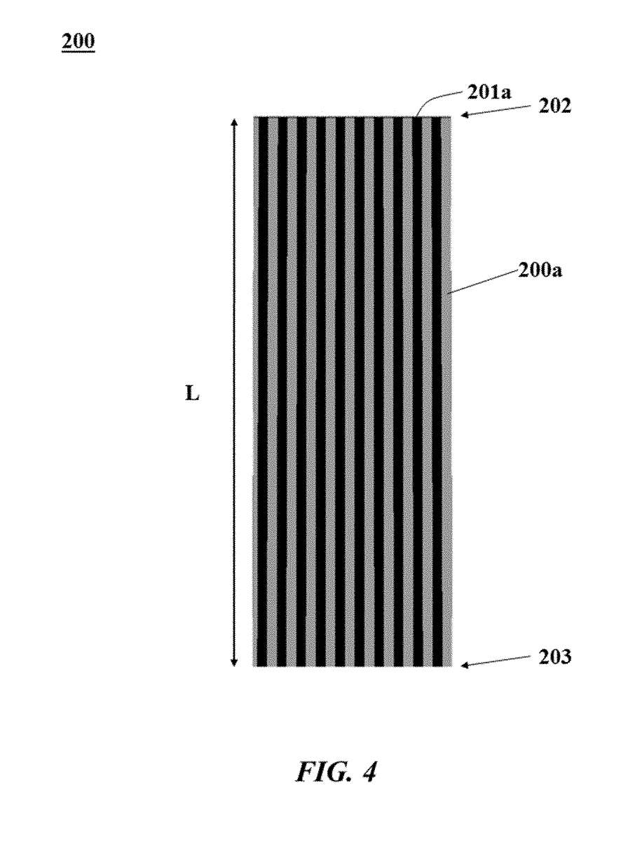

FIG. 2 is a schematic perspective view of a thermoelectric element 200 having an array of holes 201 (select holes circled), in accordance with an embodiment of the present disclosure. The array of holes can be referred to as a “nanomesh” herein. FIGS. 3 and 4 are perspective top and side views of the thermoelectric element 200. The element 200 can be an n-type or p-type element, as described elsewhere herein. The array of holes 201 includes individual holes 201a that can have widths from several nanometers or less up to microns, millimeters or more. In some embodiments, the holes have widths (or diameters, if circular) (“d”) between about 1 nm and 500 nm, or 5 nm and 100 nm, or 10 nm and 30 nm. The holes can have lengths (“L”) from about several nanometers or less up to microns, millimeters or more. In some embodiments, the holes have lengths between about 0.5 microns and 1 centimeter, or 1 micron and 500 millimeters, or 10 microns and 1 millimeter.

The holes 201a are formed in a substrate 200a. In some cases, the substrate 200a is a solid state material, such as e.g., carbon (e.g., graphite or graphene), silicon (e.g., single-crystal silicon), germanium, gallium arsenide, aluminum gallium arsenide, silicides, silicon germanium, bismuth telluride, lead telluride, oxides (e.g., SiOₓ, where ‘x’ is a number greater than zero), gallium nitride and tellurium silver germanium antimony (TAGS) containing alloys. For example, the substrate 200a can be a Group IV material (e.g., silicon or germanium) or a Group III-V material (e.g., gallium arsenide). The substrate 200a may be formed of a semiconductor material comprising one or more semiconductors. The semiconductor material can be doped n-type or p-type for n-type or p-type elements, respectively.

In some cases, the holes 201a are filled with a gas, such as He, Ne, Ar, N₂, H₂, CO₂, O₂, or a combination thereof. In other cases, the holes 201a are under vacuum. Alternatively, the holes may be filled (e.g., partially filled or completely filled) with a semiconductor material, an insulating (or dielectric) material, or a gas (e.g., He, Ar, H₂, N₂, CO₂).

A first end 202 and second end 203 of the element 200 can be in contact with a substrate having a semiconductor-containing material, such as silicon (e.g., single-crystal silicon) or a silicide. The substrate can aid in providing an electrical contact to an electrode on each end 202 and 203. Alternatively, the substrate can be precluded, and the first end 202 and second end 203 can be in contact with a first electrode (not shown) and a second electrode (not shown), respectively.

In some embodiments, the holes 201a are substantially monodisperse. Monodisperse holes may have substantially the same size, shape and/or distribution (e.g., cross-sectional distribution). In other embodiments, the holes 201a are distributed in domains of holes of various sizes, such that the holes 201a are not necessarily monodisperse. For example, the holes 201a may be polydisperse. Polydisperse holes can have shapes, sizes and/or orientations that deviate from one another by at least about 0.1%, 0.5%, 1%, 2%, 3%, 4%, 5%, 10%, 15%, 20%, 30%, 40%, or 50%. In some situations, the device 200 includes a first set of holes with a first diameter and a second set of holes with a second diameter. The first diameter is larger than the second diameter. In other cases, the device 200 includes two or more sets of holes with different diameters.

The holes 201a can have various packing arrangements. In some cases, the holes 201a, when viewed from the top (see FIG. 3), have a hexagonal close-packing arrangement.

In some embodiments, the holes 201a in the array of holes 201 have a center-to-center spacing between about 1 nm and 500 nm, or 5 nm and 100 nm, or 10 nm and 30 nm. In some cases, the center-to-center spacing is the same, which may be the case for monodisperse holes 201a. In other cases, the center-to-center spacing can be different for groups of holes with various diameters and/or arrangements.

The dimensions (lengths, widths) and packing arrangement of the holes 201, and the material and doping configuration (e.g., doping concentration) of the element 200 can be selected to effect a predetermined electrical conductivity and thermal conductivity of the element 200, and a thermoelectric device having the element 200. For instance, the diameters and packing configuration of the holes 201 can be selected to minimize the thermal conductivity, and the doping concentration can be selected to maximize the electrical conductivity of the element 200.

The doping concentration of the substrate 200a can be at least about 10¹⁸ cm⁻³, 10¹⁹ cm⁻³, 10²⁰ cm⁻³, or 10²¹ cm⁻³. In some examples, the doping concentration can be from about 10¹⁸ to 10²¹ cm⁻³, or 10¹⁹ to 10²⁰ cm⁻³. The doping concentration can be selected to provide a resistivity that is suitable for use as a thermoelectric element. The resistivity of the substrate 200a can be at least about 0.001 ohm-cm, 0.01 ohm-cm, or 0.1 ohm-cm, and in some cases less than or equal to about 1 ohm-cm, 0.5 ohm-cm, 0.1 ohm-cm. In some examples, the resistivity of the substrate 200a can be from about 0.001 ohm-cm to 1 ohm-cm, 0.001 ohm-cm to 0.5 ohm-cm, or 0.001 ohm-cm to 0.1 ohm-cm.

The array of holes 201 can have an aspect ratio (e.g., the length of the element 200 divided by width of an individual hole 201a) of at least about 1.5:1, or 2:1, or 5:1, or 10:1, or 20:1, or 50:1, or 100:1, or 1000:1, or 5,000:1, or 10,000:1, or 100,000:1, or 1,000,000:1, or 10,000,000:1, or 100,000,000:1, or more.

The holes 201 can be ordered and have uniform sizes and distributions. As an alternative, the holes 201 may not be ordered and may not have a uniform distribution. For example, the holes 201 can be disordered such that there is no long range order for the pattern of holes 201.

In some embodiments, thermoelectric elements can include an array of wires. The array of wires can include individual wires that are, for example, rod-like structures.

As an alternative to the array of holes of the element 200, the holes may not be ordered and may not have a uniform distribution. In some examples, there is no long range order with respect to the holes. In some cases, the holes may intersect each other in random directions. The holes may include intersecting holes, such as secondary holes that project from the holes in various directions. The secondary holes may have additional secondary holes. The holes may have various sizes and may be aligned along various directions, which may be random and not uniform.

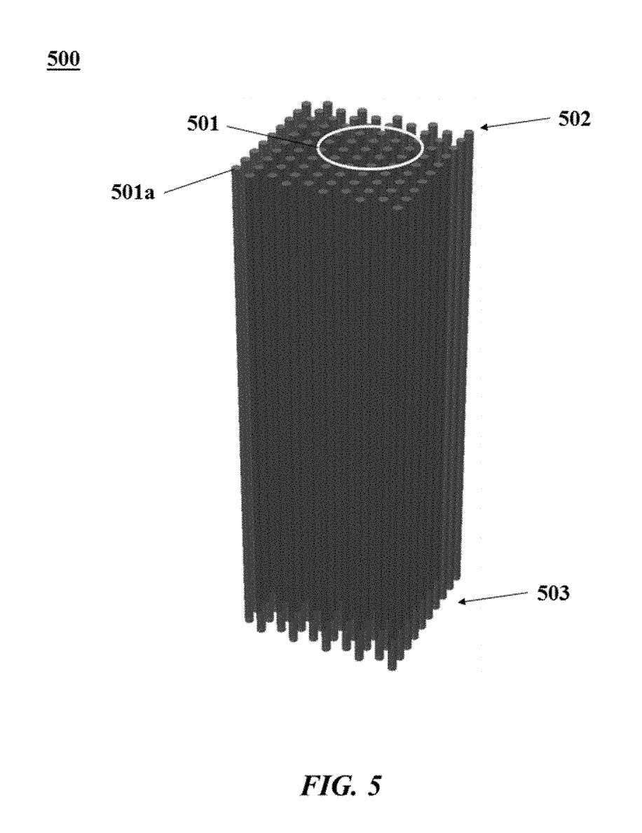

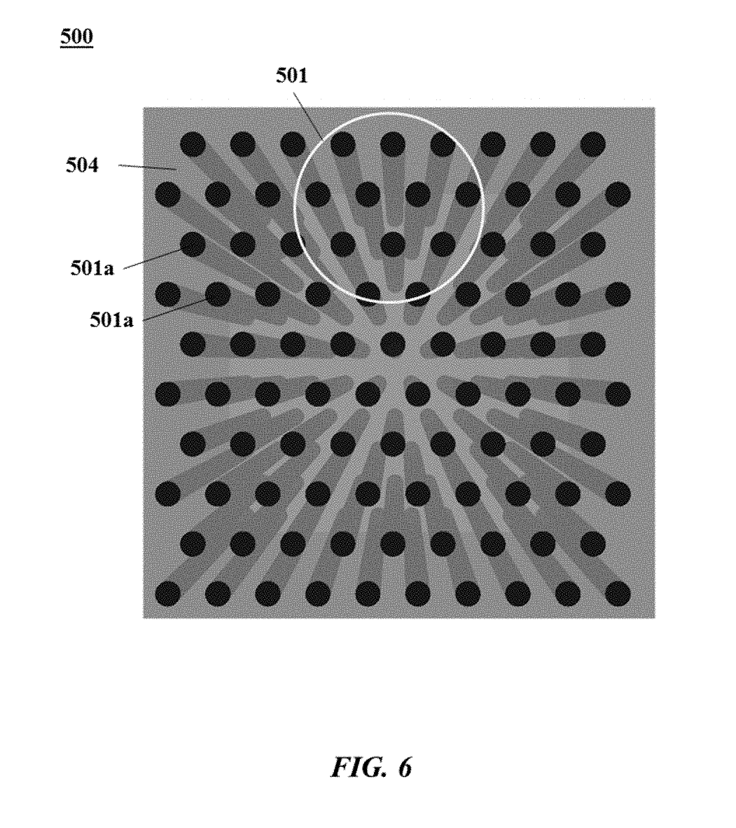

FIG. 5 is a schematic perspective view of a thermoelectric element 500, in accordance with an embodiment of the present disclosure. FIG. 6 is a schematic perspective top view of the thermoelectric element 500. The thermoelectric element 500 may be used with devices, systems and methods provided herein. The element 500 can include an array of wires 501 having individual wires 501a. In some embodiments, the wires can have widths (or diameters, if circular) (“d”) between about 1 nm and 500 nm, or 5 nm and 100 nm, or 10 nm and 30 nm. The wires can have lengths (“L”) from about several nanometers or less up to microns, millimeters or more. In some embodiments, the wires have lengths between about 0.5 microns and 1 centimeter, or 1 micron and 500 millimeters, or 10 microns and 1 millimeter.

In some embodiments, the wires 501a can be substantially monodisperse. Monodisperse wires may have substantially the same size, shape and/or distribution (e.g., cross-sectional distribution). In other embodiments, the wires 501a can be distributed in domains of wires of various sizes, such that the wires 501a are not necessarily monodisperse. For example, the wires 501a may be polydisperse. Polydisperse wires can have shapes, sizes and/or orientations that deviate from one another by at least about 0.1%, 0.5%, 1%, 2%, 3%, 4%, 5%, 10%, 15%, 20%, 30%, 40%, or 50%.

In some embodiments, the wires 501a in the array of wires 501 can have a center-to-center spacing between about 1 nm and 500 nm, or 5 nm and 100 nm, or 10 nm and 30 nm. In some cases, the center-to-center spacing can be the same, which may be the case for monodisperse wires 501. In other cases, the center-to-center spacing can be different for groups of wires with various diameters and/or arrangements.

In some embodiments, the wires 501a can be formed of a solid state material, such as a semiconductor material, such as, e.g., silicon, germanium, gallium arsenide, aluminum gallium arsenide, silicide alloys, alloys of silicon germanium, bismuth telluride, lead telluride, oxides (e.g., SiOₓ, where ‘x’ is a number greater than zero), gallium nitride and tellurium silver germanium antimony (TAGS) containing alloys. The wires 501a can be formed of other materials disclosed herein. The wires 501a can be doped with an n-type dopant or a p-type dopant. The doping concentration of the semiconductor material can be at least about 10¹⁸ cm⁻³, 10¹⁹ cm⁻³, 10²⁰ cm⁻³, or 10²¹ cm⁻³. In some examples, the doping concentration can be from about 10¹⁸ to 10²¹ cm⁻³, or 10¹⁹ to 10²⁰ cm⁻³. The doping concentration of the semiconductor material can be selected to provide a resistivity that is suitable for use as a thermoelectric element. The resistivity of the semiconductor material can be at least about 0.001 ohm-cm, 0.01 ohm-cm, or 0.1 ohm-cm, and in some cases less than or equal to about 1 ohm-cm, 0.5 ohm-cm, 0.1 ohm-cm. In some examples, the resistivity of the semiconductor material can be from about 0.001 ohm-cm to 1 ohm-cm, 0.001 ohm-cm to 0.5 ohm-cm, or 0.001 ohm-cm to 0.1 ohm-cm.

In some embodiments, the wires 501a can be attached to semiconductor substrates at a first end 502 and second end 503 of the element 500. The semiconductor substrates can have the n-type or p-type doping configuration of the individual wires 501a. In other embodiments, the wires 501a at the first end 502 and second end 503 may not be attached to semiconductor substrates, but can be attached to electrodes. For instance, a first electrode (not shown) can be in electrical contact with the first end 502 and a second electrode can be electrical contact with the second end 503.

With reference to FIG. 6, space 504 between the wires 501a may be filled with a vacuum or various materials. In some embodiments, the wires can be laterally separated from one another by an electrically insulating material, such as a silicon dioxide, germanium dioxide, gallium arsenic oxide, spin on glass, and other insulators deposited using, for example, vapor phase deposition, such as chemical vapor deposition or atomic layer deposition. In other embodiments, the wires can be laterally separated from one another by vacuum or a gas, such as He, Ne, Ar, N₂, H₂, CO₂, O₂, or a combination thereof.

The array of wires 501 can have an aspect ratio—length of the element 500 divided by width of an individual wire 501a—of at least about 1.5:1, or 2:1, or 5:1, or 10:1, or 20:1, or 50:1, or 100:1, or 1000:1, or 5,000:1, or 10,000:1, or 100,000:1, or 1,000,000:1, or 10,000,000:1, or 100,000,000:1, or more. In some cases, the length of the element 500 and the length of an individual wire 501a can be substantially the same.

Thermoelectric elements provided herein can be incorporated in thermoelectric devices for use in cooling and/or heating and, in some cases, power generation. In some examples, the device 100 may be used as a power generation device. In an example, the device 100 is used for power generation by providing a temperature gradient across the electrodes and the thermoelectric elements of the device 100.

As an alternative to the array of wires of the element 500, the wires may not be ordered and may not have a uniform distribution. In some examples, there is no long range order with respect to the wires. In some cases, the wires may intersect each other in random directions. The wires may have various sizes and may be aligned along various directions, which may be random and not uniform.

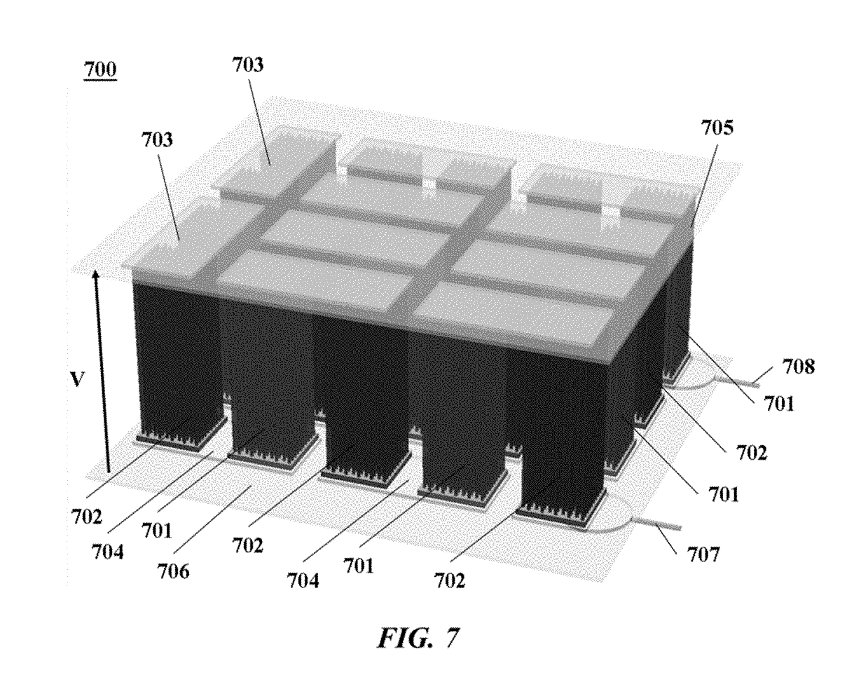

FIG. 7 shows a thermoelectric device 700 having n-type elements 701 and p-type elements 702, in accordance with an embodiment of the present disclosure. The n-type elements 701 and p-type elements 702 can each include an array of wires, such as nanowires. An array of wires can include a plurality of wires. The n-type elements 701 can include n-type (or n-doped) wires and the p-type elements 702 can include p-type wires. The wires can be nanowires or other rod-like structures.

Adjacent n-type elements 701 and p-type elements 702 can be electrically connected to one another at their ends using electrodes 703 and 704. The device 700 can include a first thermally conductive, electrically insulating layer 705 and a second thermally conductive, electrically insulating layer 706 at opposite ends of the elements 701 and 702.

The device 700 can include terminals 707 and 708 that are in electrical communication with the electrodes 703 and 704. The application of an electrical potential across the terminals 707 and 708 can generate a flow of electrons and holes in the n-type and p-type elements 701 and 702, respectively, which can generate a temperature gradient across the elements 701 and 702. The first thermally conductive, electrically insulating layer 705 may be a cold side of the device 700; the second thermally conductive, electrically insulating layer 706 may be a hot side of the device 700. The cold side is cooler (i.e., has a lower operating temperature) than the hot side.

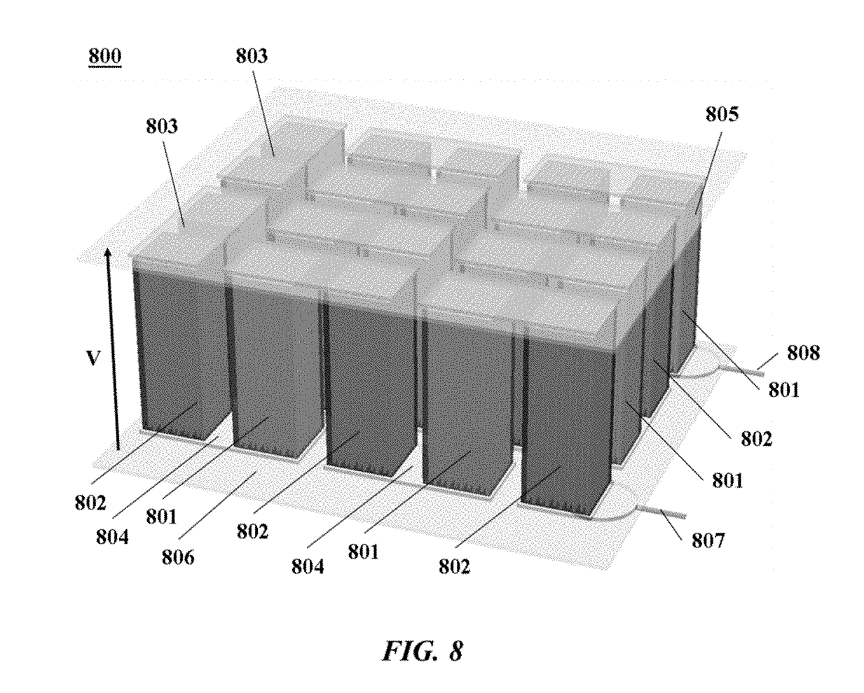

FIG. 8 shows a thermoelectric device 800 having n-type elements 801 and p-type elements 802, in accordance with an embodiment of the present disclosure. The n-type elements 801 and p-type elements 802 can be formed in n-type and p-type semiconductor substrates, respectively. Each substrate can include an array of holes, such as nanoholes. The array of holes can include a plurality of holes. An individual hole can span the length of an n-type or p-type element. The holes can be monodisperse, in which case hole dimensions and center-to-center spacing may be substantially constant. In some cases, the array of holes includes holes with center-to-center spacing and hole dimensions (e.g., widths or diameters) that may be different. In such a case, the holes may not be monodisperse.

Select n-type elements 801 and p-type elements 802 can be electrically connected to one another at their ends by electrodes 803 and 804. The device 800 can include a first thermally conductive, electrically insulating layer (“first layer”) 805 and a second thermally conductive, electrically insulating layer (“second layer”) 806 at opposite ends of the elements 801 and 802.

The device 800 can include terminals 807 and 808 that are in electrical communication with the electrodes 803 and 804. The application of an electrical potential across the terminals 807 and 808 can generate a flow of electrons and holes in the n-type and p-type elements 801 and 802, respectively, which can generate a temperature gradient across the elements 801 and 802. The first thermally conductive, electrically insulating layer 805 may be a cold side of the device 800; the second thermally conductive, electrically insulating layer 806 may be a hot side of the device 800. The cold side is cooler (i.e., has a lower operating temperature) than the hot side.

The thermoelectric device 800 may have a temperature gradient from the second thermally conductive, electrically insulating layer 806 to the first thermally conductive, electrically insulating layer 805. In some cases, the holes can be disposed parallel to a vector oriented from the first layer 805 to the second layer 806. In other cases, the holes can be disposed at an angle greater than 0° in relation to the vector. For instance, the holes can be disposed at an angle of at least about 1°, 10°, 20°, 30°, 40°, 50°, 60°, 70°, 80°, or 90° in relation to the vector.

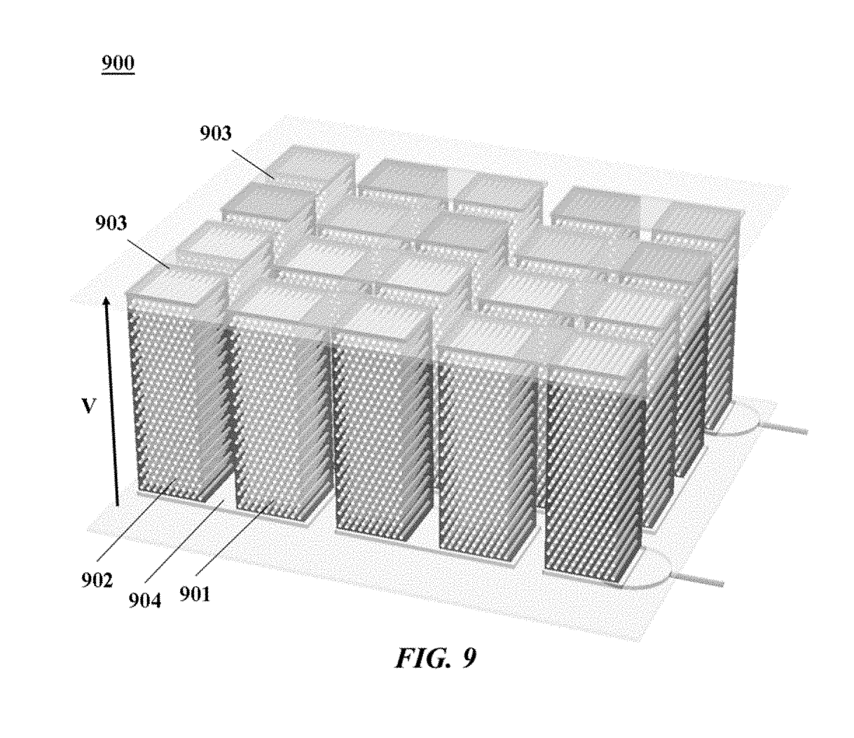

FIG. 9 shows a thermoelectric device 900 having n-type elements 901 and p-type elements 902, with the elements having holes formed in substrates of the n-type and p-type elements. The holes are oriented perpendicular to a vector (“V”) orthogonal to the electrodes 903 and 904 of the device 900.

Wires or holes of thermoelectric elements provided herein may be formed in a substrate and oriented substantially anti-parallel to a support structure, such as an electrode. In some examples, the wires or holes are oriented at an angle greater than 0°, or 10°, or 20°, or 30°, or 40°, or 50°, or 60°, or 70°, or 80°, or 85° in relation to the support structure. In an example, the wires or holes are oriented at an angle of about 90° in relation to the support structure. The electrode may be an electrode of a thermoelectric device. In some cases, wires or holes may be oriented substantially parallel to the electrode.

As an alternative to the devices of FIGS. 7-9, a thermoelectric device can have a thermoelectric element with an array of holes or wires with individual holes or wires that may have different sizes and/or distributions. An array of holes or wires may not be ordered and may not have a uniform distribution. In some examples, there is no long range order with respect to the holes or wires. In some cases, the holes or wires may intersect each other in random directions. The holes or wires may include intersecting holes or wires, such as secondary holes or wires that project from other holes or wires in various directions. The holes or wires may have various sizes and may be aligned along various directions, which may be random and not uniform. As another alternative, a thermoelectric device can include at least one thermoelectric element (p or n-type) with an ordered array of holes or wires, and at least one thermoelectric element (p or n-type) with a disordered array of holes or wires. The disordered array of holes or wires may include holes or wires that are not ordered and do not have a uniform distribution.

A hole or wire of the disclosure may have a surface roughness that is suitable for optimized thermoelectric device performance. In some cases, the root mean square roughness of a hole or wire can be between about 0.1 nm and 50 nm, or 1 nm and 20 nm, or 1 nm and 10 nm. The roughness can be determined by transmission electron microscopy (TEM) or other surface analytical technique, such as atomic force microscopy (AFM) or scanning tunneling microscopy (STM). The surface roughness may be characterized by a surface corrugation.

### Methods for Forming Thermoelectric Elements

The present disclosure provides various methods for forming thermoelectric elements. A thermoelectric element can be formed using electrochemical etching. In some cases, a thermoelectric element can be formed by cathodic or anodic etching, in some cases without the use of a catalyst. A thermoelectric element can be formed without use of a metallic catalysis. A thermoelectric element can be formed without providing a metallic coating on a surface of a substrate to be etched. This can also be performed using purely electrochemical anodic etching and suitable etch solutions and electrolytes. As an alternative, a thermoelectric element can be formed using metal catalyzed electrochemical etching in suitable etch solutions and electrolytes, as described in, for example, PCT/US2012/047021, filed Jul. 17, 2012, PCT/US2013/021900, filed Jan. 17, 2013, PCT/US2013/055462, filed Aug. 16, 2013, PCT/US2013/067346, filed Oct. 29, 2013, each of which is entirely incorporated herein by reference.

Recognized herein are various benefits to not using catalysts to form thermoelectric elements. In an example, a non-metal catalyzed etch can preclude the need for metal (or metallic) catalysts, which can provide for fewer processing steps, including cleanup steps to remove the metal catalysts from the thermoelectric element after etching. This can also provide for reduced manufacturing cost, as metal catalysts can be expensive. Metal catalysts can include rare and/or expensive metallic materials (e.g., gold, silver, platinum, or palladium), and eliminating the use of a metallic catalyst can advantageously decrease the cost of forming thermoelectric elements. Additionally, the non-catalyzed process can be more reproducible and controllable. In some cases, the non-catalyzed process described herein can be scaled from a relatively small production scale of thermoelectric elements to a relatively larger production scale of thermoelectric elements.

The present disclosure provides methods for forming thermoelectric materials for use in various applications, such as consumer and industrial applications. In some examples, thermoelectric materials are used in consumer electronic devices (e.g., smart watches, portable electronic devices, and health/fitness tracking devices). As another example, a thermoelectric material of the present disclosure can be used in an industrial setting, such as at a location where there is heat loss, which heat can be captured and used to generate power.

The present disclosure provides methods for forming flexible or substantially flexible thermoelectric materials. A flexible material can be a material that bends at an angle of least about 1°, 5°, 10°, 15°, 20°, 25°, 30°, 35°, 40°, 45°, 50°, 60°, 70°, 80°, 90°, 100°, 120°, 130°, 140°, 150°, 160°, 170°, or 180° relative to a measurement plane without experiencing plastic deformation or breaking. The flexible material can bend under an applied force over a given area of the flexible material (i.e. pressure). Plastic deformation can be measured by, for example, three-point testing (e.g., instron extension) or tensile testing. As an alternative or in addition to, the flexible material can be a material that bends at an angle of least about 1°, 5°, 10°, 15°, 20°, 25°, 30°, 35°, 40°, 45°, 50°, 60°, 70°, 80°, 90°, 100°, 120°, 130°, 140°, 150°, 160°, 170°, or 180° relative to a measurement plane at a plastic deformation that is less than or equal to about 20%, 15%, 10%, 5%, 1%, or 0.1% as measured by three-point testing (e.g., instron extension) or tensile testing. A flexible material can be a substantially pliable material. A flexible material can be a material that can conform or mold to a surface. Such materials can be employed for use in various settings, such as consumer and industrial settings. Thermoelectric elements formed according to methods herein can be formed into various shapes and configurations. Such shapes can be changed as desired by a user, such as to conform to a given object. The thermoelectric elements can have a first shape, and after being formed into a shape or configuration the thermoelectric elements can have a second shape. The thermoelectric elements can be transformed from the second shape to the initial (i.e. first) shape.

In an aspect of the present disclosure, a thermoelectric device (or material) is formed using anodic etching. Anodic etching can be performed in an electrochemical etch cell that provides electrical connections to the substrate being etched (e.g., a substrate comprising a solid-state material, a semiconductor substrate, a semiconductor substrate comprising silicon, a semiconductor substrate comprising single-crystal silicon), one or more reservoirs to hold the etch solutions or electrolytes in contact with the substrate, and access for analytical measurements or monitoring of the etching process. The etch solutions and/or electrolytes can comprise an aqueous solution. The etch (or etching) solutions and/or electrolytes can be a basic, neutral, or acidic solution. Examples of etching solutions include acids, such as hydrofluoric acid (HF), hydrochloric acid (HCl), hydrogen bromide (HBr), hydrogen iodide (HI), or combinations thereof. Moreover, an electrolyte can be provided in a solution, such as, for example, a fluoride electrolyte or fluoride electrolyte solution. A fluoride electrolyte solution can include one or more of HF, ammonium fluoride, tetrafluoroborate, lithium fluoroborate and a solvent (e.g., an alcohol (e.g., ethanol), water, acetonitrile). The etch solutions and/or electrolytes can be an electrically conductive solution. In an example, the etch cell includes a top reservoir that contains a solution comprising an electrolyte. The top reservoir can be situated adjacent to (e.g., on top of) a substrate to be etched. The substrate to be etched can be substantially free of one or more metallic material, which may be catalytic materials. The substrate to be etched may be free of a metallic coating. In some examples, the substrate to be etched can have a metal content (e.g., on a surface of the substrate) that is less than about 25%, 20%, 15%, 10%, 5%, 1%, 0.1%, 0.01%, 0.001%, 0.0001%, 0.00001%, or 000001%, as measured by x-ray photoelectron spectroscopy (XPS).

An etching solution can include an acid (e.g., HF) or a concentration of acids (taken as a weight percentage) that is less than or equal to about 70%, 60%, 50%, 40%, 30%, 20% or 10% (by weight), in some cases greater than or equal to about 1%, 10%, 20%, or 30%. In some examples, the concentration (by weight) is from about 1% to 60%, or 10% to 50%, or 20% to 45%. The balance of the etching solution can include a solvent (e.g., water) and an additive, such as an alcohol, carboxylic acid, ketone and/or aldehyde. In some examples, the additive is an alcohol, such as methanol, ethanol, isopropanol, or a combination thereof. The additive can enable the use of lower current densities while forming nanostructures (e.g., holes) with properties that are suitable for use in thermoelectric elements of the present disclosure, such as a substantially uniform distribution of holes having a disordered pattern. The additive can enable the use of lower current densities while forming nanostructures (e.g., holes) with properties that are suitable for use in thermoelectric elements of the present disclosure, such as increased control of the spacing between two or more holes. The additive can enable the use of lower current densities while forming nanostructures (e.g., holes) with properties that are suitable for use in thermoelectric elements of the present disclosure, such as spacing between two or more holes of at most about 5 nm. The additive can enable the use of lower current densities while forming nanostructures (e.g., holes) with properties that are suitable for use in thermoelectric elements of the present disclosure, such as spacing between two or more holes of at most about 20 nm. The additive can enable the use of lower current densities while forming nanostructures (e.g., holes) with properties that are suitable for use in thermoelectric elements of the present disclosure, such as spacing between two or more holes of at most about 100 nm.

Electric current can be sourced to and/or through the substrate using an edge or backside contact, through the solution/electrolyte, and into a counter electrode. The counter electrode can be in electrical communication with the top reservoir, in some cases situated in the top reservoir. In some cases, the counter electrode can be adjacent or in contact with a topside of the substrate. The body of the etch cell can be fabricated from materials inert to the etch solution or electrolyte (e.g., PTFE, PFA, polypropylene, HDPE). The edge or backside contact can include a metal contact on the substrate, or it can be a liquid contact using a suitable electrolyte. The counter electrode can include a wire or mesh constructed from a suitable electrode material. The etch cell can contain mechanical paddles or ultrasonic agitators to maintain solution motion, or the entire cell may be spun, rotated or shaken. In some examples, agitating the solution before and/or during etching can provide for improved etching uniformity. This can enable the electrolyte to be circulated during etching. In another example, the etch cell can contain one or more recirculating reservoirs and etch chambers, with one or more solutions/electrolytes.

In an example, an unpatterned substrate is loaded into reaction space provided with up to five or more electrode connections. One of the electrodes can be in ohmic contact with the substrate backside (the working electrode) and may be isolated from an etchant electrolyte. One of the electrodes can be in ohmic contact with the substrate backside (the working electrode) and may not be in contact with an etchant electrolyte. Another electrode (the counter electrode) can be submerged in the electrolyte but not in direct contact with the substrate, and used to supply current through the electrolyte to the substrate working electrode. Another electrode (the reference electrode) can be immersed in the electrolyte and isolated from both the working and counter electrodes, in some cases using a frit, and used to sense the operating potential of the etch cell using a known or predetermined reference standard. Another two or more electrodes may be placed outside the reaction space in order to set up an external electric field. In some cases, at least two electrodes—a working electrode and a counter electrode—may be required.

The reaction space can be used in a number of ways. In one approach, the reaction space can be used in a two-electrode configuration by passing an anodic current via the substrate backside through a suitable electrolyte. The electrolyte can be, for example, a liquid mixture containing a diluent, such as water, or a fluoride-containing reagent, such as hydrofluoric acid, or an oxidizer, such as hydrogen peroxide. The electrolyte can include surfactants and/or modifying agents. The working potential can be sensed during anodization using the counter electrode in a three-electrode configuration. The anodization can be performed in the presence of a DC or AC external field using the electrodes placed outside the reaction space.

In anodic etching, a voltage/current assisted etch of a semiconductor can result in etching of the semiconductor at a rate dependent on the voltage/current. The etch rate, etch depth, etch morphology, pore density, pore structure, internal surface area and surface roughness can be controlled by the voltage/current, etch solution/electrolyte composition and other additives, pressure/temperature, front/backside illumination, and stirring/agitation. They can also be controlled by the crystal orientation, dopant type, resistivity (doping concentration), and growth process (e.g., float-zone or Czochralski) of the semiconductor. The resistivity of the semiconductor can be at least about 0.001 ohm-cm, 0.01 ohm-cm, or 0.1 ohm-cm, and in some cases less than or equal to about 1 ohm-cm, 0.5 ohm-cm, 0.1 ohm-cm. In some examples, the resistivity of the semiconductor can be from about 0.001 ohm-cm to 1 ohm-cm, 0.001 ohm-cm to 0.5 ohm-cm, or 0.001 ohm-cm to 0.1 ohm-cm.

During etching of a semiconductor substrate using voltage/current control, a potential or bias (e.g., direct current bias) can be applied to the substrate using an underlying electrode. This can result in the semiconductor substrate being etched. As a result of anodic etching, the semiconductor's thermal conductivity can drop significantly. In some examples, by employing an applied bias, the porosity (mass loss) can be controlled and tuned and therefore the thermal and electrical properties can be controlled. In other examples, by employing a specific etch solution/electrolyte composition and/or additives the porosity can be controlled. In yet other examples, by employing any number of variables already listed, the porosity can be controlled.

In some cases, the semiconductor substrate may be unpatterned and in some cases it may be patterned. In an unpatterned etch, the substrate can be etched directly in the cell. In a patterned etch, a blocking layer that prevents etching can first be placed over the semiconductor, and then removed in specific locations. This layer may be formed in any manner suitable (e.g., chemical vapor deposition, spin-coating, oxidation) and then be removed in a subsequent step in desired locations (e.g., plasma etching, reactive ion etching, sputtering) using a suitable mask (e.g., photolithography). Alternatively, a blocking layer can be deposited directly (e.g., dip pen lithography, inkjet printing, spray coating through a stencil). Subsequently, a negative replica of the pattern in the blocking layer can be transferred into the substrate during the anodic etch.

The etch can be performed by applying an electrical potential (“potential”) to the semiconductor substrate, in the presence of a suitable etch solution/electrolyte. The potential can be, for example, at least about +0.01 V, +0.02 V, +0.03 V, +0.04 V, +0.05 V, +0.06 V, +0.07 V, +0.08 V, +0.09 V, +0.1 V, +0.2 V, +0.3 V, +0.4 V, +0.5 V, +0.6 V, +0.7 V, +0.8 V, +0.9 V, +1.0 V, +2.0 V, +3.0 V, +4.0 V, +5.0 V, +10 V, +20 V, +30 V, +40 V, or +50 V relative to a reference, such as ground. In some examples, the potential can be from about +0.01 V to +20 V, +0.1 V to +10 V, or +0.5 V to +5 V relative to a reference. In some examples, the potential can range from about +0.01 V to +0.05 V, +0.06 V to +0.1 V, +0.2 V to +0.5 V, +0.6 V to +1.0 V, +2.0 V to +5.0 V, +10 V to +20 V, +20V to +30 V, +30V to +40 V, or +40V to +50. In some examples, the potential can be from about +0.5 V to +5 V, or +1 V to +5 V.

The etch can be performed by applying or generating an electrical current (“current”) to or through the semiconductor substrate, in some cases in the presence of a suitable etch solution/electrolyte. The current can be applied to the substrate upon the application of the potential to the substrate. The current can have a current density, for example, of at least about +0.01 milliamps per square centimeter (mA/cm²), +0.1 mA/cm², +0.2 mA/cm², +0.3 mA/cm², +0.4 mA/cm², +0.5 mA/cm², +0.6 mA/cm², +0.7 mA/cm², +0.8 mA/cm², +0.9 mA/cm², +1.0 mA/cm², +2.0 mA/cm², +3.0 mA/cm², +4.0 mA/cm², +5.0 mA/cm², +6.0 mA/cm², +7.0 mA/cm², +8.0 mA/cm², +9.0 mA/cm², +10 mA/cm², +20 mA/cm², +30 mA/cm², +40 mA/cm², +50 mA/cm², +60 mA/cm², +70 mA/cm², +80 mA/cm², +90 mA/cm², +100 mA/cm², +200 mA/cm², +300 mA/cm², +400 mA/cm², +500 mA/cm², +600 mA/cm², +700 mA/cm², +800 mA/cm², +900 mA/cm², +1000 mA/cm². In some examples, the current density can range from about 0.01 mA/cm² to 20 mA/cm², 0.05 mA/cm² to 10 mA/cm², or 0.01 mA/cm² to 5 mA/cm². In some examples, the current density can range from about +0.1 mA/cm² to +0.5 mA/cm², +0.6 to +1.0 mA/cm², +1.0 mA/cm² to +5.0 mA/cm², +5.0 mA/cm² to +10 mA/cm², +10 mA/cm² to +20 mA/cm², +20 mA/cm² to +30 mA/cm², +30 mA/cm² to +40 mA/cm², +40 mA/cm² to +50 mA/cm², +50 mA/cm² to +60 mA/cm², +60 mA/cm² to +70 mA/cm², +70 mA/cm² to +80 mA/cm², +80 mA/cm² to +90 mA/cm², +90 mA/cm² to +100 mA/cm², +10 mA/cm² to +200 mA/cm², +20 mA/cm² to +300 mA/cm², +300 mA/cm² to +400 mA/cm², +40 mA/cm² to +500 mA/cm², +500 mA/cm² to +600 mA/cm², +600 mA/cm² to +700 mA/cm², +700 mA/cm² to +800 mA/cm², +800 mA/cm² to +900 mA/cm², or +900 mA/cm² to +1000 mA/cm². In some examples, the current density can be from about 1 mA/cm² to 30 mA/cm², 5 mA/cm² to 25 mA/cm², or 10 mA/cm² to 20 mA/cm². Such current densities may be achieved with potential provided herein, such as a potential from about +0.5 V to +5 V, or +1 V to +5 V.

The electrical potential (or voltage) can be measured using a voltmeter, for instance. The voltmeter can be in parallel with the substrate. For example, the voltmeter can measure the electrical potential between two sides of the substrate, or the electrical potential between a working electrode and counter electrode in solution. The current density can be measured using an ammeter. The ammeter can be in series with a power source and the substrate. For example, the ammeter can be coupled to a backside of the substrate.

Thermoelectric elements of the present disclosure can be formed at an etching time that is selected to provide an array of nanostructures (e.g., holes or wires). Etching times can range from 1 second to 2 days, 1 minute to 1 day, 1 minute to 12 hours, 10 minutes to 6 hours, or 30 minutes to 3 hours. In some examples, the etching time can be from 30 minutes to 6 hours, or 1 hour to 6 hours. In some cases, etching times can be at least about 1 second, 10 seconds, 30 seconds, 1 minute, 2 minutes, 3 minutes, 4 minutes, 5 minutes, 10 minutes, 30 minutes, 1 hour, 2 hours, 3 hours, 4 hours, 5 hours, 6 hours, 12 hours, or 1 day. Such etching times can be used in combination with applied voltage and/or current of the present disclosure.

In some cases, the bias applied to the semiconductor substrate can be changed during etching to regulate the etch rate, etch depth, etch morphology, pore density, pore structure, internal surface area and surface roughness of the semiconductor substrate, including the density and location of nanostructuring in the semiconductor substrate. In some cases, the etch solution/electrolyte composition and/or additives can be changed during etching. In some cases, the pressure/temperature or illumination or stirring/agitation can be changed. Alternatively, more than one of these variables may be changed simultaneously to obtain the desired etch characteristics.

During the period in which the substrate is etched, the electrical potential can be constant, varied or pulsed. In an example, the electrical potential is constant during the etching period. In another example, the electrical potential is pulsed on and off, or from positive to negative, during the etching period. In another example, the electrical potential is varied during the etching period, such as varied gradually from a first value to a second value, which second value can be less than or greater than the first value. The electrical potential can then be varied from the second value to the first value, and so on. In yet another example, the bias/current may be oscillated according to a sinusoidal/triangular/arbitrary waveform. In some cases, the bias/current can be pulsed with a frequency of at least about 0.001 cycles per second (Hertz (Hz)), 0.01 Hz, 0.1 Hz, 1 Hz, 10 Hz, 1000 Hz, 5000 Hz, 10000 Hz, 50000 Hz, or 100000 Hz.

Moreover, the substrate may be electrochemically etched at a constant current density. Etching at a constant current density can yield a porous structure with uniform pore width. Moreover, in cases where etching proceeds to larger depths, the pore widths may increase as a function of depth, reducing the uniformity of the material. In such cases, etching may be performed with a decreasing current density to compensate for the increase in pore width. In some cases, a pulsed current density can be applied to the substrate with set on and off times. A pulsed current density strategy can minimize the potential for an uneven etch, including an uneven etch that comes with increased depth. Moreover, a periodic current density waveform may be applied to a substrate during etching to form a structure with multiple layers of alternating porosities. For example, a square waveform (e.g., producing a Bragg stack), a sinusoidal waveform (e.g., producing a rugate), or a combination may be utilized.

The bias and/or current can be DC or AC, or a combination of DC and AC. Use of an AC bias and/or current with DC offset can provide control over the etch rate using the DC bias/current and control over ions using the AC bias/current. The AC bias/current can alternately enhance and retard the etch rate, or increase/decrease the porosity/surface roughness, or modify the morphology and structure in a periodic or non-periodic fashion. The amplitude and frequency of the AC bias/current can be used to tune the etch rate, etch depth, etch morphology, pore density, pore structure, internal surface area and surface roughness.

In some situations, the application of an electrical potential to a semiconductor substrate during etching can provide for a given etch rate. In some examples, the substrate can be etched at a rate of at least about 0.1 nanometers (nm)/second (s), 0.5 nm/s, 1 nm/s, 2 nm/s, 3 nm/s, 4 nm/s, 5 nm/s, 6 nm/s, 7 nm/s, 8 nm/s, 9 nm/s, 10 nm/s, 20 nm/s, 30 nm/s, 40 nm/s, 50 nm/s, 60 nm/s, 70 nm/s, 80 nm/s, 90 nm/s, 100 nm/s, 200 nm/s, 300 nm/s, 400 nm/s, 500 nm/s, 600 nm/s, 700 nm/s, 800 nm/s, 900 nm/s, 1000 nm/s, or 10,000 nm/s at 25° C. In other cases, the etch rate may be increased/decreased with a change in pressure/temperature, solution/electrolyte composition and/or additives, illumination, stirring/agitation.

The porosity of a semiconductor substrate during etching using an applied potential or current density can provide a substrate with a porosity (mass loss) that can provide a thermoelectric element that is suitable for various applications. In some examples, the porosity can be at least about 0.01%, 0.1%, 1%, 5%, 10%, 20%, 30%, 40%, 50%, or 60%. The porosity can be from about 0.01% to 99.99%, 0.1% to 60%, or 1% to 50%. In some cases, an applied current density can control substrate porosity.

A substrate can have a thickness that is selected to yield a thermoelectric element that is suitable for various applications. The thickness can be at least about 100 nanometers (nm), 500 nm, 1 micrometer (micron), 5 microns, 10 microns, 100 microns, 500 microns, 1 millimeter (mm), or 10 mm. In some examples, the thickness can be from about 500 nm to 1 mm, 1 micron to 0.5 mm, or 10 microns to 0.5 mm.

The etch may be performed to completion through the entire thickness of the substrate, or it may be stopped at any depth. A complete etch can yield a self-supporting nanostructured material with no underlying unetched substrate. An incomplete etch can yield a layer of nanostructured material over underlying unetched substrate. The nanostructured layer may have a thickness at least about 10 nanometers (nm), 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 micrometers (μm), 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, 600 μm, 700 μm, 800 μm, 900 μm, 1 millimeters (mm), 2 millimeters (mm), 3 millimeters (mm), 4 millimeters (mm), 5 millimeters (mm), 6 millimeters (mm), 7 millimeters (mm), 8 millimeters (mm), 9 millimeters (mm), 10 millimeters (mm) or more. In some cases, the thickness of the nanostructured layer is controlled by the duration of etching. Longer etching times, for example, can result in larger nanostructured layer thicknesses.

The nanostructured layer may be left on the substrate, or it may be separated from the substrate in a number of ways. The layer may be mechanically separated from the substrate (e.g., using a diamond saw, scribing and cleaving, laser cutting, peeling off). Alternatively, the layer can be separated from the substrate by effecting electropolishing conditions at the etching front at the base of the layer. These conditions can be achieved by a change in pressure, change in temperature, change in solution composition, change in electrolyte composition, use of additives, illumination, stirring, and/or agitation, or by waiting a sufficient duration of time (e.g., more than about 1 day). In some cases, a partial or incomplete separation may be desired, such that the layer is still weakly attached to the substrate. This can be achieved by varying between normal etching conditions and electropolishing. Complete separation can then be achieved in a subsequent operation.

After etching, the material may be chemically modified to yield functionally active or passive surfaces. For example, the material may be modified to yield chemically passive surfaces, or electronically passive surfaces, or biologically passive surfaces, or thermally stable surfaces, or a combination of the above. This can be accomplished using a variety of methods with non-limiting examples of such methods that include: (1) thermal oxidation; (2) thermal silanation; (3) thermal carbonization; (4) hydrosilylation; (5) Grignard reagents; and (6) electrografting. In some cases, one or more of the above methods may be used to obtain a surface with the desired or otherwise predetermined combination of properties.

After modification, the voids in the material may also be fully or partially impregnated with a filling material. For example, the filling material may be electrically conductive, or thermally insulating, or mechanically strengthening, or a combination of the above. Suitable filling materials may include one or more of the following groups: insulators, semiconductors, semimetals, metals, polymers, gases, or vacuum. Filling can be accomplished using a variety of methods, e.g., atomic layer deposition, chemical vapor deposition, deposition from chemical bath or polymerization bath, electrochemical deposition, drop casting or spin coating or immersion followed by evaporation of a solvated filling material. In some cases, one or more of the above methods may be used to obtain filling materials with the desired combination of properties.

After filling, the material may also be sealed with a capping material. For example, the capping material may be impermeable to gases, or liquids, or both. Suitable filling materials may include one or more of the following groups: insulators, semiconductors, semimetals, metals or polymers. Capping can be accomplished using a variety of methods, e.g., atomic layer deposition, chemical vapor deposition, deposition from chemical bath or polymerization bath, electrochemical deposition, drop casting or spin coating or immersion followed by evaporation of a solvated filling material. In some cases, one or more of the above methods may be used to obtain capping materials with the desired or predetermined combination of properties.

A material surface can be sealed via one or more structural change(s) made in the material, whereby sealing of the material surface achieves or improves stability of the electrical, thermal and thermoelectric properties of the material. In some cases, the material can be sealed with the aid of light, such as via laser or UV lamp flash annealing. Non-limiting examples of a suitable light source for sealing include an excimer, a solid state diode, a laser (e.g., a CO₂ gas laser) and an ultraviolet (UV) lamp. A light source may also include or be coupled to one or more optical components that are capable of manipulating and/or concentrating source light into a suitable beam. A light source may heat the material surface to any suitable temperature (e.g., at least about 100° C., at least about 200° C., at least about 300° C., at least about 400° C., at least about 500° C., at least about 600° C., at least about 700° C., at least about 800° C., at least about 900° C., at least about 1000° C., at least about 1100° C., at least about 1200° C., at least about 1300° C., at least about 1400° C., at least about 1500° C., or higher) with any suitable penetration depth (e.g., at least about 1 nanometer (1 nm), at least about 50 nm, at least about 100 nm, at least about 500 nm, at least about 1 micrometer (μm), at least about 10 μm, at least about 100 μm, or deeper).

After etching, the material can be washed with a suitable rinsing solution (e.g., water, methanol, ethanol, isopropanol, toluene, hexanes etc.) and dried (e.g., blow drying, evaporative drying, oven/furnace drying, vacuum drying, critical point drying, or air drying). The rinsing solution can be selected depending on the mode of drying.

After etching, the material may be doped through the application of a doping substance that can increase the conductivity of the material. Doping can take place before, after, or concurrent with any surface modification(s) that is completed, including those types of surface modifications described elsewhere herein. The doping may be n-type or p-type. For n-type doping, doping substances may include n-type spin-on glass (SOG) or spin-on dopants (SOD), primary, secondary, and tertiary amines and amine oxides, primary, secondary, and tertiary phosphines and phosphine oxides, phosphoric acid and its salts, phosphorus pentoxide, phosphorus pentachloride, primary, secondary, and tertiary arsines and arsine oxides, and arsenic acid, in pure form or dissolved in a suitable solvent. For p-type doping, doping substances may include p-type spin-on glass (SOG) or spin-on dopants (SOD), primary, secondary, and tertiary boranes (e.g., BCl₃, BBr₃), alkali and alkali earth borate salts, boric acid, and sodium borohydride in pure form or dissolved in a solvent. A doping substance may be applied to the material via any suitable method(s), with non-limiting examples that include spin-coating, casting, brushing and chemical vapor deposition. After application of the doping substance, the material can be annealed via heating (e.g., at a temperature of between 200 and 1200° C.) for a suitable time (e.g., for at least about 1 second, at least about 1 minute, at least about 30 minutes, at least about 1 hour, at least about 6 hours, at least about 12 hours) under an atmosphere comprising one or more of air, oxygen, nitrogen, forming gas, hydrogen or can be incubated in a vacuum. In some cases, a material may be subject to multiple annealing cycles. After annealing, excess dopant may be removed.

After anodic etching, the thermal and electrical properties of the semiconductor may be further controlled or tuned by coarsening or annealing the semiconductor nanostructure (e.g., pore or hole morphology, density, structure, internal surface area and surface roughness) through the application of heat and time. Temperatures between about 50° C. and 1500° C., or 100° C. and 1300° C. for a time period from about 1 second to 1 week can be utilized to control the thermal and electrical properties of the semiconductor. In some cases, the time period is at least about 1 second, 10 seconds, 30 seconds, 1 minute, 2 minutes, 3 minutes, 4 minutes, 5 minutes, 10 minutes, 30 minutes, 1 hour, 2 hours, 3 hours, 4 hours, 5 hours, 6 hours, 12 hours, or 1 day. The annealing may be performed in vacuum (e.g., at a pressure that is from about 1×10⁻¹⁰ Torr to <760 Torr) or in the presence of a suitable gas (e.g., helium, neon, argon, xenon, hydrogen, nitrogen, forming gas, carbon monoxide, carbon dioxide, oxygen, water vapor, air, methane, ethane, propane, sulfur hexafluoride and mixtures thereof). The gas can be an inert gas. Annealing can be performed on partially or completely etched substrates, completely separated etched layers on unetched substrates, partially separated etched layers on unetched substrates, or unseparated etched layers on unetched substrates. In some cases, when layers on unetched substrates are annealed, the semiconductor coarsening may proceed in such a fashion as to separate the layers from the unetched substrate. This can be convenient for effecting layer separation.

One or more layers of the semiconductor material may be annealed and/or thermally treated during fabrication. In some cases, the annealing and/or thermal treatment can be used to create thermal stress in the semiconductor. In some cases, the thermal stress can form defects and/or dislocations in the material. In some cases, the thermal stress can form defects and/or dislocation in the material for the purpose of reducing the thermal conductivity of the semiconductor. In some cases, the thermal stress can form defects and/or dislocation in the material for the purpose of reducing the thermal conductivity of the semiconductor without affecting the electrical resistivity and Seebeck coefficient of the material. In some cases, the semiconductor material can be annealed and/or thermally treated with the aid of light, such as via processing with a laser. In some cases, a laser may be used to create thermal stress in the semiconductor material to form defects and/or dislocations, for the purpose of reducing the thermal conductivity of the semiconductor, without affecting the electrical resistivity and Seebeck coefficient of the material. In cases where the light source is a laser, the laser may be a pulsed laser, or it may be a continuous wave (CW) laser. In cases where the light source is a laser, the power of the laser can be equal to or least about 1 Watt (W), 5 W, 10 W, 15 W, 20 W, 25 W, 30 W, 35 W, 40 W, 45 W, 50 W, 55 W, 60 W, 65 W, 70 W, 75 W, 80 W, 85 W, 90 W, 95 W, or 100 W. In some examples, the power of the laser can be from about 10 W to 100 W, 20 W to 80 W, 20 W to 50 W, or 20 W to 40 W. In cases where the light source is a laser, the percentage of the rated power of the laser used can be equal to or least about 5%, 10%, 15%, 20%, 25%, 30%, 35%, 40%, 45%, 50%, 55%, 60%, 65%, 70%, 75%, 80%, 85%, 90%, 95%, or 100%. In some examples, the percentage of the rated power of the laser used can be from about 10% to 90%, 10% to 60%, 10% to 40%, or 10% to 20%. In cases where the light source is a laser, the wavelength of the laser can be equal to or at least about 100 nanometers (nm), 200 nm, 300 nm, 400 nm, 500 nm, 600 nm, 700 nm, 800 nm, 900 nm, 1 micrometer (μm), 2 μm, 3 μm, 4 am, 5 μm, 6 μm, 7 μm, 8 μm, 9 μm, 10 μm, 11 μm, 12 μm, 13 μm, 14 μm, 15 μm, 16 μm, 17 am, 18 μm, 19 μm or 20 μm. In some examples, the wavelength of the laser can range from about 500 nm to 15 μm, 800 nm to 12 μm, or 900 nm to 11 μm. In cases where the light source is a laser, the beam size of the laser may be equal to or at least about 0.1 millimeter (mm), 1 mm, 2 mm, 3 mm, 4 mm, 5 mm, 6 mm, 7 mm, 8 mm, 9 mm, or 10 mm. In some examples, the beam size of the laser can range from about 0.1 mm to 10 mm, 1 mm, to 10 mm, 1 mm to 8 mm, 2 mm to 6 mm, or 4 mm to 6 mm. In cases where the light source is a laser, the scanning speed of the laser may be equal to or at least about 0.01 millimeters per second (mm/sec), 0.1 mm/sec, 0.2 mm/sec, 0.5 mm/sec, 1 mm/sec, 10 mm/sec, 20 mm/sec, 30 mm/sec, 40 mm/sec, 50 mm/sec, 60 mm/sec, 70 mm/sec, 80 mm/sec, 90 mm/sec, or 100 mm/sec. In some examples, the scanning speed of the laser can range from about 0.01 mm/sec to 100 mm/sec, 0.01 mm/sec to 50 mm/sec, 0.1 mm/sec to 10 mm/sec, or 0.01 mm/sec to 1 mm/sec. In cases where the light source is a pulsed laser, the frequency of the pulsed laser may be equal to or at least about 1 KHz, 2 KHz, 5 KHz, 10 KHz, 20 KHz, 50 KHz, 75 KHz, 100 KHz, 125 KHz, 150 KHz, 175 KHz, or 200 KHz. In some examples, the frequency of the pulsed laser can range from about 1 KHz to 200 KHz, 1 KHz to 100 KHz, 10 KHz to 100 KHz, 10 KHz to 50 KHz, or 10 KHz to 30 KHz. In cases where the light source is a laser, the penetration depth of the laser into the material may be equal to or at least about 1 nanometer (nm), 2 nm, 5 nm, 10 nm, 50 nm, 100 nm, 200 nm, 300 nm, 400 nm, 500 nm, 1 micrometer (μm), 10 μm, 100 μm, 200 μm, 300 μm, 400 μm, or 500 μm. In some examples, the penetration depth of the laser into the material can range from about 1 nm to 500 μm, 1 nm to 400 μm, 1 nm to 300 μm, 1 nm to 200 μm, 1 nm to 100 μm, 10 nm to 100 μm, or 10 nm to 50 μm. The semiconductor material undergoing the annealing and/or thermal treatment may have a thickness equal to or at least about 1 micrometer (μm), 10 μm, 50 μm, 100 am, 150 μm, 200 μm, 250 μm, 300 μm, 350 μm, 400 μm, 450 μm, or 500 μm. In some examples, the thickness of the semiconductor material undergoing the annealing and/or thermal treatment may have a thickness ranging from about 1 μm to 500 μm, 10 μm to 500 μm, or 100 am to 500 μm. The semiconductor material undergoing the annealing and/or thermal treatment may attain a temperature during processing equal to or at least about 100° C., 200° C., 300° C., 400° C., 500° C., 600° C., 700° C., 800° C., 900° C., 1000° C., 1100° C., 1200° C., 1300° C., 1400° C., or 1500° C. The process of annealing and/or thermal treatment, in some cases via a light source, and in some cases wherein the light source is a laser, may decrease the thermal conductivity of the semiconductor material by an amount equal to or at least about 0.1 W/mK, 0.2 W/mK, 0.5 W/mK, 1 W/mK, 2 W/mK, 3 W/mK, 4 W/mK, 5 W/mK, 6 W/mK, 7 W/mK, 8 W/mK, 9 W/mK, or 10 W/mK. In some examples, the decrease in thermal conductivity of the semiconductor material may decrease in a range of about 0.1 W/mK to 10 W/mK, 1 W/mK to 10 W/mK, 2 W/mK to 8 W/mK, or 3 W/mK to 6 W/mK.

Electrical contacts may be deposited on or adjacent to the nanostructured material using standard deposition techniques (e.g., silk-screening, inkjet deposition, painting, spraying, dip-coating, soldering, metal sputtering, metal evaporation). These may be metal contacts (e.g., gold, silver, copper, aluminum, indium, gallium, lead-containing solder, lead-free solder or combinations thereof) with/without suitable adhesion layers (e.g., titanium, chromium, nickel or combinations thereof). Alternatively, they may be silicide contacts (e.g., titanium silicide, cobalt silicide, nickel silicide, palladium silicide, platinum silicide, tungsten silicide, molybdenum silicide etc.). Barrier layers (e.g., platinum, palladium, tungsten nitride, titanium nitride, molybdenum nitride etc.) may be inserted to prevent inter-diffusion between the silicon and the contact, or between contact layers, or between every layer. In other examples, they may be combinations of both metal and silicide contacts. A silicide contact can be provided to reduce contact resistance between a metal contact and the substrate. Examples of silicides include tungsten silicide, titanium disilicide and nickel silicide. A subsequent annealing step may be used to form the contact and improve its properties. For example annealing can reduce contact resistance, which can provide an ohmic contact. In some cases, prior to forming an electrical contact or contacts, a material on which contacts are later formed may be treated with a plasma tool (e.g., a plasma tool flowing O₂ or H₂O), and, in some cases, followed by a chemical etch (e.g., in hydrofluoric acid (HF)) to clean the surface of the material.

After electrical contacts have been formed, the material can be assembled into a thermoelectric device comprising of p- and n-type thermoelectric elements (or legs). A thermoelectric device can include p- and n-legs connected electrically in series, and thermally in parallel with each other. They can be built upon electrically insulating and thermally conductive rigid plates (e.g., aluminum nitride, aluminum oxide, silicon carbide, silicon nitride etc.) with electrical connections between the legs provided by metal interconnects (e.g., copper, aluminum, gold, silver etc.). In another example, the thermoelectric material may be assembled on a flexible insulating material (e.g., polyimide, polyethylene, polycarbonate etc.). Electrical connections between the legs can be provided via metal interconnects integrated on the flexible material. The resulting thermoelectric may be in sheet, roll or tape form. Desired sizes of thermoelectric material may be cut out from the sheet, roll or tape and assembled into devices.

Processing conditions (e.g., applied voltages and current densities) provided herein have various unexpected benefits, such as the formation of nanostructures (e.g., holes) having orientations and configurations that provide thermoelectric elements and devices of the present disclosure with enhanced or otherwise improved properties, such as a thermoelectric element with a ZT from about 0.01 to 3, 0.1 to 2.5, 0.5 to 2.0 or 0.5 to 1.5 at 25° C. Such processing conditions can provide for the formation of an array nanostructures in a substrate. The array of nanostructures can have a disordered pattern. Such processing conditions can provide for the formation of flexible thermoelectric elements or devices.

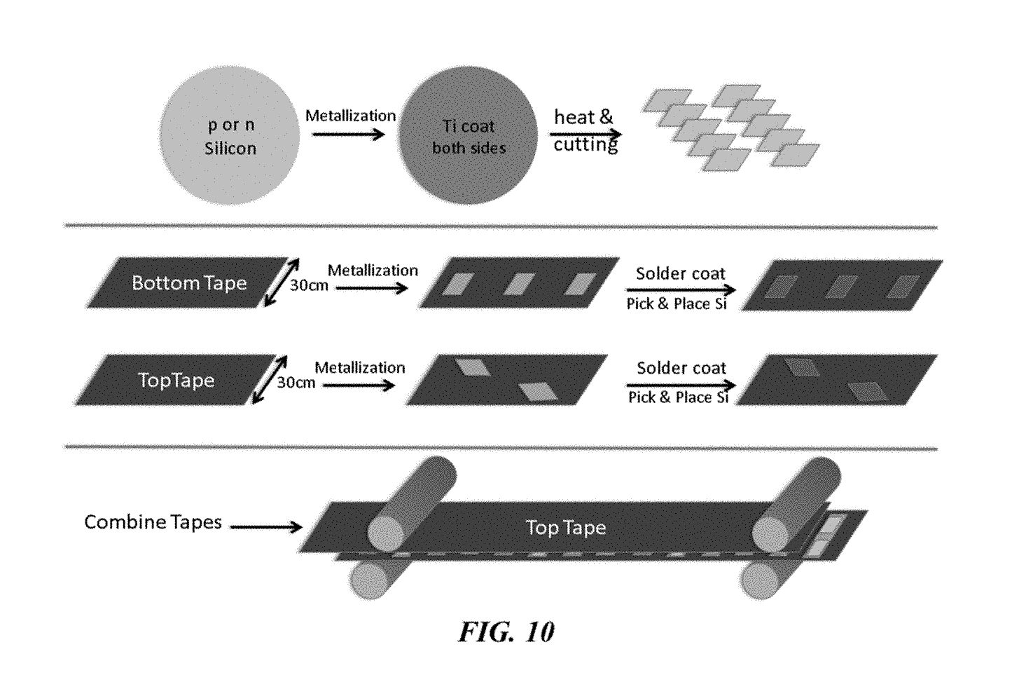

FIG. 10 schematically illustrates a method for manufacturing a flexible thermoelectric device comprising a plurality of thermoelectric elements. A p-type or n-type silicon substrate that has been processed using, for example, a non-catalytic approach described elsewhere herein (e.g., anodic etching) can be coated on both sides with a suitable contact material, such as titanium, nickel, chromium, tungsten, aluminum, gold, platinum, palladium, or any combination thereof. The substrate can then be heated to a temperature of at least about 250° C., 300° C., 350° C., 400° C., 450° C., 500° C., 550° C., 600° C., 650° C., 700° C., 750° C., 800° C., 850° C., 900° C., 950° C., or 1000° C., and cut into multiple pieces using, for example, a diamond cutter, wire saw, or laser cutter.

Next, in a metallization operation, individual pieces of the cut substrate can be placed on bottom and top tapes having widths of about 30 centimeters (cm). The tapes can be formed of a polymeric material, such as, for example, polyimide, polycarbonate, polyethylene, polypropylene, or copolymers, mixtures and composites of these and other polymers.

Next, the individual pieces can be subjected to solder coating to form serial connections to the individual pieces across a given tape. The tapes can then be combined through one or more rollers (two rollers are illustrated). A thermally conductive adhesive can be provided around the tables to help seal the individual pieces between the tapes.

Thermoelectric elements, devices and systems formed according to methods provided herein can have various physical characteristics. The performance of a thermoelectric device of the disclosure may be related to the properties and characteristics of holes and/or wires of thermoelectric elements. In some cases, optimum device performance may be achieved for an element having holes or wires, an individual hole or wire having a surface roughness between about 0.1 nm and 50 nm, or 1 nm and 20 nm, or 1 nm and 10 nm, as measured by transmission electron microscopy (TEM). In some cases, a thermoelectric element may have a residual metal content that is less than or equal to about 0.000001%, 0.00001%, 0.0001%, 0.001%, 0.01%, 0.1%, 1%, 5%, 10%, 15%, 20%, or 25%, as measured by x-ray photoelectron spectroscopy (XPS).

A thermoelectric element of the present disclosure may have a surface roughness that is suitable for optimized thermoelectric device performance. In some cases, the root mean square roughness of a hole or wire can be between about 0.1 nm and 50 nm, or 1 nm and 20 nm, or 1 nm and 10 nm. The roughness can be determined by transmission electron microscopy (TEM) or other surface analytical technique, such as atomic force microscopy (AFM) or scanning tunneling microscopy (STM). The surface roughness may be characterized by a surface corrugation.

### Uses of Thermoelectric Elements

Thermoelectric elements, devices and systems of the present disclosure can be employed for use in various settings or employed for various uses. Settings can include, without limitation, healthcare, consumer, and industrial settings. Such uses include, without limitation, flexible thermoelectric tape with flexible heat sinks, wearable electronic devices powered by body heat, waste heat recovery units for generating power (e.g., waste heat recovery unit in a vehicle or chemical plant) and communication with another electronic device (e.g., transmission or receipt of wireless communication to/from another electronic device).

In some cases, an electronic device described herein may be wearable, or capable of attachment to an animate object. In other cases, an electronic device described herein may be attached to, or incorporated into an inanimate object. In general, an electronic device described herein may be attached to an object that is generating heat, or that is in proximity to a heat source or thermal gradients.

An electronic device described herein may be powered solely or partially by heat (e.g., power generated from heat), or may be powered from a battery or other energy storage, or may switch between power sources, or powered using various combinations of power sources (e.g., thermoelectric and battery). In some cases, an electronic device described herein may report its location (e.g., to correlate, control or direct passage of the electronic device through physical locations), take and/or report measurements on the ambient environment, or measure and/or report other information. A device may also be used to display notifications or otherwise communicate information to a user. In some cases, an electronic device described herein, may be used to store an identity and/or other identifying information (e.g., addresses, phone numbers, credit card numbers, etc.). In some cases, an electronic device described herein may receive identity information from a remote computer system (e.g., accessible via a network, such as a wireless network/cellular network) and transmit a search query or other data to the remote computer system to search a database, and/or exchange other information with a remote computer system. The electronic device may also be capable of receiving data from the remote computer system.

For example, an electronic device described herein may be worn by a subject in a healthcare setting. Such an electronic device can store patient identity information, medical information (disease information, diagnosis information, treatment information, prescription information, patient alerts, etc.) and/or other any other medically-relevant information. In some cases, such an electronic device may provide a search query or transmit (e.g., via a computer network, such as a wireless network) data stored on the electronic device to a remote database that retrieves (e.g., via a computer network, such as a wireless network) medical records, medical information etc. Such an electronic device may also report its location, which location may then be used to correlate, control or direct passage of the patient through a healthcare facility.

In another example, an electronic device described herein may be worn by a subject in a conference setting. Such an electronic device can store conference participant identity information, affiliation (e.g., work-place, academic affiliation, interest-group affiliation, church-affiliation, etc.), participant field-of-expertise, a participant's conference schedule, and/or any other relevant information. In some cases, such an electronic device may provide a search query or transmit data stored on the electronic device to a remote database that retrieves (e.g., via a computer network, such as a wireless network) other participant information, participant records, etc and transmits (e.g., via a computer network, such as a wireless network) such information back to the electronic device. Such an electronic device may also report its location, which location may then be used to correlate, control or direct passage of the participant through a conference venue or facility.

A heat sink can aid in collecting or dissipating heat. A heat sink can include one or more heat fins which can be sized and arranged to provide increase heat transfer area.

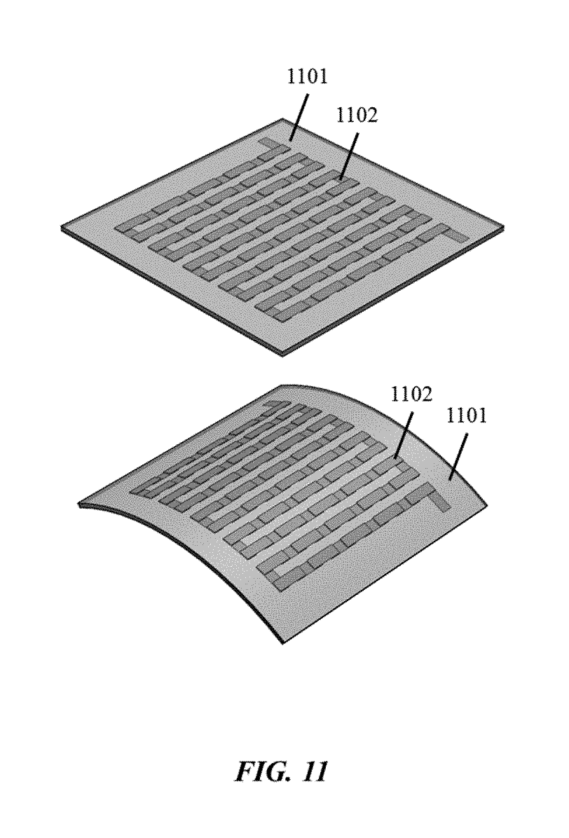

FIG. 11 shows a flexible thermoelectric device 1101. The flexible thermoelectric device 1101 can include thermoelectric elements 1102 in a serial configuration (see, e.g., FIG. 1). The flexible thermoelectric device can have a Young's Modulus that is less than or equal to about 30×10⁶ pounds per square inch (psi), 20×10⁶ psi, 10×10⁶ psi, 5×10⁶ psi, 2×10⁶ psi, 1×10⁶ psi, 900,000 psi, 800,000 psi, 700,000 psi, 600,000 psi, 500,000 psi, 400,000, 300,000, or 200,000 psi at 25° C. The Young's Modulus can be measured by static deflection of the thermoelectric element. The Young's Modulus can be measured by a tensile test.

In some cases, a flexible thermoelectric device can be used with heat sinks and electrical interconnects. The device can be in the shape of a tape, film or sheet form. The device can be substantially flat and flexible, which can enable the device to have increased contact surface area with a surface.

A heat sink may be any flexible material, which can be sufficiently thermally conductive to provide low internal thermal resistance and sufficiently thin to bend in a flexible manner. In some cases, a heat sink can have a thickness from about 0.1 millimeters (mm) to 100 mm, or 1 mm to 10 mm. The heat sink can include thermoelectric elements provided herein within or in contact with a matrix or substrate. The matrix or substrate can be a polymer foil, elastomeric polymer, ceramic foil, semiconductor foil, insulator foil, insulated metal foil or combinations thereof. To increase the surface area presented to the environment for effective thermal transfer, the matrix or substrate may be patterned with dimples, corrugations, pins, fins or ribs.

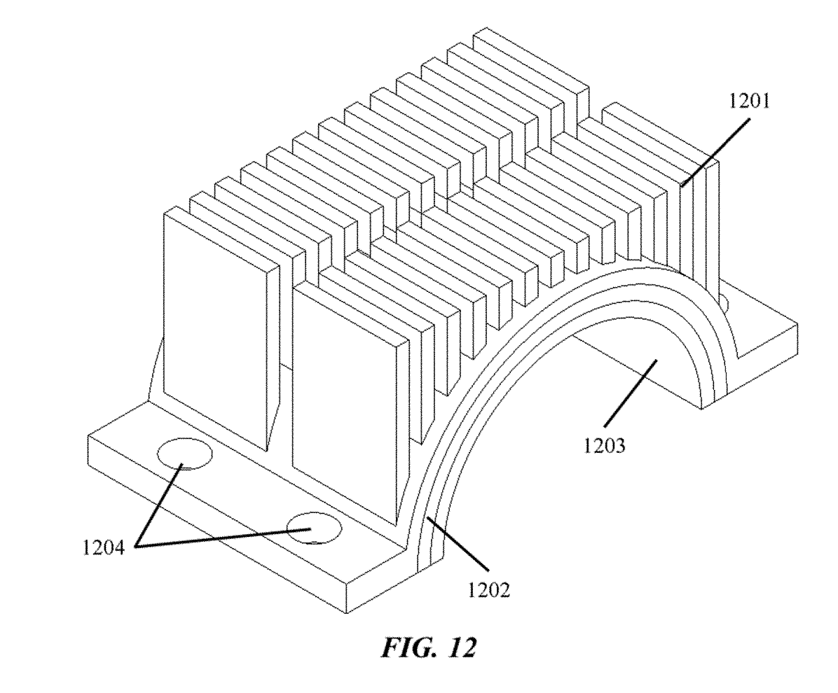

FIG. 12 shows a heat sink 1201 and a thermoelectric device 1202 with thermoelectric material adjacent to the heat sink 1201. The thermoelectric material can include thermoelectric elements disclosed herein. The thermoelectric device 1202 can be adjacent to a mating surface 1203, which can be used to mate with an object, such as, for example, a pipe or an electronic device (e.g., computer processor). The thermoelectric material can be flexible and able to conform to the shape of the molding surface. The heat sink 1201 can include attachment members 1204 that can enable the heat sink 1201 to be secured to the object.

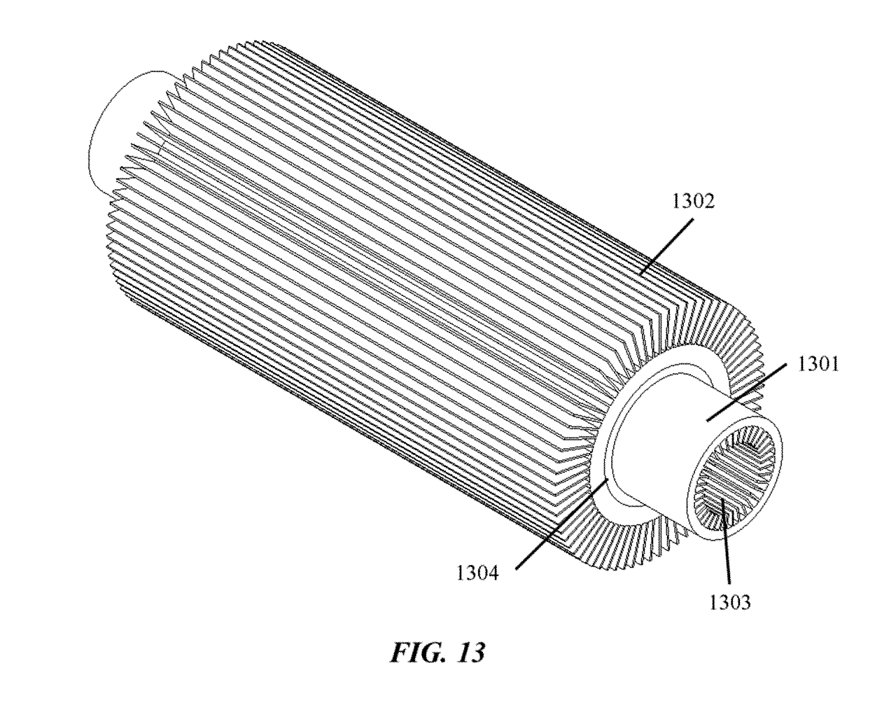

Heat sinks with integrated or standalone thermoelectric devices can be used with other objects, such as objects with surfaces that can provide for a temperature gradient. For example, heat sinks can be used with tubes, which may be employed in various settings, such as industrial settings. FIG. 13 shows a weldable tube 1301 with an integrated thermoelectric device and heat sinks. A cold side heat sink 1302 may be situated at an exterior of the tube 1301 and a hot side heat sink 1303 may be situated at an interior of the tube 1301. The tube 1301 can be formed of a metallic or metal-containing material. A thermoelectric device 1304 comprising a thermoelectric material may be disposed at an exterior of the tube, between the tube and the cold side heat sink.

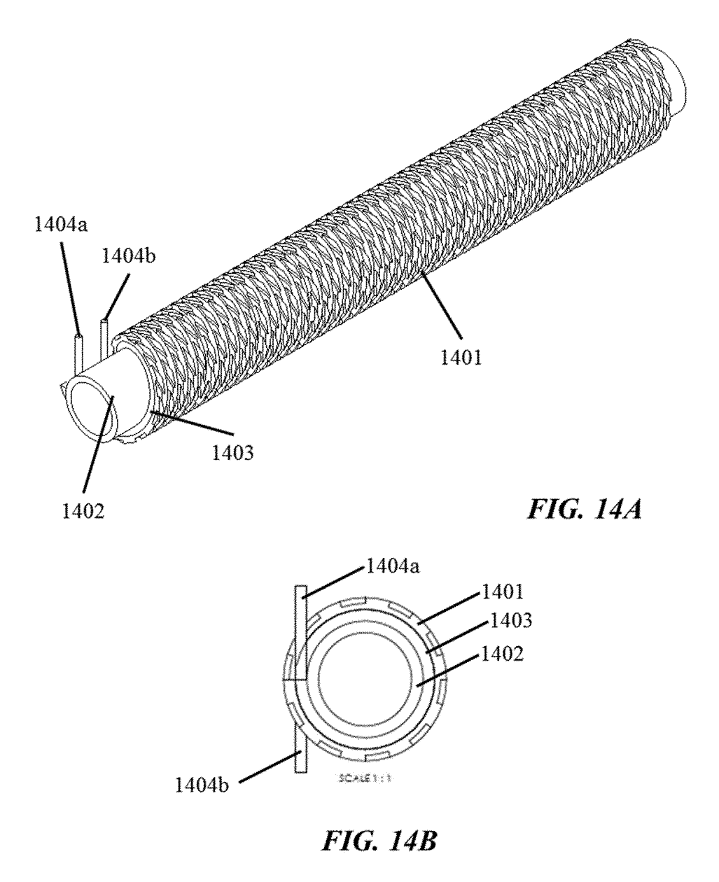

FIGS. 14A and 14B show a flexible heat sink 1401 wrapped around an object 1402, which can be, for example, a pipe carrying a hot or cold fluid. FIG. 14B is a cross-sectional side view of FIG. 14A. The heat sink can include thermoelectric elements in a thermoelectric device layer 1403, which can include thermoelectric elements provided herein. The object 1402 can have a hot or cold surface, which can be situated adjacent to a side of the thermoelectric device layer 1403. An opposing side of the thermoelectric device layer can be situated adjacent to an environment that is hotter or colder than the surface, thereby providing a temperature differential. The thermoelectric elements can be in electrical communication as described herein (see, e.g., FIG. 1) and in electrical communication with electrical wires 1404a and 1404b which may be disposed at an end of the thermoelectric device layer 1403.

As an alternative, the heat sink can be separate from the thermoelectric device layer. The thermoelectric device layer can be in the form of a tape, which can be wrapped around an object. The heat sink can be subsequently applied to the thermoelectric device layer.

The thermoelectric device may have both sides attached to heat sinks, or have only one side attached to a heat sink, or have neither side attached to a heat sink. The thermoelectric device may have both sides coated with adhesive, or have only one side coated with adhesive, or have neither side coated with adhesive. The adhesive can permit the thermoelectric device to be securely coupled to an object and/or one or more heat sinks. The adhesive can be sufficiently thermally conductive.

Heat sink substrates or matrixes may be any flexible electrically insulating material, which can be thin enough to present a low thermal resistance. Examples include polymer foil (e.g., polyethylene, polypropylene, polyester, polystyrene, polyimide, etc.); elastomeric polymer foil (e.g., polydimethylsilazane, polyisoprene, natural rubber, etc.); fabric (e.g., conventional cloths, fiberglass mat, etc.); ceramic, semiconductor, or insulator foil (e.g., glass, silicon, silicon carbide, silicon nitride, aluminum oxide, aluminum nitride, boron nitride, etc.); insulated metal foil (e.g., anodized aluminum or titanium, coated copper or steel, etc.); or combinations thereof. The substrate can be both flexible and stretchable when an elastomeric material is used.

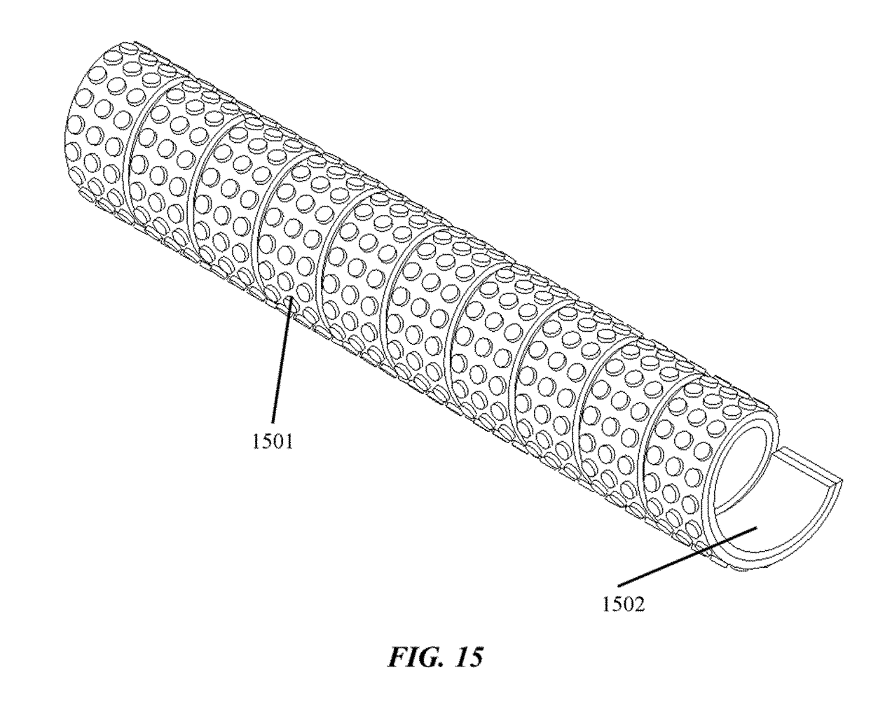

FIG. 15 shows a flexible thermoelectric tape with an integrated heat sink. The tape includes a flexible heat sink 1501 and a thermoelectric material 1502 adjacent to the heat sink. The heat sink 1501 may include a pattern of dimples, which can provide for improved surface area for heat transfer. The tape can include electrical wires that are coupled to electrodes of the thermoelectric material 1502. The wires can be situated at an end of the tape.

The tape can be applied to various objects, such as planar or non-planar objects. In an example, the tape is wrapped around a pipe. The tape can be supplied from a roll and applied to an object from the roll.

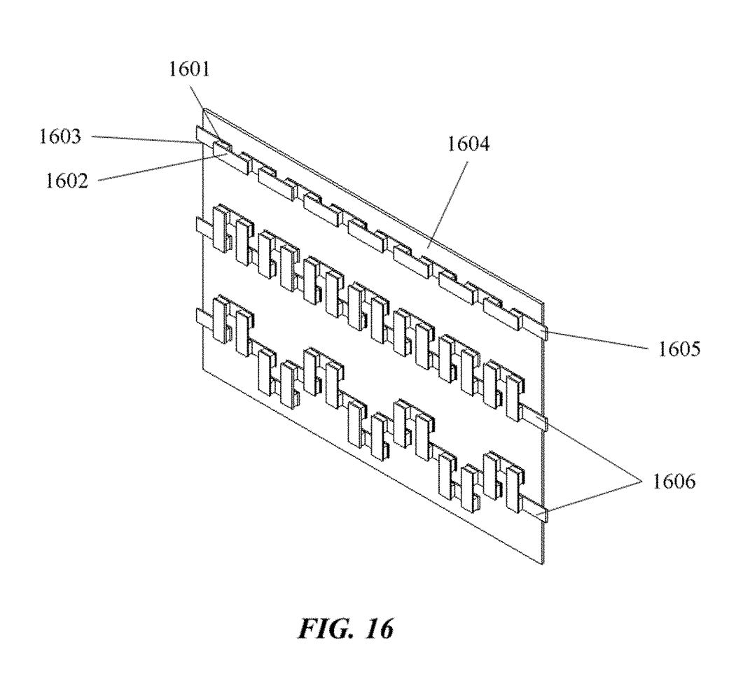

Thermoelectric elements, devices and systems of the present disclosure can be used with electrical interconnects. The electrical interconnects may be any flexible electrically conductive material, which can be sufficiently thin to present low electrical resistance. Examples include metals and their alloys and intermetallics (e.g., aluminum, titanium, nickel, chromium, nichrome, tantalum, hafnium, niobium, zirconium, vanadium, tungsten, indium, copper, silver, platinum, gold, etc.), silicides (e.g., titanium silicide, nickel silicide, chromium silicide, tantalum silicide, hafnium silicide, zirconium silicide, vanadium silicide, tungsten silicide, copper silicide), conductive ceramics (e.g., titanium nitride, tungsten nitride, tantalum nitride, etc.), or combinations thereof. The thermoelectric elements may be formed of flexible substrates, such as materials that are sufficiently thin to be flexible. Examples of such materials include bismuth telluride, lead telluride, half-heuslers, skutterudites, silicon, and germanium. In some examples, the thermoelectric elements are formed of a nanostructured semiconductor (e.g., silicon), which can be made sufficiently thin to be flexible. The nanostructure semiconductor can have a thickness that is less than or equal to about 100 micrometer (microns), 10 microns, 1 micron, 0.5 microns, or 0.1 microns. FIG. 16 shows an electronic device having thermoelectric elements 1601 that are used with top interconnects 1602 and bottom interconnects 1603. The thermoelectric elements 1601 can be situated between at least a portion of the top interconnects 1602 and a bottom interconnects 1603. The interconnects 1602 and 1603 and thermoelectric elements 1601 can be disposed on a substrate 1604. The interconnects 1602 and 1603 can have a linear pattern 1605 or a zigzag pattern 1606.

In some cases, depending on the combination of component materials used, the flexible thermoelectric device may be optimally used at conditions at room temperature, near room temperature, or at temperatures substantially below room temperature, or at temperatures substantially above room temperature. The choice of nanostructured semiconductor for the thermoelectric elements can permit effective operation of the device across a broad temperature range spanning at least about −273° C. to above 1000° C.

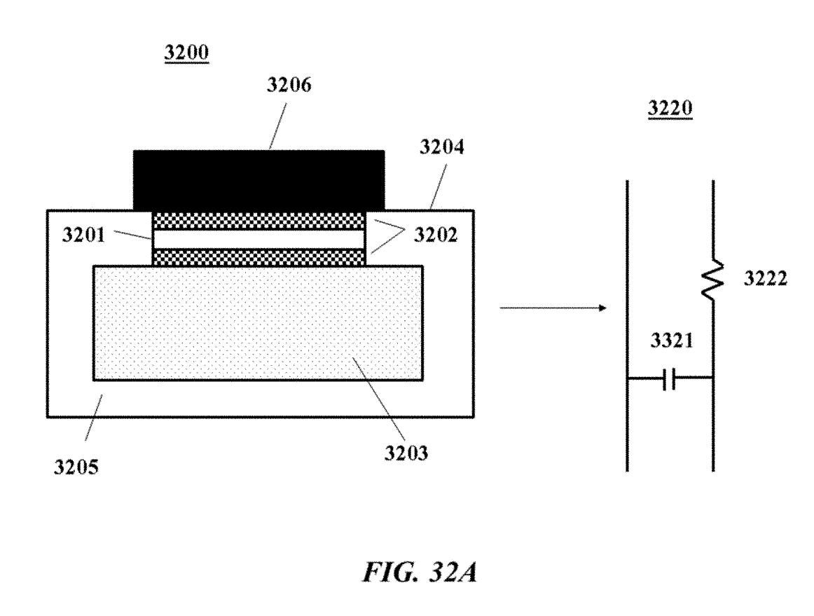

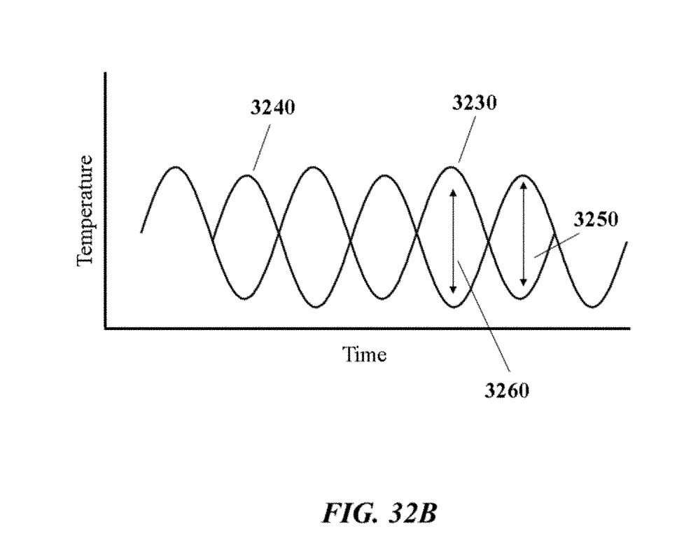

Additionally, depending on the power rating, the interconnect pattern may be varied. For example, given a fixed device size, the output current can be maximized if the thermoelectric elements are connected in parallel linear chains. As another example, the output current can be halved and the output voltage doubled, if the thermoelectric elements are connected in a zigzag pattern (see FIG. 16). Many interconnect patterns are possible. Additionally, external circuitry or switches may be used to switch on/off specific interconnection segments, reroute the interconnection network, or step up/down the output voltage or current.

Where a heat source (e.g., an ambient environment, a body surface) is held at a relatively constant temperature, there can be a well-defined temperature gradient across a thermoelectric device. In some cases, though, the temperature of a heat source can change with time and thus, the temperature gradient across a thermoelectric device can also change with time. In some environments, temperature variations can exist with characteristic frequencies. For example, in an outdoor environment the ambient temperature can vary with time of day. In another example, the ambient temperature of an air-conditioned environment may oscillate whenever an associated thermostat activates in concert with longer period oscillations (e.g. daily). In another example, temperature of a body surface can oscillate with time of day (e.g., a sleeping subject vs. awake subject), time of year (e.g., colder months vs. warmer months), and/or environment with which a subject is associated.

Where heat is collected from a heat source (e.g., ambient environment, a body surface) having a variable temperature, a device comprising a thermoelectric device may include a thermal impedance network (e.g., resistance, inductance and capacitance elements), the operation and/or configuration of which can be matched with temperature oscillations of the heat source. Impedance matching can shift temperature oscillations within the device in time, resulting in periodic temperature differences between the device and the heat source. This temperature difference can be used for thermoelectric power generation. An example of a device comprising a thermal impedance network is schematically depicted in FIG. 32A. Indeed, impedance matching of one or more device components with a heat source (e.g., ambient environment, body surface) can be implemented in any wearable device described elsewhere herein.

As shown in FIG. 32A, the device 3200 can include a thermoelectric device 3201, which can be a thermoelectric device described elsewhere herein. Thermal interface layers 3202 can be positioned adjacent to the top and bottom surfaces of the thermoelectric device 3201 and can be in thermal contact with the thermoelectric device 3201. The thermal interface layers 3202 can aid and/or regulate heat transfer to and from the thermoelectric device 3201. In some cases, one or both of the thermal interface layers 3202 may comprise a material with a relatively high thermal conductivity (e.g., a thermal conductor). In some cases, one or both of the thermal interface layers 3202 may comprise a material with a relatively low thermal conductivity (e.g., a thermal insulator). The thermoelectric device 3201 and thermal interface layers 3202 can be positioned on top of a heat storage unit 3203. The heat storage unit can store heat that has been transferred from the heat source (e.g., ambient environment, body surface) to the device 3200. The thermoelectric device 3201, thermal interface layers 3202 and heat storage unit 3203 can be packaged together in a housing 3204 along with thermal insulation 3205, with an example configuration shown in FIG. 32A. The housing 3204 can have a length of at least about 10 mm, 20 mm, 30 mm, 40 mm, 50 mm, 60 mm, 70 mm, 80 mm, 90 mm, or 100 mm, or more, and/or a length of at least about 10 mm, 20 mm, 30 mm, 40 mm, 50 mm, 60 mm, 70 mm, 80 mm, 90 mm, or 100 mm, or more. The housing 3204 can have a footprint of at least about 100 mm², 200 mm², 300 mm², 400 mm², 500 mm², 600 mm², 700 mm², 800 mm², 900 mm², 1000 mm², or more.

Moreover, the device 3200 can also include a heat transfer unit 3206, that can be positioned adjacent to the housing 3204 and can be thermally coupled to the thermoelectric device 3202 (e.g., via a thermal interface layer 3202 as shown in FIG. 32A). The heat transfer unit 3206 can function as heat collector or heat expeller, depending upon the direction of heat flow through the device 3200. When functioning as a heat collector, the heat transfer unit 3206 can collect heat from the heat source (e.g., ambient environment, body surface) and provides the heat to the thermoelectric device 3201 (e.g., via a thermal interface layer 3202), whereby it converts at least some of the heat to electrical energy. Remaining heat that passes through the thermoelectric device 3201 can be transferred to the heat storage unit 3203 for further use. When functioning as a heat expeller, the heat transfer unit 3206 can remove heat from the device 3200 and provide it to a heat source (e.g., ambient environment, body surface) that is cooler than the components of the device 3200. The heat storage unit 3203 can provide stored heat to the thermoelectric device 3201 (e.g., via a thermal interface layer 3202) which converts at least some of the heat to electrical energy. Remaining heat that passes through the thermoelectric device 3201 can be transferred to the heat transfer unit 3206 (e.g., via a thermal interface layer 3202) which then provides the heat to the heat source (e.g., ambient environment, body surface). The process of transferring heat into and out of the device 3200 can result in an oscillating heat flow through the device 3200 and an oscillating temperature of various components of the device, including the heat storage unit 3203.

An equivalent thermal circuit 3220 for the device 3200 is schematically depicted in FIG. 32A. The thermal circuit 3220 can include a thermal capacitor 3321 and a thermal resistance 3222. The thermal capacitor 3321 represents the heat storage unit 3203 of device 3200 and the thermal resistance 3222 includes the total thermal resistance associated with the combination of the heat transfer unit 3206, the thermal interface layers 3202 and the thermoelectric device 3201.

The components of the thermal impedance network (e.g., heat transfer unit 3206, thermoelectric device 3201, thermal interface layers 3202 and heat storage unit 3203) of the device 3200 can be selected and arranged such that oscillating temperature(s) through them are tuned to be at least partially out of phase with temperature oscillations of the heat source (e.g., ambient environment, body surface). In some cases, tuning can be such that temperature oscillations of one or more device components and temperature oscillations of the heat source (e.g., ambient temperature, body surface) are completely out of phase. The differences in phase can produce the temperature gradients that are used by the thermoelectric device 3201 to generate electrical energy.

FIG. 32B graphically depicts an example of such operation. FIG. 32B shows a temperature versus time plot, with data for heat source temperature 3230 and heat storage unit temperature 3240. The associated device (e.g., such as the device 3200 shown in FIG. 32A) can be tuned such that the maximum temperature of its heat storage unit (e.g., heat storage unit 3203 shown in FIG. 32A) occurs when the heat source temperature is at its minimum. The temperature difference 3250 between the heat storage unit and heat source can drive heat from the heat storage unit, through an associated thermoelectric device (e.g., thermoelectric device 3201 shown in FIG. 32A) and out through an associated heat transfer unit (e.g., heat transfer unit 3206 shown in FIG. 32A). As a result of heat storage unit temperature dropping from release of its stored heat and the temperature of the heat source increasing due to regular fluctuations in temperature, the heat transfer unit can “switch” function and function as a heat collector. The heat collector can collect heat from the heat source and, by the temperature difference between the heat source and heat storage unit, drive heat through the thermoelectric device and into the heat storage unit.

In the example shown in FIG. 32B, the device (e.g., device 3200 shown in FIG. 32A) is tuned such that the minimum temperature of its heat storage unit (e.g., heat storage unit 3203 shown in FIG. 32A) coincides with the maximum temperature of the heat source. This temperature difference 3260 generates the thermal gradient that drives heat from the heat source, into the thermoelectric device and into the heat storage unit. As shown in FIG. 32B, the temperature oscillations of the heat storage unit cycles at a regular frequency (e.g., the same frequency as the temperature oscillations of the heat source) to generate electrical energy in the device, with both a transfer of energy into and out of the device.

While the example operation shown in FIG. 32B shows temperature oscillations of the heat source and temperature oscillations of a heat storage unit that are completely out of phase, any difference in phase can generate a temperature difference that can drive heat flow into and out of a device. The example shown in FIG. 32B is not meant to be limiting. Moreover, in some cases, multiple stages (e.g., each stage having a thermoelectric device, thermal interface layer and/or heat storage unit) can be included in a device to achieve a particular tuning. Each stage may include identical components in type and/or number or may include components that different in type and/or number. In general, where multiple stages are used, each stage can phase shift the temperature oscillations in the device to a certain degree, such that the combination of the phase shifts results in the desired tuning.

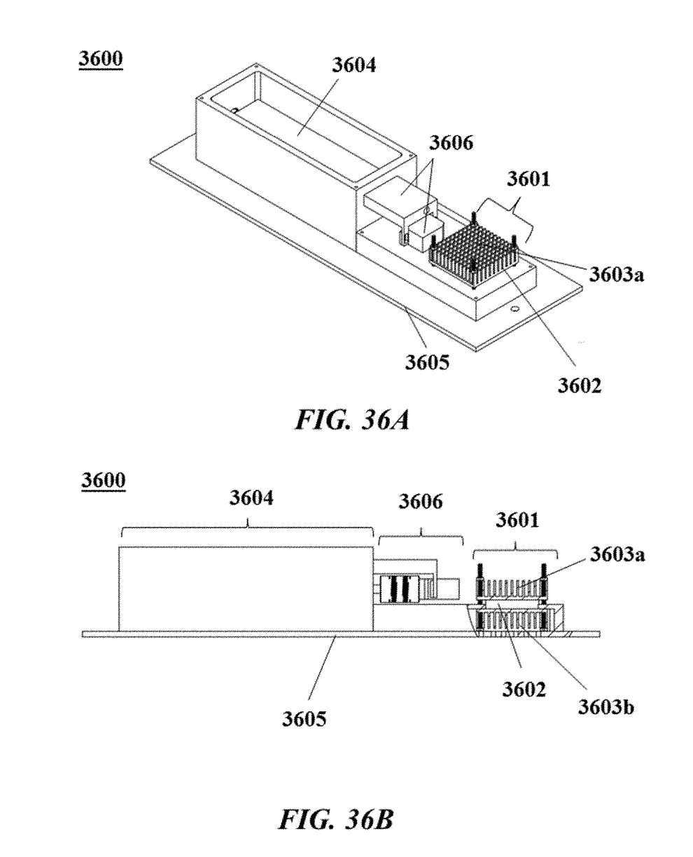

An additional example of a power device comprising a thermal impedance network and designed for use with an air-flow network (e.g., a heating system, a cooling system (e.g., air conditioner)) is schematically depicted in FIG. 36A and FIG. 36B in various views. As shown in FIG. 36A and FIG. 36B, the device 3600 can include a thermal impedance assembly 3601 that can comprise a thermoelectric device 3602, which can be a thermoelectric device described elsewhere herein. Thermal interface layers can be positioned adjacent to the top and bottom surfaces of the thermoelectric device 3602 and in thermal contact with the thermoelectric device 3602. The thermal interface layers aid and/or regulate heat transfer to and from the thermoelectric device 3602. In some cases, one or both of the thermal interface layers can comprise a material with a relatively high thermal conductivity (e.g., a thermal conductor). In some cases, one or both of the thermal interface layers can comprise a material with a relatively low thermal conductivity (e.g., a thermal insulator). The thermoelectric device 3602 and thermal interface layers can be sandwiched between two heat transfer units 3603a and 3603b.

The heat transfer units 3603a and 3603b can be positioned adjacent to a respective thermal interface layer (or a respective side of the thermoelectric device 3602) and can each be thermally coupled to the thermoelectric device 3602 (e.g., via a thermal interface layer). The heat transfer units 3603a and 3603b can each function as one of a heat collector or heat expeller, depending upon the direction of heat flow through the device 3600. One or both of the heat transfer units 3603a and 3603b can comprise a heat sink, heat pipe or other type of heat transfer device described herein. In some cases, one or both of the heat transfer units 3603a and 3603b can comprise fins that improve heat transfer. Such fins may be of a solid material or may be perforated.

The device 3600 can also include a vent assembly 3604 that can be coupled to a transfer member 3605 that can be thermally coupled to heat transfer unit 3603b and capable of transferring energy to/from heat transfer unit 3603b. Moreover, the device 3600 can also include a drive and electronics assembly 3606 that can include a drive for controlling electrical flow received from the thermal impedance assembly 3601 and provided to an electronic device to-be-powered (e.g., a motor). The drive and electronics assembly 3606 can include one or more of a DC-DC converter, power management electronics, and an electrical power storage module (e.g., a batter, a capacitor). In some cases, the device 3600 may also include one or more electromechanical actuators that control the flow of air through the device 3600.

During operation, air flow from a source of heating (e.g., a furnace, a radiator, a building heating system) or cooling (e.g., an air-conditioning system) can flow through the vent 3604. During a “heating” cycle with respect to air-temperature (e.g., operation of a heater, non-operation of an air conditioner), heat can flow from the environment of the vent 3604 to transfer member 3605 and to heat transfer unit 3603b when an appropriate temperature gradient through the thermal impedance assembly 3601 gradient exists. In this case, heat transfer unit 3603b can function as a heat collector. Heat transfer unit 3603b can collect heat received from the air-flow and provide the heat to the thermoelectric device 3602 (e.g., via a thermal interface layer), whereby it can convert at least some of the heat to electrical energy. Electrical energy that is generated can flow from the thermoelectric device 3602 to the drive and electronics assembly 3606, where it can be transferred to a device to-be-powered and/or stored. Remaining heat that is not converted to electrical energy can pass through the thermoelectric device 3602, be transferred to heat transfer unit 3603a and expelled to the ambient environment surrounding heat transfer unit 3603a.

During a “cooling” cycle with respect to air-temperature (e.g., operation of an air-conditioner, non-operation of a heater), heat can flow from the ambient environment surrounding heat transfer unit 3603a when an appropriate temperature gradient exists. In this case, heat transfer unit 3603a can function as a heat collector. Heat transfer unit 3603a can collect heat from its surrounding environment and provides the heat to the thermoelectric device 3602 (e.g., via a thermal interface layer), whereby it can convert at least some of the heat to electrical energy. Electrical energy that is generated can flow from the thermoelectric device 3602 to the drive and electronics assembly 3606, where it can be transferred to a device to-be-powered and/or stored. Remaining heat that is not converted to electrical energy can pass through the thermoelectric device 3602, be transferred to heat transfer unit 3603b, be transferred to transfer member 3605 and finally be expelled to the ambient environment of the vent 3604. The process of transferring heat into and out of the thermal impedance assembly 3601 can result in an oscillating heat flow through the device 3600 that corresponds to changes in temperature of the environment (e.g., air) in the vent 3604.

The components of the thermal impedance 3601 assembly and/or transfer member 3605 can be selected and arranged such that oscillating temperature(s) through them are tuned to be at least partially out of phase with temperature oscillations of the environment (e.g., air) in the vent 3604. In some cases, tuning can be such that temperature oscillations of one or more device components and temperature oscillations in the vent 3604 are completely out of phase. The differences in phase can produce the temperature gradients that are used by the thermoelectric device thermal impedance assembly 3601 to generate electrical energy.

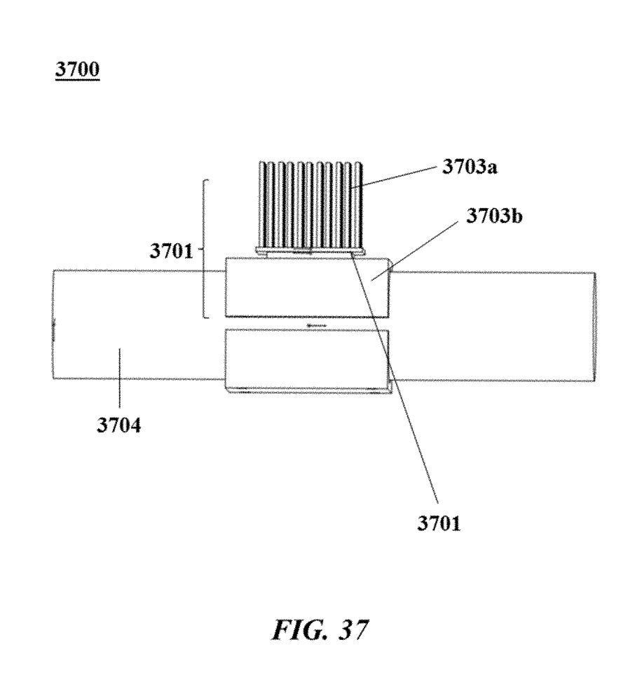

An additional example of a power device comprising a thermal impedance network and designed for use with a fluid flow network is schematically depicted FIG. 37. As shown in FIG. 37, the device 3700 can include a thermal impedance assembly 3701 that can comprise a thermoelectric device 3702, which can be a thermoelectric device described elsewhere herein. Thermal interface layers can be positioned adjacent to the top and bottom surfaces of the thermoelectric device 3702 and in thermal contact with the thermoelectric device 3702. The thermal interface layers can aid and/or regulate heat transfer to and from the thermoelectric device 3702. In some cases, one or both of the thermal interface layers can comprise a material with a relatively high thermal conductivity (e.g., a thermal conductor). In some cases, one or both of the thermal interface layers can comprise a material with a relatively low thermal conductivity (e.g., a thermal insulator). The thermoelectric device 3702 and thermal interface layers can be sandwiched between two heat transfer units 3703a and 3703b.

The heat transfer units 3703a and 3703b can be positioned adjacent to a respective thermal interface layer (or a respective side of the thermoelectric device 3602) and can each be thermally coupled to the thermoelectric device 3702 (e.g., via a thermal interface layer). As shown in FIG. 37, heat transfer unit 3703b can be positioned adjacent to a pipe 3704 through which fluid can flow, and heat transfer unit 3703b can be thermally coupled to heat transfer unit 3703a via the thermoelectric device 3702 and its associated thermal interface layers. Heat transfer unit 3703b can also be thermally coupled to the interior space of the pipe 3704 (e.g., fluid in the pipe 3704). The heat transfer units 3703a and 3703b can each function as one of a heat collector or heat expeller, depending upon the direction of heat flow through the device 3700. One or both of the heat transfer units 3703a and 3703b can comprise a heat sink, heat pipe or other type of heat transfer device described herein (e.g. heat conduit). In some cases, one or both of the heat transfer units 3703a and 3703b comprise fins that improve heat transfer. Such fins may be of a solid material or may be perforated. As shown in FIG. 37, heat transfer unit 3703a can comprise a heat sink with fins, whereas heat transfer unit 3703b can comprise a solid material.

Moreover, the device 3700 can also include an electronics assembly that can include a device for controlling electrical flow received from the thermal impedance assembly 3701 and provided to an electronic device to-be-powered. The electronics assembly can include one or more of a DC-DC converter, power management electronics, and an electrical power storage module (e.g., a batter, a capacitor).

During operation, fluid flow from a source of “hot” fluid or “cold” fluid can flow through the pipe 3704. During a “hot” cycle, heat can flow from the interior of the pipe 3704 (e.g., from a hot fluid in the pipe 3704) to heat transfer unit 3703b when an appropriate temperature gradient through the thermal impedance assembly 3701 gradient exists. In this case, heat transfer unit 3703b can function as a heat collector. Heat transfer unit 3703b can collect heat received from the pipe 3704 interior and provide the heat to the thermoelectric device 3702 (e.g., via a thermal interface layer), whereby it can convert at least some of the heat to electrical energy. Electrical energy that is generated can flow from the thermoelectric device 3702 to the electronics assembly, where it can be transferred to a device to-be-powered and/or stored. Remaining heat that is not converted to electrical energy can pass through the thermoelectric device 3702, be transferred to heat transfer unit 3703a and expelled to the ambient environment surrounding heat transfer unit 3703a.

During a “cold” cycle, heat can flow from the ambient environment surrounding heat transfer unit 3703a when an appropriate temperature gradient exists. In this case, heat transfer unit 3703a can function as a heat collector. Heat transfer unit 3703a can collect heat from its surrounding environment and provide the heat to the thermoelectric device 3702 (e.g., via a thermal interface layer), whereby it can convert at least some of the heat to electrical energy. Electrical energy that is generated can flow from the thermoelectric device 3702 to the electronics assembly, where it can be transferred to a device to-be-powered and/or stored. Remaining heat that is not converted to electrical energy can pass through the thermoelectric device 3702, be transferred to heat transfer unit 3703b and then be expelled into the environment (e.g., fluid) within the pipe 3704. The process of transferring heat into and out of the thermal impedance assembly 3701 can result in an oscillating heat flow through the device 3700 that corresponds to changes in temperature of the interior of the pipe 3704.

The components of the thermal impedance assembly 3701 can be selected and arranged such that oscillating temperature(s) through them are tuned to be at least partially out of phase with temperature oscillations in the pipe 3704. In some cases, tuning can be such that temperature oscillations of one or more device components and temperature oscillations of the pipe 3704 interior are completely out of phase. The differences in phase can produce the temperature gradients that are used by the thermoelectric device thermal impedance assembly 3701 to generate electrical energy.

In some embodiments, thermoelectric elements, devices and systems provided herein can be used in or with wearable electronic devices. Such wearable electronic devices can be powered at least in part by body heat (e.g., power generated by a thermoelectric device using body heat). Body heat can be used to generate power that is sufficient to meet at least 1%, 5%, 10%, 20%, 30%, 40%, 50%, 60%, 70%, 80%, 90%, 95%, 99%, or 100% of a power demand or requirement of a wearable electronic device. Any additional power that may be required may be supplemented using, for example, an energy storage unit (e.g., battery) or other alternative sources of power, such as, for example, solar cells.

For example, a thermoelectric device can be provided in a shirt or jacket lining, which can help generate power using the temperature difference between the body of a user and the external environment. This can be used to directly provide power to an electronic device (e.g., wearable electronic device or mobile device), or to charge a rechargeable battery of the electronic device.

A thermoelectric material can be integrated in an apparatus that converts body heat to electricity for purposes of powering electronic circuits. The apparatus can be integrated with a thermoelectric device (such as a thermoelectric device described herein) and an electronic device to-be-powered (e.g., wearable electronic device), including, but not limited to, watches (e.g., analog watches, digital watches, smart watches), smart glasses, worn or in-ear media players, consumer health monitors (such as pedometers, fitness trackers or baby monitors), hearing aids, medical devices (such as heart rate monitors, blood pressure monitors, brain activity (EEG) monitors, cardiac activity (EKG) monitors, pulse oximeters, insulin monitors, insulin pumps, pacemakers, wearable defibrillators). In some cases, the electronic device to-be-powered includes a user interface (e.g., face of a watch, display of an electronic device, etc.), such as a graphical user interface (GUI) (e.g., GUI of a smart phone, GUI of a smart watch, GUI of a consumer health monitor, etc.).

Moreover, the thermoelectric unit and/or electronic device to-be-powered can include at least one fastening device, fastener, or coupler (e.g., a strap, a buckle, a bracelet, a tie, a clip, a clasp, a clamp, an adhesive, etc.) that secures the thermoelectric device to a body surface of a user. A fastening member or fastener can include one or more components (thermoelectric device, heat collector, heat expeller, etc.) of the apparatus. Additionally, in some cases, the electronic device to-be-powered may be removably positioned against the thermoelectric device and/or any other device component. In such cases, the thermoelectric device can include one or more securing members or couplers (e.g., a clip, a clasp, a hole, a connector, a peg, a magnet, an adhesive, velcro, etc.) that secures (e.g., removably secures) the electronic device to-be-powered against the thermoelectric device. In some cases, an electronic device to be powered may be integrated with a thermoelectric device into a housing.

An electronic device to-be-powered may be directly and/or indirectly coupled electronically to the thermoelectric device. For example, the thermoelectric device may include one or more electrical output ports or connectors to which an electronic device to be powered can mate. Via the output ports or connectors, electrical power is supplied to the device from the thermoelectric device. In other cases, an apparatus may include an inductive unit that is in electrical communication with a thermoelectric device and couples electrical power generated by the thermoelectric device to an associated electronic device to-be-powered. In some cases, inductive coupling of electrical power generated by a thermoelectric device and an associated electronic device to-be-powered is done without the use of electrical ports or connectors (e.g., wirelessly).

The apparatus can be a standalone apparatus that can be used to power electronic devices, such as mobile electronic devices, including, but not limited to, smart phones (e.g., Apple® iPhone) or laptop computers. The apparatus can be integrated into an electronically augmented piece of clothing or body accessory, including, but not limited to, smart clothing, smart jewelry (e.g., bracelets, bangles, rings, earrings, studs, necklaces, wristbands, or anklets). The apparatus may be used as the sole source of electrical power, generating at least about 1 μW, 10 μW, 100 μW, 1 mW, 10 mW, 20 mW, 30 mW, 40 mW, 50 mW, 100 mW, or 1 W, in some cases from 1 W to 10 mW. It can also be augmented or supported by another source (e.g., battery, capacitors, supercapacitors, photovoltaic panels, kinetic energy, or rechargeable from wall).

In an example, the apparatus may include a heat collector, a heat expeller, and a thermoelectric device sandwiched therebetween so as to be interposed in the primary path of heat flow. In another example, the apparatus may be integrated with power management circuitry (e.g., step up transformers, direct current (DC) to DC converters, trickle charge circuits, etc.) or power storage (battery, capacitor, supercapacitor, etc.). In yet another example, the apparatus may be further integrated with sensors, data storage, communication and/or display circuitry, and microprocessor systems.

A heat collector can absorb heat from the body of a user and channel heat to the thermoelectric device. It may take any form amenable for its purpose and can be sufficiently thermally conductive to absorb heat from the body and channel heat to the thermoelectric device. In some cases, a heat collector is a slab, plate, ring, or annulus. The heat collector can be formed of a thermally conductive metal, ceramic, or plastic. In an example, the heat collector is a metallic band. In another example, the heat collector may be integrated with a heat pipe. The heat collector may be held on the body by physical insertion, loose or tight clamping, friction, or adhesives. In some cases, a fastening member or fastener may comprise a heat collector.

In some cases, the heat expeller can remove heat from the thermoelectric device and expel heat to the environment. The heat expeller can have any shape, form or configuration, such as, for example, a slab, plate, ring, or annulus. The heat expeller can be sufficiently thermally conductive to remove heat from the thermoelectric device and expel it to the environment. In some cases, the heat expeller may be formed of a thermally conductive metal, ceramic, or plastic. In an example, the heat expeller is a metallic heat sink. In another example, the heat expeller may be integrated with a heat pipe. In some cases, a fastening member or fastener may comprise a heat collector.

The thermoelectric device can convert heat into electricity, and may be rigid, semi-rigid or flexible. In some cases, use of a flexible thermoelectric device can simplify manufacturing and assembly of the apparatus. In an example, this may be one or more layers of a flexible thermoelectric device and attached between the heat collector and expeller using thermally conductive adhesives, mechanical preforming or mechanical clamping.

In some cases, a thermoelectric device may convert heat into electricity that can be harvested and stored via an energy storage system (e.g., a battery, a capacitor, etc.). Upon exposure of the thermoelectric device to heat, the thermoelectric device can convert the heat to electrical energy, which can then be routed through associated circuitry to an associated energy storage system. The stored electrical energy can be accessed to electrically power an associated electronic device in the absence of a heat source and/or to supplement electrical power provided by a thermoelectric device in the presence of heat. Moreover, energy stored in an associated energy storage system may be exclusively generated by a thermoelectric device or may supplement electrical energy that is provided by other sources, including an inductive energy source and/or a wired energy source.

In some cases, an apparatus comprising a thermoelectric device can be charged and/or powered via a heat pad. The heat pad can be any suitable device that comprises a heating surface that can be thermally coupled to a thermoelectric device. In some cases, a heat pad may be a heating plate. A heat pad may include one or more members that can secure a thermoelectric device (or an apparatus comprising a thermoelectric device) such that it is thermally coupled to the thermoelectric device. Examples of heat pad securing members or couplers include a clip, a clasp, a strap and a magnet. In some cases, a heat pad can be powered via a wired electrical source (e.g., a wall socket) and/or may be powered by a non-wired source, such as a battery. In some cases, a heat pad that is capable of charging a thermoelectric device can be warmed to at least about 20° C., at least about 25° C., at least about 30° C., at least about 35° C., at least about 40° C., at least about 45° C., at least about 50° C., at least about 55° C., at least about 60° C., at least about 65° C. or higher. The heat generated by a heat pad can generate a temperature difference across the thermoelectric electric device which generates electrical energy that can be used to power an electronic device and/or stored in an associated energy storage system for later use.

An apparatus comprising a thermoelectric device can be wearable. In some cases, the apparatus may take the form of a bracelet or ring. In some cases, the apparatus may be a wrist-worn, arm-worn, leg-worn, hand-worn, foot-worn, finger-worn, toe-worn, or head-word device with examples that include a wristwatch (e.g., an analog watch, a digital watch, a smart watch, etc.), an activity monitor, a fitness monitor, or any other type of electrically powered jewelry. In another implementation, the apparatus may take the form of spectacle frames. In yet another implementation, the apparatus may take the form of a patch to be applied over a human chest, back or torso using adhesive or attachment straps. In yet another implementation, the apparatus may take the form of an implantable film, disc or plate. The apparatus can provide an output power from the thermoelectric device of at least about 1 microwatts (μW), 10 μW, 100 μW, 1 mW, 10 milliwatts (mW), 20 mW, 30 mW, 40 mW, 50 mW, 100 mW, or 1 watt (W), in some cases from 1 μW to 10 mW, at a voltage of at least about 1 mV, 2 mV, 3 mV, 4 mV, 5 mV, 10 mV, 20 mV, 30 mV, 40 mV, 50 mV, 100 mV, 200 mV, 300 mV, 400 mV, 500 mV, 1 V, 2 V, 3 V, 4 V, 5 V or 10 V, in some cases from about 10 mV-10 V. In some situations, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery. An auxiliary power supply, such as a battery, can also be included in the apparatus to provide reserve power in times of intermittent bodily contact, decreased power output or increased power consumption. The apparatus can also contain a set of sensors, display and communication circuits, and microprocessors to measure, store and display information.

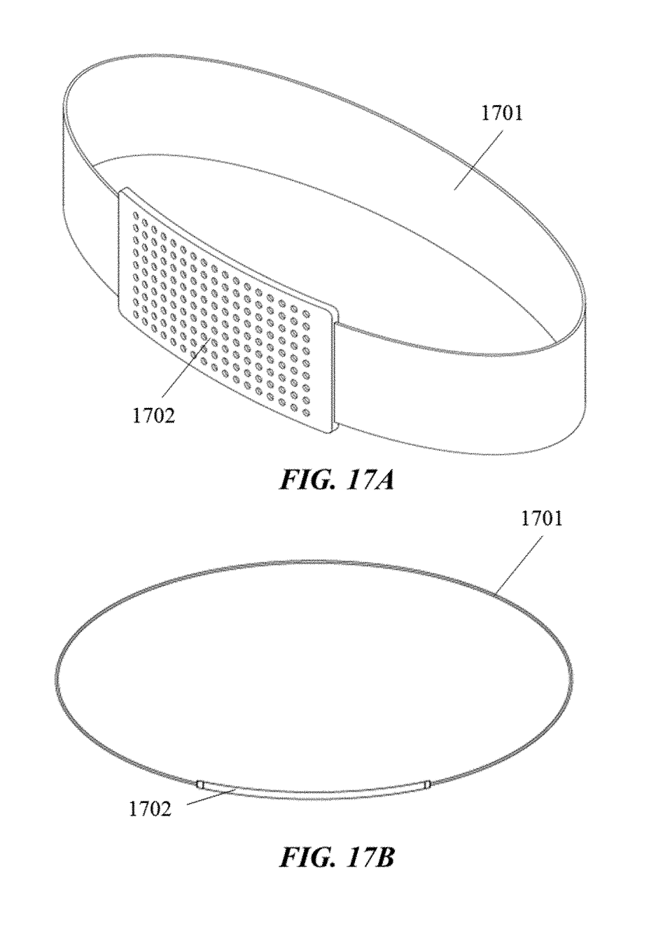

FIGS. 17A-17D show various views of a baby monitor. The baby monitor can be powered at least in part by body heat, such as the body heat of a baby. The baby monitor can include a band or belt 1701 and a buckle or harness piece 1702 that can be integrated with heat collectors and heat expellers, a thermoelectric device with thermoelectric material, power management electronics and energy storage, a sensor, a communications interface (e.g., for wireless communication with another electronic device) and a computer processor.

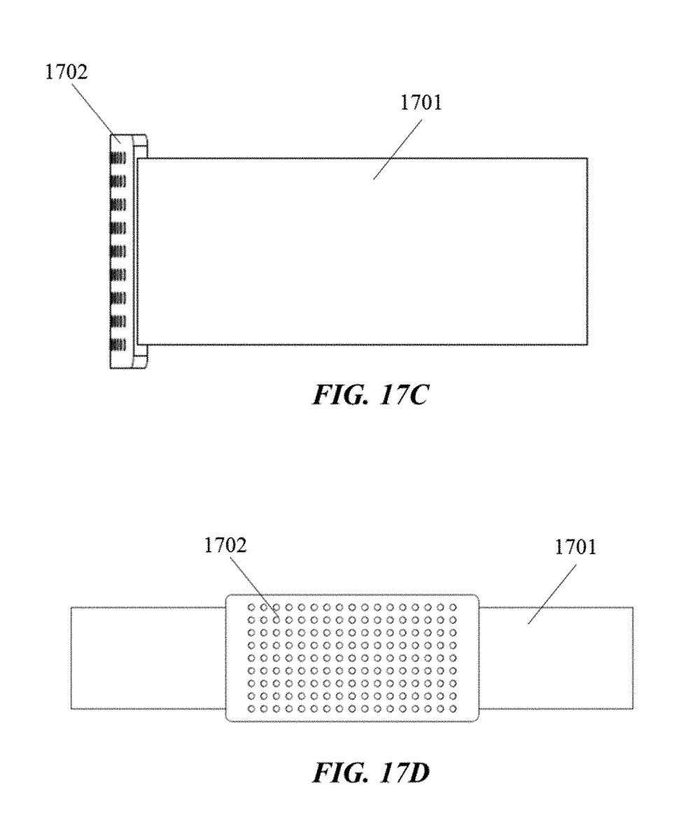

FIGS. 18A-18D show various views of a body heat powered pacemaker system. The system can include a pacemaker 1801, an implantable thermoelectric module 1802 comprising a thermoelectric device of the present disclosure, and power leads 1803. The thermoelectric module 1802 can be in film, disc or plate form, for example.

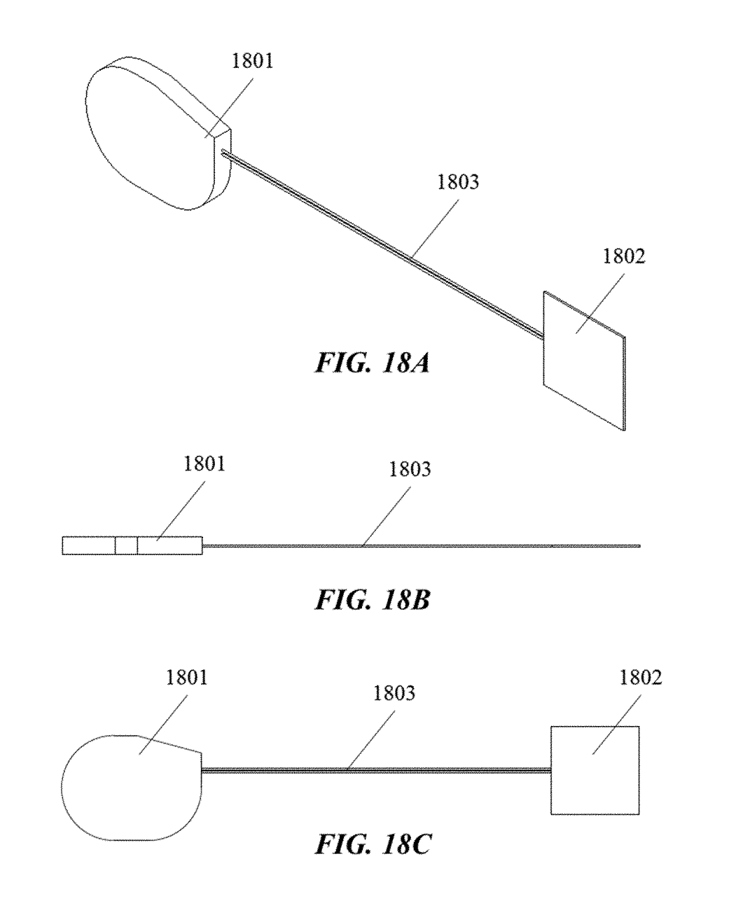

FIGS. 19A and 19B schematically illustrate an electronic device that can be body heat powered and wearable by a user (e.g., as jewelry). The device 1901 may comprise a control module 1902 having a sensor display, communications interface and computer processor, which can be in electrical communication with one another. The device 1901 may further comprise a heat expeller 1903, thermoelectric device 1904 having a thermoelectric material, a heat collector 1905, and a power module 1906 having power management electronics and an energy storage system. The energy storage system can be a battery, such as a rechargeable battery. The thermoelectric device 1904 can be in electrical communication with the control module 1902. Power to the control module 1902 can be at least partially (e.g., at least about 1%, 5%, 10%, 20%, 30%, 40%, 50%, 60%, 70%, 80%, 90%, 95%, 99% of a power demand or requirement) or fully provided by the thermoelectric device 1904 either directly to the control module 1902 or, in some cases, used to charge the energy storage system in the power module 1906. FIG. 19B shows the device 1901 disposed around a hand 1907 of a user.

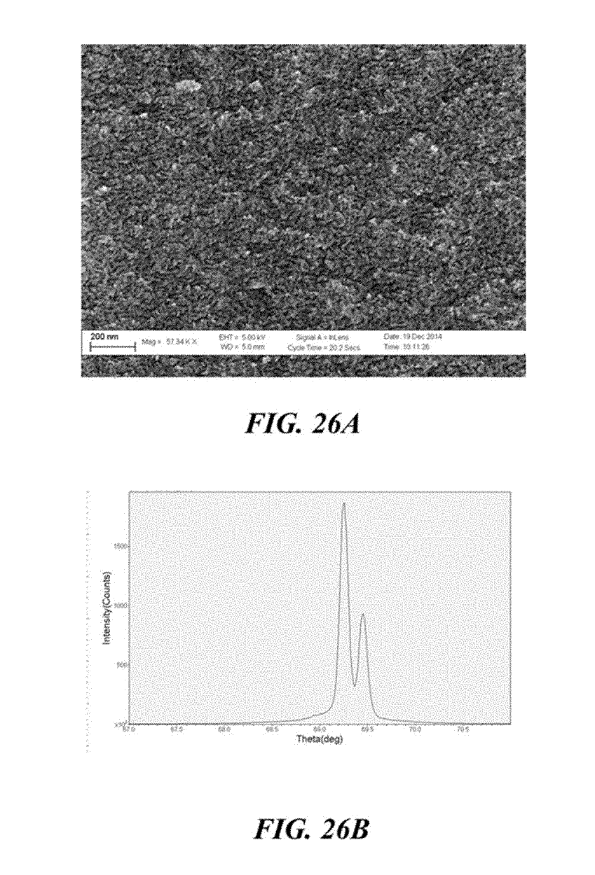

FIG. 27A and FIG. 27B schematically depict views of an example wrist-worn device 2700 that includes a power generation module. The power generation module can include a thermoelectric device (e.g., a thermoelectric device described elsewhere herein) 2701, a heat collector 2702 and a heat expeller (e.g., 2703 and 2707). In some cases, the power generation module can also include one or more of a DC-DC converter, power management electronics, and onboard energy storage. The device 2700 can also include a strap 2704 and buckle 2705 that can be used to secure the power generation module to a subject's wrist.

The heat collector 2702 may be a solid material, a heat pipe, or a combination thereof. Non-limiting examples of suitable heat pipes include simple heat pipes, diode heat pipes, vacuum chambers and thermosyphons. As shown in FIG. 27B, the heat collector 2702 can be positioned on the bottom of the power generation module where it can make contact with a subject's skin or other outer body surface. In some cases, the heat collector 2702 can be a surface of the thermoelectric device 2701, or a separate surface in thermal contact with a surface of the thermoelectric device 2701.

Moreover, the heat expeller may include one or more heat pipes 2707 integrated with a heat sink 2703 that can extend beyond the body of the device 2700. The heat sink 2703 can be a heat exchanger that can be patterned with inclusions or extrusions. The heat expeller can remove heat from the thermoelectric device 2701, thereby generating a temperature gradient in the thermoelectric device 2701 between the heat collector 2702 and the heat expeller. As described elsewhere herein, such a temperature gradient can be used to generate electrical energy. In some cases, one or more of the heat collector 2702, thermoelectric device 2701 and heat expeller may have surface treatments that aid in increasing thermal transfer rates to/from the respective components. Such surface treatments can be chemical, electrochemical, mechanical, chemomechanical, physical, or a combination thereof. Non-limiting examples of surface treatments that can aid in increasing thermal transfer rates include blanching, burnishing, case hardening, ceramic glazing, cladding, corona treatment, carburizing, nitriding, electroplating, galvanizing, gilding, glazing, knurling, painting, passivation coatings, pickling, plasma spraying, powder coating, thin-film deposition, application or deposition of intervening films or layers, chemical-mechanical planarization, electropolishing, flame polishing, industrial etching, laser ablation, laser engraving, magnetic field-assisted finishing, shot peening, laser peening, abrasive blasting, sandblasting, grinding, belt sanding, tumble finishing, vibratory finishing, polishing, buffing, lapping and superfinishing. In some cases, more than one type of surface treatment may be applied to increase thermal transfer rates.

Via the heat collector 2702, heat generated from the subject can be provided to the power generation module, whereby it can be converted to electrical energy in the thermoelectric device 2701 by its flow from the heat collector 2702 to the heat expeller. In some cases, the electrical output from the power generation module can be linked to a power bus that can be connected to the device 2700 that can supply electrical energy to an electrically powered device electrically coupled to the power generation module. In some cases, the electrically powered device can be integrated into a housing with the power generation module and/or thermoelectric device 2701 of the power generation module. Moreover, in some cases, the device 2700 may also include an auxiliary energy storage unit 2706 such as a battery or capacitor (e.g., a supercapacitor). The auxiliary energy storage unit 2706 can provide reserve power in times of intermittent contact of the device 2700 with a subject's body surface, decreased power output and/or increased power consumption.

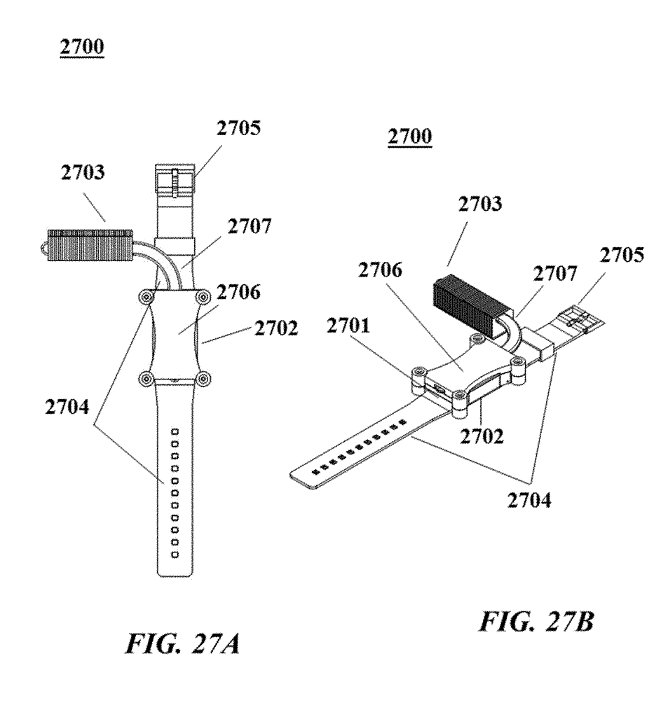

FIG. 28A and FIG. 28B schematically depict views of an example wrist-worn device 2800 that includes a power generation module. The power generation module can include a thermoelectric device (e.g., a thermoelectric device described elsewhere herein) 2801, a heat collector 2802 and a heat expeller 2803. In some cases, the power generation module can also include one or more of a DC-DC converter, power management electronics, and onboard energy storage.

The heat collector 2802 may be a solid material, a heat pipe (e.g., a type of heat pipe described elsewhere herein) or a combination thereof. As shown in FIG. 28A and FIG. 28B, the heat collector 2802 can be positioned on the bottom of the power generation module where it can make contact with a subject's skin or other outer body surface. In some cases, the heat collector 2802 can be a surface of the thermoelectric device 2801, or a separate surface in thermal contact with a surface of the thermoelectric device 2801.

Moreover, as shown in FIGS. 28A and 28B, the heat expeller 2803 can be in a strap configuration and may include one or more heat pipes integrated with a heat sink. In the example shown in FIG. 28A and FIG. 28B, the heat expeller 2803 of the device 2800 includes a single piece of flat heat pipe that is fitted with solid heat sink fins. The heat expeller 2803 can remove heat from the thermoelectric device 2801, thereby generating a temperature gradient in the thermoelectric device 2801 between the heat collector 2802 and the heat expeller 2803. As described elsewhere herein, such a temperature gradient can be used to generate electrical energy. In some cases, one or more of the heat collector 2802, thermoelectric device 2801 and heat expeller 2803 may have surface treatments that aid in increasing thermal transfer rates to/from the respective components. Examples of surface treatments that can aid in increasing thermal transfer rates described elsewhere and can be applied to one or more of the heat collector 2802, thermoelectric device 2801 and heat expeller 2803. In some cases, more than one surface treatment may be applied to increase thermal transfer rates.

Via the heat collector 2802, heat generated from the subject can be provided to the power thermoelectric device 2801, whereby it can be converted to electrical energy by its flow from the heat collector 2802 to the heat expeller 2803. In some cases, the electrical output from the power generation module can be linked to a power bus that can be connected to the device 2800 that can supply electrical energy to an electrically powered device electrically coupled to the power generation module. In some cases, the electrically powered device can be integrated into a housing with the power generation module and/or thermoelectric device 2801 of the power generation module. Moreover, in some cases, the device 2800 may also include an auxiliary energy storage unit 2804 such as a battery or capacitor (e.g., a supercapacitor). The auxiliary energy storage unit 2804 can provide reserve power in times of intermittent contact of the device 2800 with a subject's skin or other outer body surface, decreased power output and/or increased power consumption.

The device 2800 can be mated to a strap 2805 having pieces that include a hollow interior, whereby the components of the heat expeller 2803 fit. The device 2800 in its configuration with strap 2805 is shown as device 2810 in FIG. 28C. The strap 2805 can completely cover the heat expeller or, as shown in FIG. 28C may be perforated to improve heat transfer from the heat expeller. Furthermore, the strap 2805 can include a buckle 2806 that can be used to secure the power generation module to a subject's wrist.

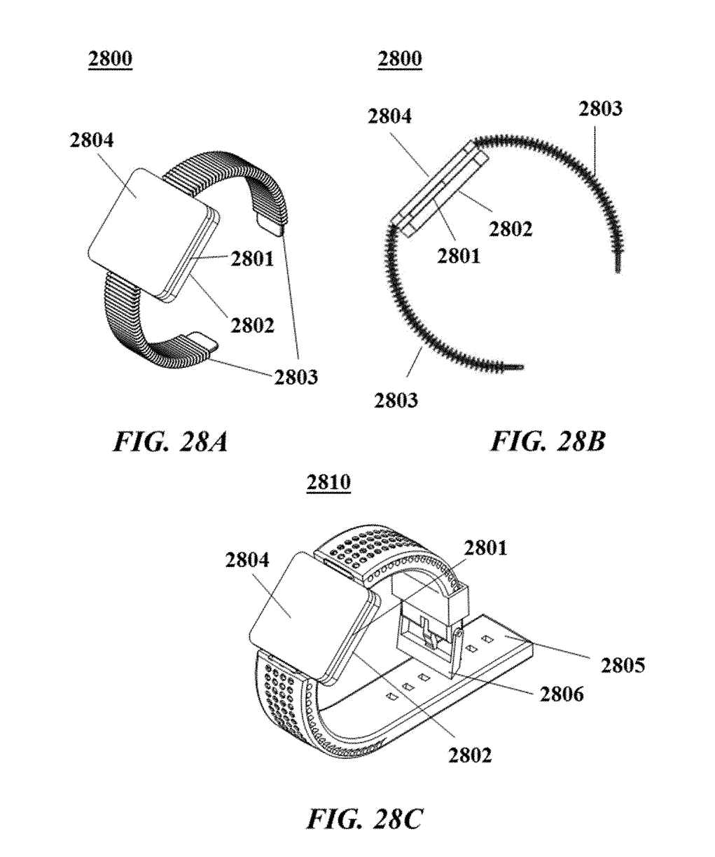

FIG. 29A schematically depicts an example wrist-worn device 2900 that includes a power generation module. The power generation module can include a thermoelectric device (e.g., a thermoelectric device described elsewhere herein) 2901, a heat collector 2902 and a heat expeller 2903. In some cases, the power generation module also includes one or more of a DC-DC converter, power management electronics, and onboard energy storage.

The heat collector 2902 may be a solid material, a heat pipe (e.g., a type of heat pipe described elsewhere herein) or a combination thereof. As shown in FIG. 29A, the heat collector 2902 can be positioned on the bottom of the power generation module where it can make contact with a subject's skin or other outer body surface. In some cases, the heat collector 2902 can be a surface of the thermoelectric device 2901, or a separate surface in thermal contact with a surface of the thermoelectric device 2901.

Moreover, as shown in FIG. 29A, the heat expeller 2903 can be in a strap configuration and may include one or more heat pipes integrated with a heat sink. In the example shown in FIG. 29A, the heat expeller 2903 of the device 2900 can include dual cylindrical heat pipes, fitted with perforated heat sink fins. The heat expeller 2903 can remove heat from the thermoelectric device 2901, thereby generating a temperature gradient in the thermoelectric device 2901 between the heat collector 2902 and the heat expeller 2903. As described elsewhere herein, such a temperature gradient can be used to generate electrical energy. In some cases, one or more of the heat collector 2902, thermoelectric device 2901 and heat expeller 2903 may have surface treatments that aid in increasing thermal transfer rates to/from the respective components. Examples of surface treatments that can aid in increasing thermal transfer rates described elsewhere and can be applied to one or more of the heat collector 2902, thermoelectric device 2901 and heat expeller 2903. In some cases, more than one surface treatment may be applied to increase thermal transfer rates.

Via the heat collector 2902, heat generated from the subject can be provided to the power generation module 2901, whereby it can be converted to electrical energy by its flow between the heat collector 2902 and the heat expeller 2903. In some cases, the electrical output from the power generation module can be linked to a power bus that can be connected to the device 2900 that can supply electrical energy to an electrically powered device electrically coupled to the power generation module. In some cases, the electrically powered device can be integrated into a housing with the power generation module and/or thermoelectric device 2901 of the power generation module. Moreover, in some cases, the device 2900 may also include an auxiliary energy storage unit 2904 such as a battery or capacitor (e.g., a supercapacitor). The auxiliary energy storage unit 2904 can provide reserve power in times of intermittent contact of the device 2900 with a subject's skin or other outer body surface, decreased power output and/or increased power consumption.

As shown in the views of FIGS. 29B and 29C, the device 2900 can be mated to a strap 2905, to which the ends of the heat expeller 2903 can be affixed. In the configuration shown, the heat expeller 2903 can be positioned adjacent to the strap such that one of its outer surfaces is completely exposed. Complete exposure of the heat expeller 2903 can aid in heat transfer from the heat expeller 2903. Moreover, the strap 2905 can include a clasp 2906 that can be used to secure the power generation module to a subject's wrist.

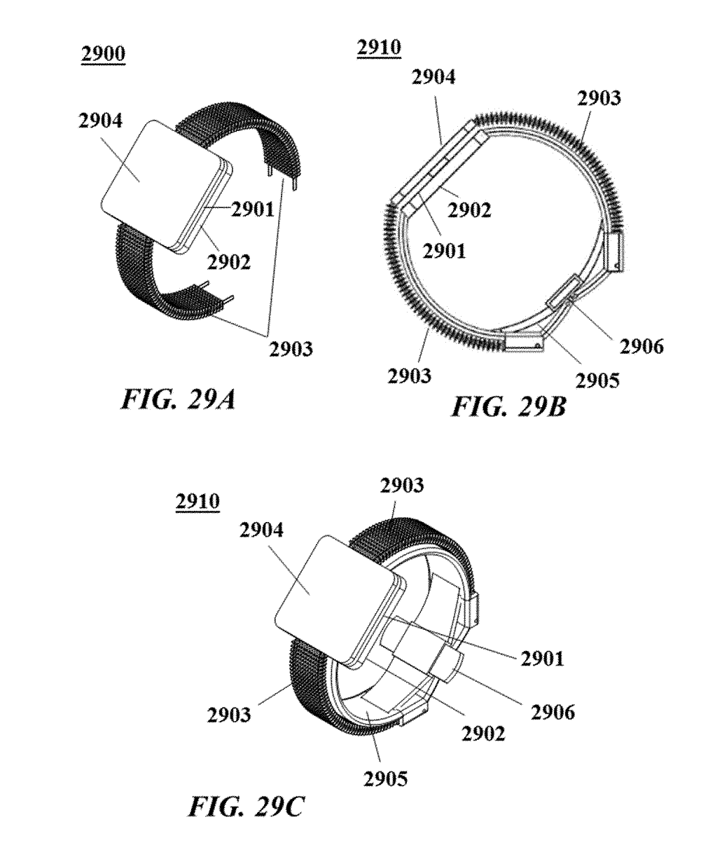

FIGS. 30A-30C schematically depict views of an example wrist-worn device 3000 that can include a plurality of power generation modules 3010 linked together and configured as a strap. The number of power generation modules 3010 can be adjusted by adding or removing individual power generation modules and/or electronically disabling individual power generation modules. Such adjustment may be needed to more closely match the power requirements of an associated device. Moreover, each power generation module 3010 can include a thermoelectric device (e.g., a thermoelectric device described elsewhere herein) 3001, a heat collector 3002 and a heat expeller 3003. In some cases, each power generation module can also include one or more of a DC-DC converter, power management electronics, and onboard energy storage.

The heat collector 3002 may be a solid material, a heat pipe (e.g., a type of heat pipe described elsewhere herein) or a combination thereof. As shown in FIG. 30A and FIG. 30C, the heat collector 3002 can be positioned on the bottom of a power generation module 3010 where it can make contact with a subject's skin or other outer body surface. In some cases, the heat collector 3002 can be a surface of power generation module's thermoelectric device 3001, or a separate surface in thermal contact with a surface of the thermoelectric device 3001.

Moreover, the heat expeller 3003 can include one or more heat pipes integrated with a heat sink and/or, as shown in FIGS. 30A and 30C, may have a flat surface. Alternatively, the heat expeller 3003 may be patterned with inclusions (e.g., slots, holes, depressions) or extrusions (e.g., fins, pins, bumps). Each heat expeller 3003 can remove heat from a power generation module's thermoelectric device 3001, thereby generating a temperature gradient in the thermoelectric device 3001 between the heat collector 3002 and the heat expeller 3003. As described elsewhere herein, such a temperature gradient can be used to generate electrical energy. In some cases, one or more of the heat collector 3002, thermoelectric device 3001 and heat expeller 3003 may have surface treatments that aid in increasing thermal transfer rates to/from the respective components. Examples of surface treatments that can aid in increasing thermal transfer rates described elsewhere and can be applied to one or more of the heat collector 3002, thermoelectric device 3001 and heat expeller 3003. In some cases, more than one surface treatment may be applied to increase thermal transfer rates.

Moreover, the individual power generation modules 3010 can be linked together and coupled to a strap piece 3005 that includes a clasp. The strap piece 3005 and its clasp may allow the device 3000 to be secured to a subject's wrist.

Via the heat collector 3002, heat generated from the subject can be provided to each of the power generation modules 3010, whereby it can be converted to electrical energy by its flow between the heat collector 3002 and the heat expeller 3003. In some cases, the electrical output from each of the individual power generation modules can be linked to a power bus that can be connected to the device 3000 and that can supply electrical energy to an electrically powered device coupled to the power generation modules 3010. Moreover, in some cases, the device 3000 may also include an auxiliary energy storage unit 3004 such as a battery or capacitor (e.g., a supercapacitor). The auxiliary energy storage unit 3004 can provide reserve power in times of intermittent contact of the device 3000 with a subject's skin or other outer body surface, decreased power output and/or increased power consumption.

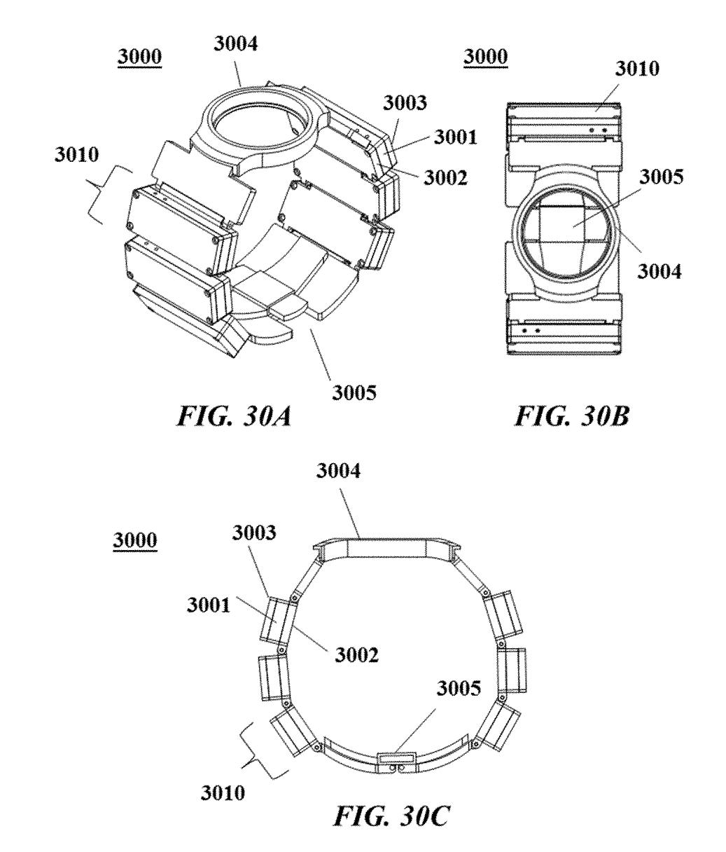

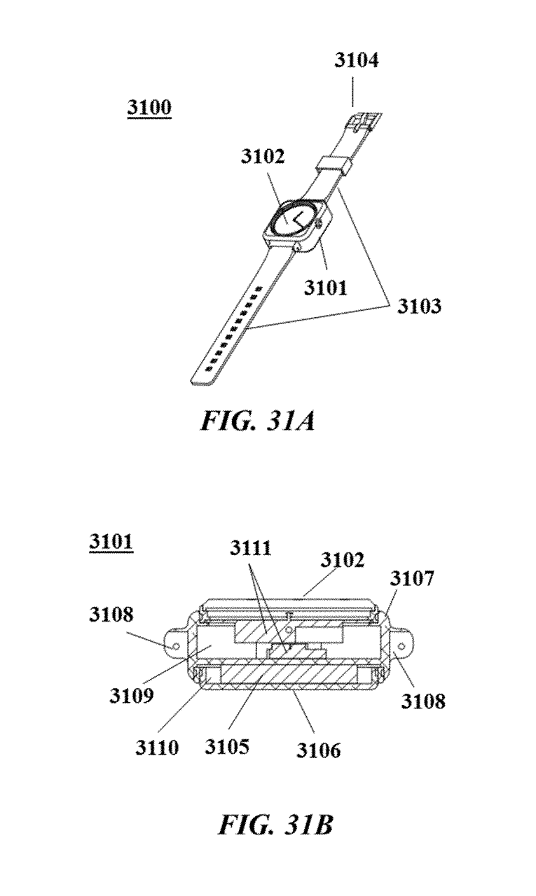

FIG. 31A schematically depicts an example wrist-worn device 3100 that can include a power generation module 3101 associated with a module 3102 to-be-powered (e.g., a timepiece module shown in FIG. 31A) electrically. The device 3100 can also include a strap 3103 that can includes a buckle 3104 that can be used to secure the device 3100 to a subject's wrist. FIG. 31B schematically depicts an exploded side-view of the power generation module 3101 and its associated electronic device 3102 to-be-powered. In some cases, the power generation module 3101 and electronic device 3102 to-be-powered can be integrated together into a housing. As shown in FIG. 31B, the power generation module 3101 can include a thermoelectric material 3105 (e.g., a type of thermoelectric material described herein), a heat collector 3106 and a heat expeller 3107 that can be integrated into the body of the power generation module 3101. The power generation module 3101 can also include attachment points 3108 that couple pieces of the strap 3103 to the power generation module 3101. In some cases, the power generation module 3101 can also include one or more of a DC-DC converter, power management electronics 3109, and onboard energy storage 3110.

The heat collector 3106 may be a solid material, a heat pipe (e.g., a type of heat pipe described elsewhere herein) or a combination thereof. As shown in FIG. 31B, the heat collector 3106 can be positioned on the bottom of the power generation module 3101 where it can make contact with a subject's skin or other outer body surface. Moreover, as shown in FIG. 31B, the heat collector 3106 can be in thermal contact with a surface of the thermoelectric material 3105.

Moreover, as shown in FIG. 31B, the heat expeller 3107 can be integrated into the body of the power generation module 3101. The heat expeller 3107 can remove heat that passes through the thermoelectric material 3105, thereby generating a temperature gradient between the heat collector 3106 and the heat expeller 3107. As described elsewhere herein, such a temperature gradient can be used to generate electrical energy. In some cases, one or more of the heat collector 3106, and heat expeller 3107 and thermoelectric material 3105 may have surface treatments that aid in increasing thermal transfer rates to/from the respective components. Examples of surface treatments that can aid in increasing thermal transfer rates described elsewhere and can be applied to one or more of the heat collector 3106, thermoelectric material 3105 and heat expeller 3107. In some cases, more than one surface treatment may be applied to increase thermal transfer rates.

Via the heat collector 3106, heat generated from the subject can be provided to the thermoelectric material 3105, whereby it can be converted to electrical energy by its flow between the heat collector 3106 and the heat expeller 3107. In some cases, the electrical output from the power generation module 3101 can be linked to a power bus that can be connected to the power generation module 3101 that can supply electrical energy to the device 3102 to-be-powered. Moreover, in some cases, the power generation module 3101 may also include one or more auxiliary energy storage units 3111 such as a battery or capacitor (e.g., a supercapacitor). An auxiliary energy storage unit 3111 can provide reserve power in times of intermittent contact of the power generation module 3101 with a subject's skin or other outer body surface, decreased power output and/or increased power consumption.

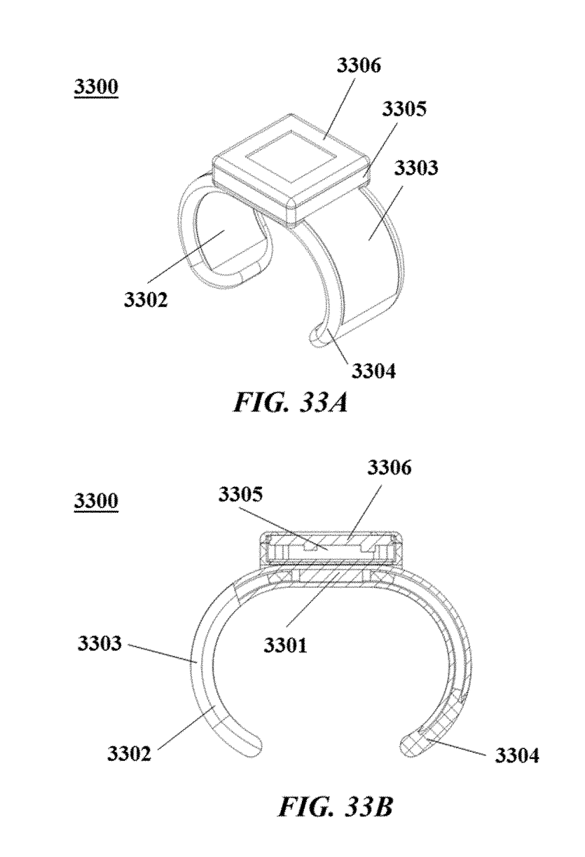

FIG. 33A and FIG. 33B schematically depict various views of an example wrist-worn device 3300. The device 3300 can include a power generation module that may comprise a thermoelectric material 3301 (e.g., a type of thermoelectric material described herein), a heat collector 3302 and a heat expeller 3303. Components of the power generation module can be integrated into a strap (e.g., a fastening member or fastener) 3304 that can be coupled to a power management module 3305 and a module to-be-powered 3306 (e.g., a timepiece module) electrically. In some cases, the module to-be-powered 3306 can be removably secured to/against the power management module 3305 via a securing member or coupler. In some cases, the module-to-be powered 3306 can be integrated into a housing with the power management module 3305. The power management module 3305 can include one or more of a DC-DC converter, power management electronics, and onboard energy storage.

The heat collector 3302 may be a solid material, a heat pipe (e.g., a type of heat pipe described elsewhere herein) or a combination thereof. As shown in FIG. 33A and FIG. 33B, the heat collector 3302 can be positioned on the bottom of the strap 3304 (e.g., integrated into the bottom of the strap 3304) where it can make contact with a subject's skin or other outer body surface across an extended area (e.g., the area of the heat collector). Moreover, as shown in FIG. 33B, the heat collector 3302 can be in thermal contact with a surface of the thermoelectric material 3301.

Moreover, as shown in FIG. 33B, the heat expeller 3303 can be positioned on the top of the strap 3304 (e.g., integrated into the top of the strap 3304) and extend across an area of the strap 3304. In some cases, the heat expeller can include one or more heat pipes integrated with a heat sink (not shown in FIG. 33A and FIG. 33B) that may or may not extend beyond the body of the device 3300. In some cases, the heat sink can be patterned with inclusions or extrusions. In some cases, the heat sink can include solid fins and/or perforated fins that improve heat transfer from the heat expeller 3303. Furthermore, the heat expeller may be completely covered by the strap 3304, partially covered by the strap 3304 or not at all covered by the strap 3304 (e.g., completely exposed).

The heat expeller 3303 can remove heat that passes through the thermoelectric material 3301, thereby generating a temperature gradient between the heat collector 3302 and the heat expeller 3303. As described elsewhere herein, such a temperature gradient can be used to generate electrical energy. In some cases, one or more of the heat collector 3302, heat expeller 3303 and thermoelectric material 3301 may have surface treatments that aid in increasing thermal transfer rates to/from the respective components. Examples of surface treatments that can aid in increasing thermal transfer rates are described elsewhere herein and can be applied to one or more of the heat collector 3302, thermoelectric material 3301 and heat expeller 3303. In some cases, more than one surface treatment may be applied to increase thermal transfer rates.

Via the heat collector 3302, heat generated from the subject can be provided to the thermoelectric material 3301, whereby it can be converted to electrical energy by its flow between the heat collector 3302 and the heat expeller 3303. In some cases, the electrical output from the power generation module can be linked to a power bus that is connected to the power management module 3305 that can supply electrical energy to the module to-be-powered 3306. Moreover, in some cases, the power management module 3305 may also include one or more auxiliary energy storage units such as a battery or capacitor (e.g., a supercapacitor). An auxiliary energy storage unit can provide reserve power in times of intermittent contact of the power generation module with a subject's skin or other outer body surface, decreased power output and/or increased power consumption.

Where a housing is implemented, the housing can have any suitable length. For example, a housing can have a length of at least about 1 mm, 10 mm, 20 mm, 30 mm, 40 mm, 50 mm, 60 mm, 70 mm, 80 mm, 90 mm, or 100 mm, or more, and/or a width of at least about 1 mm, 10 mm, 20 mm, 30 mm, 40 mm, 50 mm, 60 mm, 70 mm, 80 mm, 90 mm, or 100 mm, or more. In some cases, the housing can have a footprint of at least about 1 mm², 10 mm², 100 mm², 200 mm², 300 mm², 400 mm², 500 mm², 600 mm², 700 mm², 800 mm², 900 mm², 1000 mm, or more.

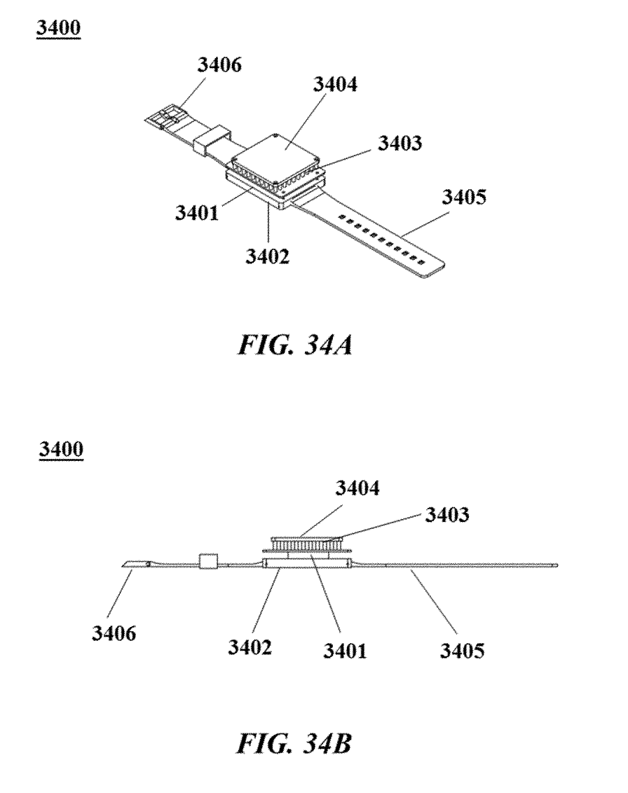

FIG. 34A and FIG. 34B schematically depict views of an example wrist-worn device 3400 that includes a power generation module. The power generation module can include a thermoelectric device (e.g., a thermoelectric device described elsewhere herein) 3401, a heat collector 3402 and a heat expeller 3403. In some cases, the power generation module can also include one or more of a DC-DC converter, power management electronics, and onboard energy storage. These auxiliary components can be provided in an electrical management unit 3404 that can also include one or more mounting points for an electronic device or components of an electronic device (e.g., an electronic display). The device 3400 can also include a strap 3405 and buckle 3406 that can be used to secure the power generation module to a subject's wrist.

The heat collector 3402 may be a solid material, a heat pipe, or a combination thereof. Non-limiting examples of suitable heat pipes include simple heat pipes, diode heat pipes, vacuum chambers and thermosyphons. As shown in FIG. 34A and FIG. 34B, the heat collector 3402 can be positioned on the bottom of the power generation module where it can make contact with a subject's skin or other outer body surface. In some cases, the heat collector 3402 can be a surface of the thermoelectric device 3401, or a separate surface in thermal contact with a surface of the thermoelectric device 3401.

Moreover, the heat expeller 3403 can have other device components (e.g., electrical management unit 3404 shown in FIG. 34A and FIG. 34B, an electronic device to-be-powered, energy storage components) mounted adjacent (e.g., above, to a side, below) to it and/or may include a solid material, a heat pipe and/or a heat sink. Where the heat expeller 3403 includes a heat sink, the heat sink may be integrated with a heat pipe, a vapor chamber and/or fins to improve heat transfer. Associated heat sink fins can be solid or they may be perforated. The heat expeller 3403 can remove heat from the thermoelectric device 3401, thereby generating a temperature gradient in the thermoelectric device 3401 between the heat collector 3402 and the heat expeller 3403. As described elsewhere herein, such a temperature gradient can be used to generate electrical energy. In some cases, one or more of the heat collector 3402, thermoelectric device 3401 and heat expeller 3403 may have one or more surface treatments that aid in increasing thermal transfer rates to/from the respective components, with examples of such surface treatments described elsewhere herein.

Via the heat collector 3402, heat generated from the subject can be provided to the power generation module, whereby it can be converted to electrical energy in the thermoelectric device 3401 by its flow from the heat collector 3402 to the heat expeller 3403. In some cases, the electrical output from the power generation module can be linked to a power bus that can be connected to the device 3400 that can supply electrical energy to an electrically powered device electrically coupled to the power generation module. In some cases, the electrically powered device can be integrated into a housing with the power generation module and/or thermoelectric device 3401 of the power generation module. In some cases, the electrically powered device can be mounted to the electrical management unit 3404. Moreover, in some cases, the device 3400 may also include an auxiliary energy storage unit (e.g., integrated into electrical management unit 3404) such as a battery or capacitor (e.g., a supercapacitor). The auxiliary energy storage unit can provide reserve power in times of intermittent contact of the device 3400 with a subject's body surface, decreased power output and/or increased power consumption.

While the example devices shown in FIGS. 27A-B, FIGS. 28A-C, FIGS. 29A-C, a FIGS. 29A-C, FIGS. 30A-C, FIGS. 31A-B, FIGS. 33A-B and FIGS. 34A-B are described above with respect to a subject's wrist, the examples are not meant to be limiting. The example devices can be applied to any suitable body region in which they can be secured to a subject's body. Non-limiting examples of such body regions include arms, legs, torso, head, knees, elbows, waste, thighs, ankles, hands, feet, fingers, toes, and a subject's crown.

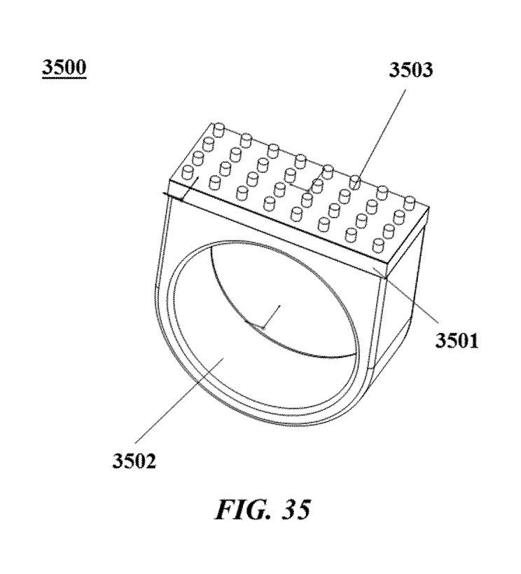

FIG. 35 schematically depicts an example finger-worn device 3500 that can include a power generation module. The power generation module can include a thermoelectric device (e.g., a thermoelectric device described elsewhere herein) 3501, a heat collector 3502 and a heat expeller 3503. In some cases, the power generation module can also include one or more of a DC-DC converter, power management electronics, and onboard energy storage. The heat collector 3502 may be integrated into the band of the device 3500.

The heat collector 3502 may be a solid material, a heat pipe, or a combination thereof. Non-limiting examples of suitable heat pipes include simple heat pipes, diode heat pipes, vacuum chambers and thermosyphons. As shown in FIG. 35, the heat collector 3502 can be positioned on the bottom of the power generation module where it can make contact with a subject's skin or other outer body surface. In some cases, the heat collector 3502 can be a surface of the thermoelectric device 3501, or a separate surface in thermal contact with a surface of the thermoelectric device 3501.

Moreover, the heat expeller 3503 can have other device components (e.g., power management components, energy storage components, an electronic device to-be-powered, etc.) mounted adjacent (e.g., above, to a side, below) to it and/or may include a solid material, a heat pipe and/or a heat sink. Where the heat expeller 3503 includes a heat sink, the heat sink may be integrated with a heat pipe, a vapor chamber and/or fins to improve heat transfer. Associated heat sink fins can be solid or they may be perforated. The heat expeller 3503 can remove heat from the thermoelectric device 3501, thereby generating a temperature gradient in the thermoelectric device 3501 between the heat collector 3502 and the heat expeller 3503. As described elsewhere herein, such a temperature gradient can be used to generate electrical energy. In some cases, one or more of the heat collector 3502, thermoelectric device 3501 and heat expeller 3503 may have one or more surface treatments that aid in increasing thermal transfer rates to/from the respective components, with examples of such surface treatments described elsewhere herein.

Via the heat collector 3502, heat generated from the subject can be provided to the power generation module, whereby it can be converted to electrical energy in the thermoelectric device 3501 by its flow from the heat collector 3502 to the heat expeller 3503. In some cases, the electrical output from the power generation module can be linked to a power bus that can be connected to the device 3500 that can supply electrical energy to an electrically powered device electrically coupled to the power generation module. In some cases, the electrically powered device can be integrated into a housing with the power generation module and/or thermoelectric device 3501 of the power generation module. Moreover, in some cases, the device 3500 may also include an auxiliary energy storage unit such as a battery or capacitor (e.g., a supercapacitor). The auxiliary energy storage unit can provide reserve power in times of intermittent contact of the device 3500 with a subject's body surface, decreased power output and/or increased power consumption.

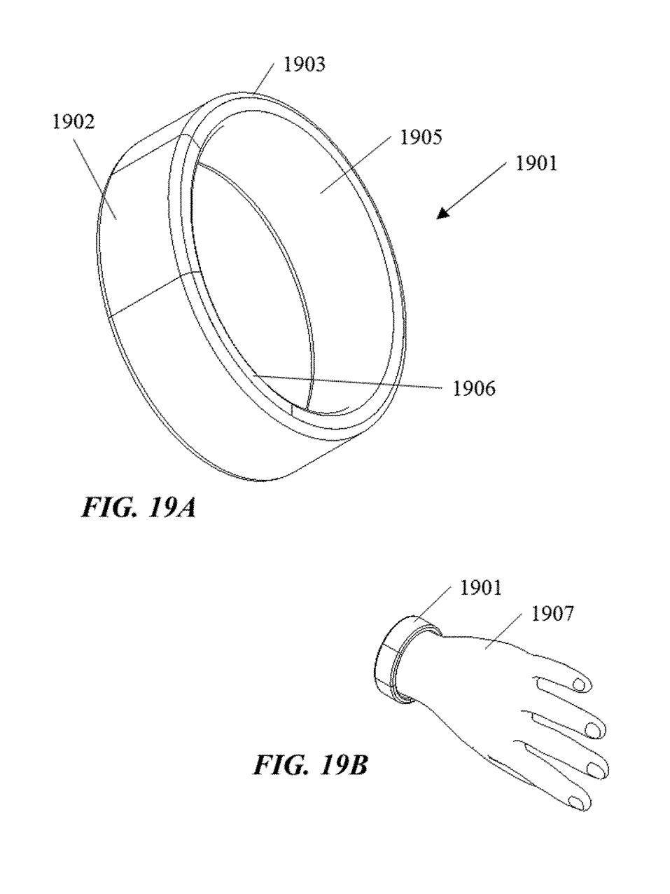

FIG. 20 shows eyewear 2001 that can be configured to operate on power at least partially (e.g., at least about 1%, 5%, 10%, 20%, 30%, 40%, 50%, 60%, 70%, 80%, 90%, 95%, 99% of a power demand or requirement) or fully generated from body heat. The eyewear 2001 may comprise a control module 2002 that can include a sensor, communications interface and a computer processor, which can be in electrical communication with one another. The eyewear 2001 may further comprise a heat expeller 2003, a thermoelectric device 2004, a heat collector 2005, and a power module 2006 having power management electronics and an energy storage system. The thermoelectric device 2004 can be in electrical communication with the control module 2002. Power to the control module 2002 can be at least partially (e.g., at least about 1%, 5%, 10%, 20%, 30%, 40%, 50%, 60%, 70%, 80%, 90%, 95%, 99% of a power demand or requirement) or fully provided by the thermoelectric device 2004 either directly to the control module 2002 or, in some cases, used to charge the energy storage system in the power module 2006, which can then provide power to the control module 2002.

The control module 2002 can be configured to present content to the user, such as on at least one of the glasses 2007 of the eyewear 2001. The content can include electronic communications, such as text messages and electronic mail, geographic navigation information, network content (e.g., content from the World Wide Web), and documents (e.g., text document).

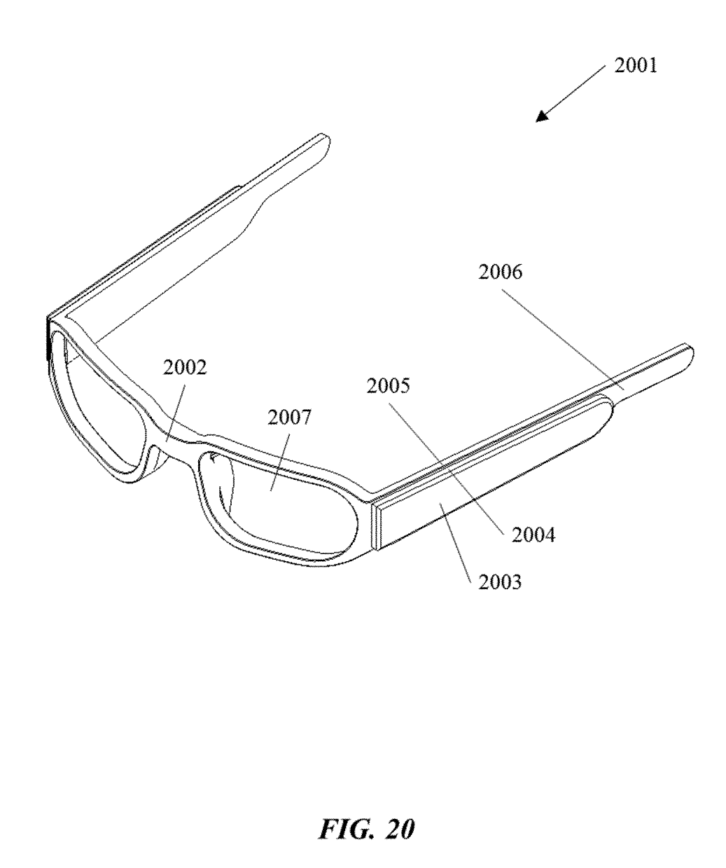

FIGS. 21A and 21B show a medical device 2101 that can be configured to operate on power at least partially (e.g., at least about 1%, 5%, 10%, 20%, 30%, 40%, 50%, 60%, 70%, 80%, 90%, 95%, 99% of a power demand or requirement) or fully generated from body heat. The medical device 2101 may comprise a control module and power module, as described elsewhere herein. The medical device 2101 may further comprise a heat expeller 2102 on one surface and a heat collector 2103 on an opposing surface, and a thermoelectric device 2104 with thermoelectric material between the heat expeller and the heat collector. The thermoelectric device 2104 can be in electrical communication with the control module and the power module. FIG. 21B shows the medical device 2101 disposed adjacent the body 2105 of a user.

In some cases, during use of a device having a thermoelectric device, heat from an object (e.g., body of a user) can generate a temperature gradient (high temperature to low temperature) from a heat collector to a heat expeller. The heat collector may collect heat and the heat expeller may expel heat. The temperature gradient can be used to generate power using a thermoelectric device between the heat collector and heat expeller.

Moreover, while the example devices shown in FIG. 20, FIGS. 21A-B, FIGS. 27A-B, FIGS. 28A-C, FIGS. 29A-C, FIGS. 29A-C, FIGS. 30A-C, FIGS. 31A-B, FIGS. 33A-B and FIGS. 34A-B and others described herein are described with respect to converting thermal energy to electrical energy, the example devices can also be used for heating and cooling applications. The thermoelectric device of a device shown in FIG. 20, FIGS. 21A-21B, FIGS. 27A-B, FIGS. 28A-C, FIGS. 29A-C, FIGS. 29A-C, FIGS. 30A-C, FIGS. 31A-B, FIGS. 33A-B and FIGS. 34A-B and others described herein can be connected to a source of electrical energy. Upon passing an electrical current through the thermoelectric device via the source of electrical energy, a temperature gradient can be established through the thermoelectric device. Via this temperature gradient, “hot” and “cold” surfaces can be generated at the heat expeller and heat collector. As to which of the surfaces is “hot” and “cold” can depend upon the direction of the current provided to the thermoelectric device. These “hot” and “cold” surfaces can be used for heating and cooling, respectively.

Thermoelectric elements, devices and systems provided herein can be used in a vehicle waste heat recovery, such as in an apparatus that uses thermoelectric materials to convert vehicular waste heat to electricity (or electric power). The apparatus can be integrated with components common to automotive vehicles, including, but not limited to, engine blocks, heat exchangers, radiators, catalytic converters, mufflers, exhaust pipes and various components in the cabin of the vehicle, such as a heating and/or air conditioning unit, or components common to industrial facilities, including, but not limited to, turbine blocks, engine blocks, exchangers, radiators, reaction chambers, chimneys and exhaust. The apparatus may be used as the sole source of electrical power to the vehicle or an electrical component of the vehicle (e.g., radio, heating or air conditioning unit, or control system), generating at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W of power, in some cases from about 100 W to 1000 W of power. Power from the apparatus can be augmented or supported by another power source. For example, in the context of automotive vehicles, power can be augmented or supported by power from a battery, alternator, regenerative braking, or a vehicular recharge station. As another example, in the context of industrial or commercial facilities, power can be augmented or supported by power from one or more of batteries, generators, the power grid, turbine blocks, engine blocks, heat exchangers, radiators, reaction chambers, chimneys and exhaust, and/or a renewable energy source, such as one or more of solar power, wind power, wave power, and geothermal power.

Flexible thermoelectric devices can be wrapped around pipes through which hot fluid can be flowed. The wrapped pipes may also be further integrated with heat sinks to increase thermal transfer. The hot fluid may be hot exhaust, hot water, hot oil, hot air etc. Over the wrapped pipes, a cool fluid can be flowed. The cool fluid may be cool exhaust, cool water, cool oil, cool air etc. The wrapped pipes may be enclosed within a housing through which the coolant is flowed if the coolant fluid is to be isolated from the ambient environment. They may be exposed to the environment if the coolant fluid is ambient air or water.

In an implementation, an apparatus for power generation from heat is a power generating pipe wrapping. Hot fluid (such as hot exhaust) may be passed through a pipe wrapped with thermoelectric devices. The hot side of the thermoelectric device may be physically or chemically bonded to the external surface of the tube/pipe to improve thermal transfer. The cold side of the thermoelectric device may be physically or chemically bonded with heat sinks to improve thermal transfer. A cool fluid (e.g., air or water) can be forced over the wrapped pipes to extract heat from the hot fluid. The thermoelectric devices interspersed in the path of heat flow can convert heat to electricity, providing an output power at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W, in some cases from about 100 W to 1000 W. If desired, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery.

In another implementation, an apparatus for power generation from heat is a power generating exhaust pipe. Hot fluid (such as hot exhaust gas) can be passed through a pipe wrapped with thermoelectric devices. The hot side of the thermoelectric device may be physically or chemically bonded to the external surface of the tube/pipe to improve thermal transfer. The cold side of the thermoelectric device may be physically or chemically bonded with heat sinks to improve thermal transfer. To further increase the surface area of the pipe and improve thermal transfer, the pipe internal surface may be molded with dimples, corrugations, pins, fins or ribs. The pipe may be made from a material that is readily weldable, extrudable, machinable or formable, such as, for example, steel, aluminum etc. A cool fluid (e.g., air or water) can be forced over the wrapped pipes to extract heat from the hot fluid. The thermoelectric devices interspersed in the path of heat flow can convert heat to electricity, providing an output power at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W, in some cases from about 100 W to 1000 W. If desired, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery.

In yet another implementation, an apparatus for power generation from heat is a discrete power generating unit to be installed on an exhaust pipe or on any hot surface. A hot surface can be placed in contact with the apparatus containing thermoelectric devices. A mating face can be provided, which can be attached in close physical contact to a hot surface using any suitable technique (e.g., bolted, strapped, welded, brazed, or soldered). The hot side of the thermoelectric device may be physically or chemically bonded to the opposite side of the mating face to improve thermal transfer. The cold side of the thermoelectric device may be physically or chemically bonded with heat sinks to improve thermal transfer. A cool fluid (such as air) can be forced over the unit to extract heat from the hot surface. The thermoelectric devices interspersed in the path of heat flow can convert heat to electricity, providing an output power at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W, in some cases from about 100 W to 1000 W. If desired, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery.

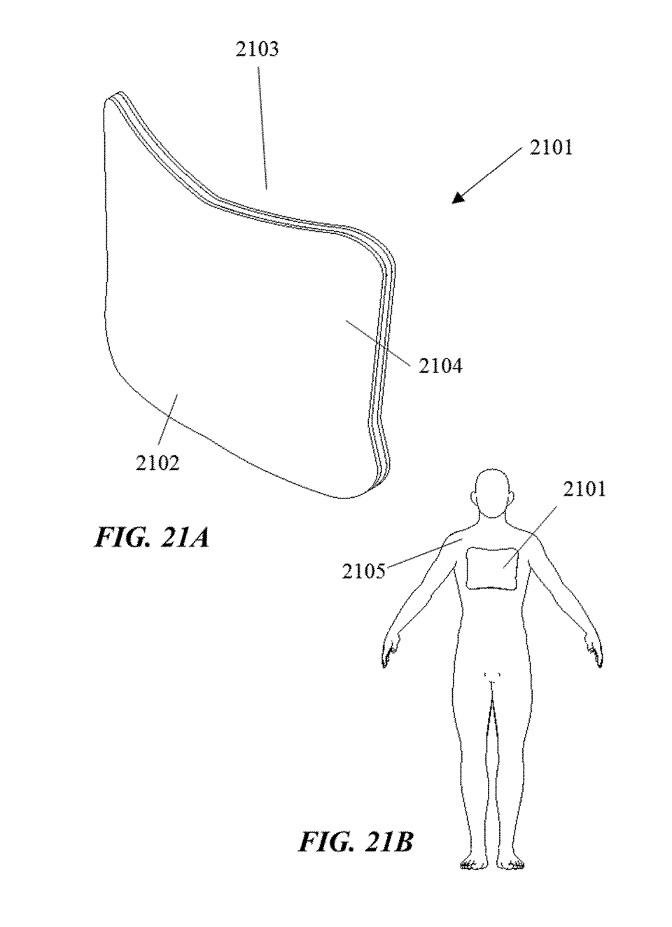

FIG. 22 schematically illustrates thermoelectric power recovery from vehicle exhaust. Apparatuses for heat recovery can be installed at various locations of an exhaust pipe 2201, such as clamped around a catalytic converter 2202, welded in an in-line fashion 2203, and/or wrapped around 2204 at least a portion of the exhaust pipe 2201.

During use, exhaust gas is directed from a manifold 2205 through the pipe 2201 to a muffler 2206. Waste heat in the exhaust gas can be used to generate power using one or more apparatuses for heat recovery, which can generate power from waste heat.

In another implementation, an apparatus for power generation from heat is a power generating radiator unit. Hot fluid (such as hot water or steam, hot oil) can be passed through a series of pipes wrapped with thermoelectric devices. The hot side of the thermoelectric device may be physically or chemically bonded to the external surface of the tube to improve thermal transfer. The cold side of the thermoelectric device may be physically or chemically bonded with heat sinks to improve thermal transfer. A cool fluid (such as air) can be forced over the wrapped pipes to extract heat from the hot fluid. The thermoelectric devices interspersed in the path of heat flow can convert heat to electricity, providing an output power at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W, in some cases from about 100 W to 1000 W. If desired, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery.

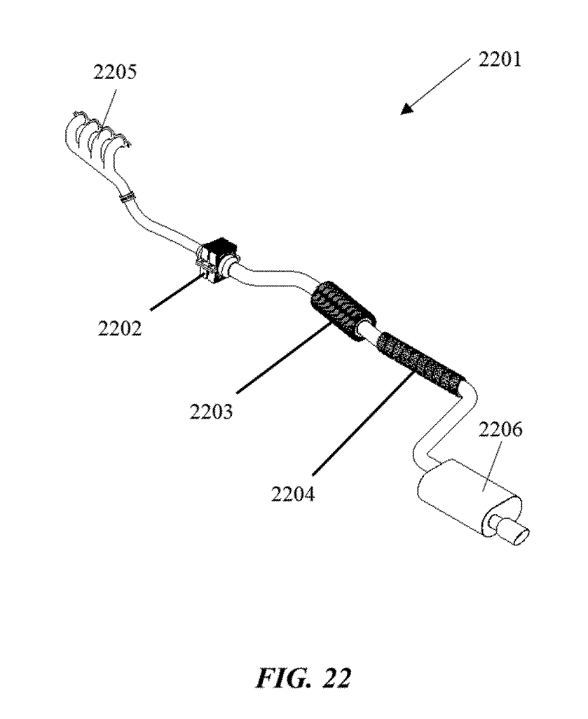

FIGS. 23A and 23B show an apparatus for heat recovery and power generation installed in a radiator 2301, which may comprise a hot fluid inlet 2302 in fluid communication with a hot fluid outlet 2303, in addition to cooling fans 2304. The radiator 2301 can be part of a vehicle. Hot pipes of the radiator may be at least partially wrapped by a heat recovery apparatus 2305 comprising a flexible thermoelectric device with flexible heat sinks. The flexible thermoelectric device can include thermoelectric elements disclosed herein.

During use, a hot fluid can be directed from the hot fluid inlet 2302 to the hot fluid outlet 2303. Waste heat in the fluid can be used to generate power using the apparatus 2305 for heat recovery, which can generate power from the waste heat.

In another implementation, an apparatus for power generation from heat is a power generating exchanger unit. Hot fluid (e.g., hot water or steam, or hot oil) can be passed through a series of pipes wrapped with thermoelectric devices. The hot side of the thermoelectric device may be physically or chemically bonded to the external surface of the tube to improve thermal transfer. The cold side of the thermoelectric device may be physically or chemically bonded with heat sinks to improve thermal transfer. A cool fluid (e.g., cool water or cool oil) can be pumped over the wrapped pipes to extract heat from the hot fluid. The thermoelectric devices interspersed in the path of heat flow can convert heat to electricity, providing an output power at least about 1 W, 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1000 W, or 5000 W, in some cases from about 100 W to 1000 W. If desired, a lower voltage can be converted to at least about 1 V, 2, V, 2.1 V, 2.2 V, 2.3 V, 2.35 V, 2.4 V, 2.45 V, 2.5 V, 3 V, 3.1 V, 3.2 V, 3.3 V, 3.4 V, 3.5 V, 3.6 V, 3.7 V, 3.8 V, 3.9 V, 4 V, 4.1 V, 4.2 V, 4.3 V, 4.4 V, 4.5 V, or 5.0 V using a DC-DC converter and associated power management circuitry, and can be used to power circuits directly or to trickle charge a power storage unit such as a battery.

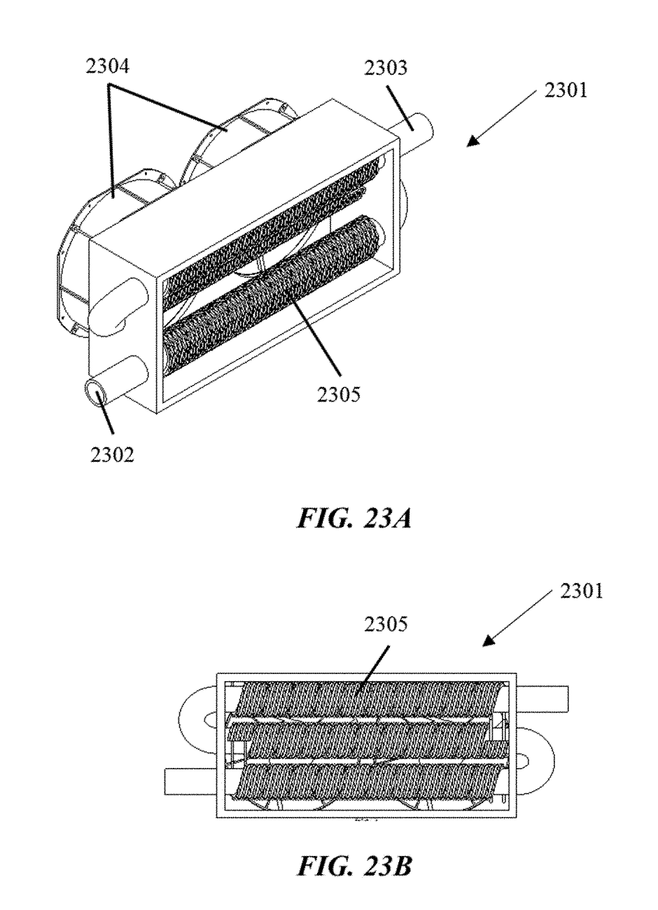

FIGS. 24A and 24B show an apparatus for heat recovery and power generation installed in a heat exchanger 2401, which may comprise a hot fluid inlet 2402 in fluid communication with a hot fluid outlet 2403 and a cold fluid inlet 2404 in fluid communication with a cold fluid outlet 2405. The heat exchanger 2401 may further include baffles 2406 to direct cold fluid flow, and hot pipes 2407 wrapped with a flexible thermoelectric device.

During use, a hot fluid (e.g., steam) may be directed from the hot fluid inlet 2402 to the hot fluid outlet 2403 and a cold fluid (e.g., liquid water) may be directed from the cold fluid inlet 2404 to the cold fluid outlet 2405. The hot fluid can flow through the hot pipes 2407 and dissipate heat to the cold fluid being directed from the fold fluid inlet 2404 to the cold fluid outlet 2405. Waste heat in the fluid can be used to generate power using the flexible thermoelectric device wrapped around the hot pipes 2407.

### Computer Control Systems

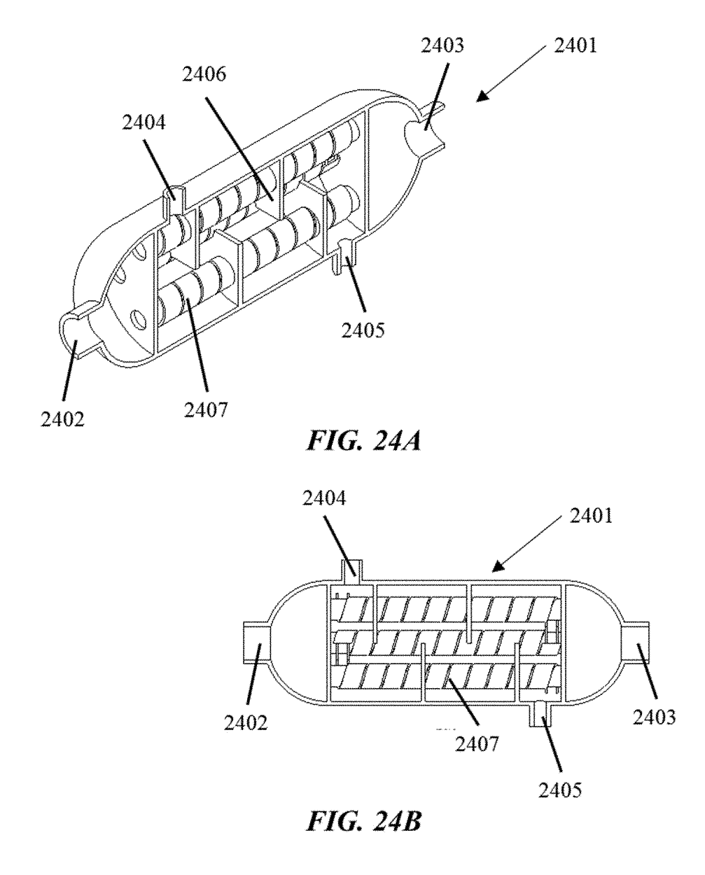

The present disclosure provides computer control systems that can be programmed or otherwise configured to implement various methods of the disclosure, such as manufacturing a thermoelectric element. FIG. 25 shows a computer system (also “system” herein) 2501 programmed or otherwise configured to facilitate the formation of thermoelectric devices of the disclosure. The system 2501 can be programmed or otherwise configured to implement methods described herein. The system 2501 can include a central processing unit (CPU, also “processor” and “computer processor” herein) 2505, which can be a single core or multi core processor, or a plurality of processors for parallel processing. The system 2501 can also include memory 2510 (e.g., random-access memory, read-only memory, flash memory), electronic storage unit 2515 (e.g., hard disk), communications interface 2520 (e.g., network adapter) for communicating with one or more other systems, and peripheral devices 2525, such as cache, other memory, data storage and/or electronic display adapters. The memory 2510, storage unit 2515, interface 2520 and peripheral devices 2525 can be in communication with the CPU 2505 through a communications bus (solid lines), such as a motherboard. The storage unit 2515 can be a data storage unit (or data repository) for storing data. The system 2501 can be operatively coupled to a computer network (“network”) 2530 with the aid of the communications interface 2520. The network 2530 can be the Internet, an internet and/or extranet, or an intranet and/or extranet that is in communication with the Internet. The network 2530 in some cases can be a telecommunication and/or data network. The network 2530 can include one or more computer servers, which can enable distributed computing, such as cloud computing. The network 2530 in some cases, with the aid of the system 2501, can implement a peer-to-peer network, which may enable devices coupled to the system 2501 to behave as a client or a server.

The system 2501 can be in communication with a processing system 2535 for forming thermoelectric elements and devices of the disclosure. The processing system 2535 can be configured to implement various operations to form thermoelectric devices provided herein, such as forming thermoelectric elements and forming thermoelectric devices (e.g., thermoelectric tape) from the thermoelectric elements. The processing system 2535 can be in communication with the system 2501 through the network 2530, or by direct (e.g., wired, wireless) connection. In an example, the processing system 2535 is an electrochemical etching system. In another example, the processing system 2535 is a dry box.

The processing system 2535 can include a reaction space for forming a thermoelectric element from the substrate 2540. The reaction space can be filled with an electrolyte and include electrodes for etching (e.g., cathodic or anodic etching).

Methods as described herein can be implemented by way of machine (or computer processor) executable code (or software) stored on an electronic storage location of the system 2501, such as, for example, on the memory 2510 or electronic storage unit 2515. During use, the code can be executed by the processor 2505. In some examples, the code can be retrieved from the storage unit 2515 and stored on the memory 2510 for ready access by the processor 2505. In some situations, the electronic storage unit 2515 can be precluded, and machine-executable instructions can be stored on memory 2510.

The code can be pre-compiled and configured for use with a machine have a processor adapted to execute the code, or can be compiled during runtime. The code can be supplied in a programming language that can be selected to enable the code to execute in a pre-compiled or as-compiled fashion.

Aspects of the systems and methods provided herein, such as the system 2501, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

Methods described herein can be automated with the aid of computer systems having storage locations with machine-executable code implementing the methods provided herein, and a processor for executing the machine-executable code.

### Example 1

A thermoelectric element is formed by providing a semiconductor substrate in a reaction chamber having an etching solution comprising hydrofluoric acid at a concentration from about 10% to 50% (by weight) HF. The semiconductor substrate has a dopant concentration such that the semiconductor substrate has a resistivity from about 0.001 ohm-cm to 0.1 ohm-cm. The etching solution is at a temperature of about 25° C. A working electrode is brought in contact with a backside of the substrate and a counter electrode is submerged in the etching solution facing a front side of the substrate. The counter electrode is not in contact with the substrate. Next, a power source is used to force a current density from about 10 mA/cm² to 20 mA/cm², which yields an electrical potential of about 1 V between the working electrode and the counter electrode. The applied electrical potential and flow of electrical current is maintained for a time period of about 1 hour. This forms a disordered pattern of holes in the substrate.

### Example 2

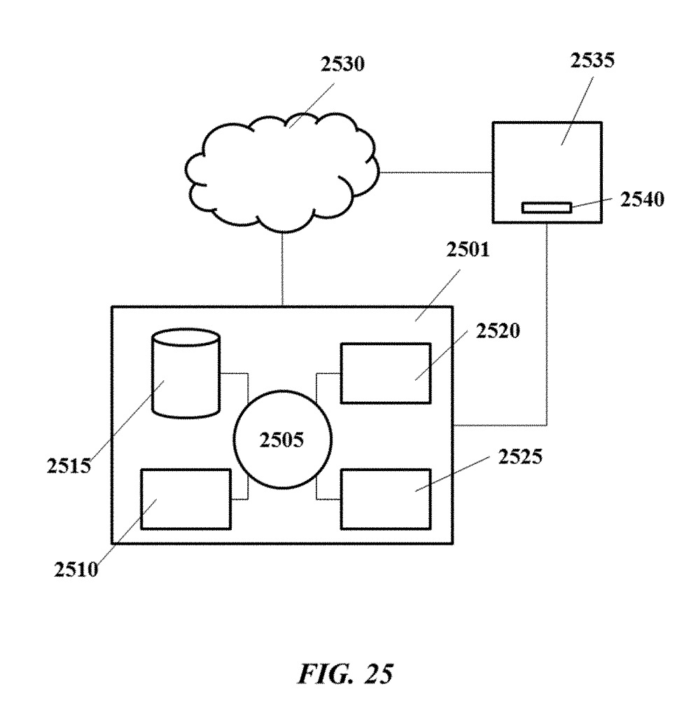

A thermoelectric element is formed according to the method described in Example 1. FIGS. 26A and 26B show an SEM micrograph and XRD spectrum, respectively, of the thermoelectric element. The SEM micrograph is obtained under the following conditions: 5 kilovolts (kV) and a working distance of 5 millimeters. The SEM micrograph shows a disordered pattern of holes in silicon. The XRD spectrum shows two peaks. The taller peak (left) is of porous silicon and the smaller peak (right) is of bulk silicon.

### Example 3

A p- or n-type single crystal silicon wafer of thickness 100 micrometers (rpm) to 500 am, with resistivity of range 0.002-0.02 ohm-cm is used. A 30-Watt pulsed laser with 1064 nm wavelength and 5 mm beam size operating at 20 KHz is scanned across the wafer with a speed of 0.2 mm/sec and a power of 20%. On a sample with resistivity of 0.003 ohm-cm, the thermal conductivity decreases to 5 W/mK after laser processing.

Devices, systems and methods provided herein may be combined with or modified by other devices, systems and methods, such as devices, systems and/or methods described in U.S. Pat. No. 7,309,830, U.S. Pat. No. 9,263,662 to Boukai et al., U.S. Patent Publication No. 2006/0032526 to Fukutani et al., U.S. Patent Publication No. 2009/0020148 to Boukai et al., U.S. patent application Ser. No. 13/550,424 to Boukai et al., PCT/US2012/047021, filed Jul. 17, 2012, PCT/US2013/021900, filed Jan. 17, 2013, PCT/US2013/055462, filed Aug. 25, 2013, PCT/US2005/024541, filed Jul. 12, 2005, and PCT/US2013/067346, filed Oct. 29, 2013, each of which is entirely incorporated herein by reference.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1.-45. (canceled)

46. A thermoelectric power management system, comprising:
an electronic device comprising a user interface; and
a thermoelectric device integrated with said electronic device in a housing, wherein said thermoelectric device comprises (i) a thermoelectric unit having a heat transfer surface that rests adjacent to a body surface of a user, and (ii) at least one fastener coupled to said thermoelectric unit, wherein said at least one fastener secures said thermoelectric device to said body surface of said user, wherein said at least one fastener comprises a heat expelling unit comprising a conduit that is in thermal communication with said thermoelectric unit,
wherein during use, said thermoelectric unit generates power upon flow of thermal energy from said heat transfer surface to said heat expelling unit.

47. The thermoelectric power management system of claim 46, wherein said electronic device is a watch.

48. The thermoelectric power management system of claim 46, wherein said user interface is a graphical user interface.

49. The thermoelectric power management system of claim 46, wherein said thermoelectric device comprises a plurality of fasteners coupled to said thermoelectric unit, wherein said plurality of fasteners secure said thermoelectric device to said body surface of said user.

50. The thermoelectric power management system of claim 46, wherein said electronic device comprises an energy storage unit.

51. The thermoelectric power management system of claim 46, further comprising an inductive unit in electrical communication with said thermoelectric unit, wherein said inductive unit couples said power generated by said thermoelectric unit to said electronic device.

52. The thermoelectric power management system of claim 46, wherein said fastener comprises said heat transfer surface.

53. The thermoelectric power management system of claim 46, wherein said conduit is a heat pipe.

54. A thermoelectric power management system, comprising:
an electronic device comprising a user interface; and
a thermoelectric device comprising (i) a thermoelectric unit having a heat transfer surface that rests adjacent to a body surface of a user, (ii) a coupler that removably secures said thermoelectric unit against said electronic device, (iii) at least one fastener coupled to said thermoelectric unit, wherein said at least one fastener secures said thermoelectric device to said body surface of said user, and (iv) a separate heat expelling unit in thermal communication with said thermoelectric unit,
wherein during use, said thermoelectric unit generates power upon flow of thermal energy from said heat transfer surface to said separate heat expelling unit.

55. The thermoelectric power management system of claim 54, wherein said separate heat expelling unit comprises at least one heat pipe that is in thermal communication with said thermoelectric unit.

56. The thermoelectric power management system of claim 54, wherein said fastener comprises said heat expelling unit.

57. The thermoelectric power management system of claim 54, wherein said electronic device comprises an energy storage unit.

58. The thermoelectric power management system of claim 54, wherein said coupler is magnetic.

59. The thermoelectric power management system of claim 54, further comprising an inductive unit in electrical communication with said thermoelectric unit, wherein said inductive unit couples said power generated by said thermoelectric unit to said electronic device.

60. A thermoelectric power management system, comprising:
a conduit that permits flow of a fluid;
a thermoelectric device comprising (i) a first heat transfer surface that is in thermal communication with said conduit; (ii) a thermoelectric material in thermal communication with said first heat transfer surface; and (iii) a second heat transfer surface that is in thermal communication with said thermoelectric material, wherein during use, said thermoelectric device generates power upon flow of thermal energy from said conduit, through said first heat transfer surface, to said second heat transfer surface; and
an electronic device electrically coupled to said thermoelectric device, wherein during use, said thermoelectric device generates power that is sufficient to meet at least a portion of a power demand of said electronic device.

61. The thermoelectric power management system of claim 60, wherein said electronic device comprises a user interface.

62. The thermoelectric power management system of claim 60, wherein said fluid is a gas or liquid.

63. The thermoelectric power management system of claim 60, wherein said conduit is a pipe or vent.

64. The thermoelectric power management system of claim 60, wherein during use, said thermoelectric device generates power upon flow of thermal energy from said second heat transfer surface, through said first heat transfer surface, to said conduit.

65. The thermoelectric power management system of claim 60, wherein said thermoelectric device is impedance matched with said conduit.
